(19) United States
(12) Patent Application Publication
(10) Pub. No.: US 2024/0032413 A1
(43) Pub. Date: Jan. 25, 2024

(54) ORGANOMETALLIC COMPOUND AND ORGANIC LIGHT-EMITTING DIODE INCLUDING THE SAME

(71) Applicants: LG Display Co., Ltd., Seoul (KR); LT Materials Co., Ltd., Gyeonggi-do (KR)

(72) Inventors: Inbum SONG, Seoul (KR); Dohan KIM, Goyang-si (KR); Sungjin PARK, Incheon (KR); Jaemin MOON, Seoul (KR); Seokwoo KANG, Hwaseong-si (KR); Yong Woo KIM, Osan-si (KR); Hyun Ju LA, Osan-si (KR); Kundo KIM, Yongin-si (KR); Haneal JEONG, Yongin-si (KR)

(73) Assignees: LG Display Co., Ltd., Seoul (KR); LT Materials Co., Ltd., Gyeonggi-do (KR)

(21) Appl. No.: 18/214,741

(22) Filed: Jun. 27, 2023

(30) Foreign Application Priority Data
Jul. 8, 2022 (KR) 10-2022-0084559

(51) Int. Cl. H10K 85/30; C07F 15/00; C09K 11/06

(52) U.S. Cl. CPC H10K 85/342; C07F 15/0033; C09K 11/06; H10K 50/121

(57) ABSTRACT

An organometallic compound represented by Chemical Formula I, and an organic light-emitting diode containing the same. In the Chemical Formula I, M may represent a central coordination metal, and includes one selected from a the group consisting of molybdenum (Mo), tungsten (W), rhenium (Re), ruthenium (Ru), osmium (Os), rhodium (Rh), iridium (Ir), palladium (Pd), platinum (Pt), and gold (Au). Each of R₁ to R₈ may independently represent one selected from the group consisting of hydrogen, deuterium, a substituted or unsubstituted C1 to C20 alkyl group, and a substituted or unsubstituted C3 to C20 bicycloalkyl group. A may represent a ring structure of isoquinoline. Each of X₁ to X₄ may independently represent one selected from CR₁₁ and nitrogen (N).

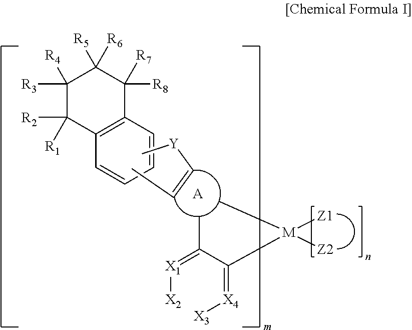

### CROSS-REFERENCE TO RELATED APPLICATION

This application claims the benefit of and the priority to Korean Patent Application No. 10-2022-0084559, which is filed on Jul. 8, 2022 in the Korean Intellectual Property Office, and which is hereby incorporated by reference in its entirety.

### BACKGROUND

### 1. Technical Field

The present disclosure relates to an organometallic compound, and for example, to an organometallic compound having phosphorescent properties and an organic light-emitting diode including the same.

### 2. Description of Related Art

Display devices are ubiquitous, and interest in such devices is increasing. One of the display devices is an organic light-emitting display device including an organic light-emitting diode (OLED) which is rapidly developing.

In the organic light-emitting diode, when electric charges are injected into a light-emitting layer formed or disposed between a positive electrode and a negative electrode, an electron and a hole may be recombined with each other in the light-emitting layer to form an exciton. The energy of the exciton may be converted to light that will be emitted by the organic light-emitting diode. Compared to conventional display devices, the organic light-emitting diode may operate at a lower voltage, consume relatively little power, render excellent colors, and may be used in a variety of ways when the organic light-emitting diode includes a flexible substrate. Further, a size of the organic light-emitting diode may be adjustable.

### SUMMARY

The organic light-emitting diode (OLED) may have superior viewing angle and contrast ratio compared to a liquid crystal display (LCD), and may be lightweight and ultra-thin because the OLED may not require a backlight. The organic light-emitting diode may include a plurality of organic layers between a negative electrode (electron injection electrode; cathode) and a positive electrode (hole injection electrode; anode). The plurality of organic layers may include a hole injection layer, a hole transport layer, a hole transport auxiliary layer, an electron blocking layer, and a light-emitting layer, an electron transport layer, etc.

In this organic light-emitting diode structure, when a voltage is applied across the two electrodes, electrons and holes are injected from the negative and positive electrodes, respectively, into the light-emitting layer. Excitons are generated in the light-emitting layer and then fall to a ground state to emit light.

Organic materials used in the organic light-emitting diode may be largely classified into light-emitting materials and charge-transporting materials. The light-emitting material may be an important factor determining luminous efficiency of the organic light-emitting diode. The luminescent material may have high quantum efficiency, excellent electron and hole mobility, and may exist uniformly and stably in the light-emitting layer. The light-emitting materials may be classified into light-emitting materials emitting blue, red, and green colors based on colors of the light. A color-generating material may include a host and dopants to increase the color purity and luminous efficiency through energy transfer.

When the fluorescent material is used, singlets, which make up about 25% of excitons generated in the light-emitting layer, are used to emit light, while most of triplets, which make up 75% of the excitons generated in the light-emitting layer, are dissipated as heat. However, when the phosphorescent material is used, both singlets and triplets may emit light.

Conventionally, an organometallic compound is used as the phosphorescent material used in the organic light-emitting diode. Research and development of the phosphorescent material to solve low efficiency and lifetime problems are continuously performed.

Accordingly, objects of the present disclosure are to provide an organometallic compound capable of lowering operation voltage, and improving efficiency, and lifespan, and an organic light-emitting diode including an organic light-emitting layer containing the same.

Objects of the present disclosure are not limited to the above-mentioned objects. Other objects and advantages of the present disclosure that are not mentioned may be understood based on following descriptions, and may be more clearly understood based on aspects of the present disclosure. Further, it will be easily understood that the objects and advantages of the present disclosure may be realized using means shown in the claims and combinations thereof.

To achieve these and other advantages and in accordance with objects of the disclosure, as embodied and broadly described herein, an organometallic compound represented by Chemical Formula I:

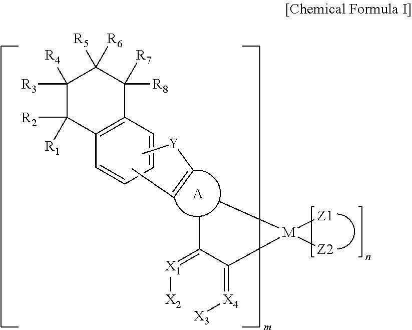

wherein in the Chemical Formula I,
M may represent a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au);
each of R₁ to R₈ may independently represent one selected from the group consisting of hydrogen, deuterium, a substituted or unsubstituted C1 to C20 alkyl group, and a substituted or unsubstituted C3 to C20 bicycloalkyl group;
Y may represent one selected from the group consisting of BR₉, CR₉R₁₀, C═O, CNR₉, SiR₉R₁₀, NR₉, PR₉, AsR₉, SbR₉, P(O)R₉, P(S)R₉, P(Se)R₉, As(O)R₉, As(S)R₉, As(Se)R₉, Sb(O)R₉, Sb(S)R₉, Sb(Se)R₉, O, S, Se, Te, SO, SO₂, SeO, SeO₂, TeO, and TeO₂;
each of R₉ and R₁₀ may independently represent one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
A may represent a ring structure of isoquinoline;
each of X₁ to X₄ may independently represent one selected from CR₁₁ and nitrogen (N);
each R₁₁ may independently represent one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group and a phosphino group;
when at least two of X₁ to X₄ are each independently represented by CR₁₁, two adjacent R₁₁ may be optionally fused with each other to form one ring structure selected from a 5-membered carbon ring, a 5-membered hetero ring, a 6-membered carbon ring, and a 6-membered hetero ring;

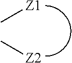

may represent a bidentate ligand;
m may be an integer of 1, 2 or 3, n may be an integer of 0, 1 or 2, and m+n may be an oxidation number of the metal M.

The organometallic compound according to the present disclosure may be used as the dopant of the phosphorescent light-emitting layer of the organic light-emitting diode. The operation voltage of the organic light-emitting diode may be lowered, and the efficiency and lifespan characteristics of the organic light-emitting diode may be improved.

Effects of the present disclosure are not limited to the above-mentioned effects, and other effects as not mentioned may be clearly understood by those skilled in the art from following descriptions.

It is to be understood that both the foregoing general description and the following detailed description of the present disclosure are merely by way of example and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a cross-sectional view schematically illustrating an organic light-emitting diode in which a light-emitting layer contains an organometallic compound represented by the Chemical Formula I according to an example embodiment of the present disclosure.

FIG. 2 is a cross-sectional view schematically illustrating an organic light-emitting diode having a tandem structure having two light-emitting stacks and containing an organometallic compound represented by the Chemical Formula I according to an example embodiment of the present disclosure.

FIG. 3 is a cross-sectional view schematically illustrating an organic light-emitting diode having a tandem structure having three light-emitting stacks and containing an organometallic compound represented by the Chemical Formula I according to an example embodiment of the present disclosure.

FIG. 4 is a cross-sectional view schematically illustrating an organic light-emitting display device including an organic light-emitting diode according to an example embodiment of the present disclosure.

### DETAILED DESCRIPTION

Reference will now be made in detail to some of the examples and embodiments of the disclosure illustrated in the accompanying drawings. Wherever possible, the same reference numbers will be used throughout the drawings to refer to the same or like parts.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and may be embodied in various different forms. Thus, these example embodiments are set forth only to make the present disclosure sufficiently complete, and to assist those skilled in the art to fully understand the scope of the present disclosure. The protected scope of the present disclosure is defined by claims and their equivalents.

For convenience of description, a scale in which each of elements is illustrated in the accompanying drawings may differ from an actual scale. Thus, the illustrated elements are not limited to the specific scale in which they are illustrated in the drawings. The same reference numbers in different drawings represent the same or similar elements, which may perform similar functionality. Further, where the detailed description of the relevant known steps and elements may obscure an important point of the present disclosure, a detailed description of such known steps and elements may be omitted. Furthermore, in the following detailed description of the present disclosure, numerous specific details are set forth in order to provide a sufficiently thorough understanding of the present disclosure. However, it will be understood that the present disclosure may be practiced without these specific details. In other instances, known methods, procedures, components, and circuits have not been described in detail so as not to unnecessarily obscure aspects of the present disclosure.

Although example embodiments of the present disclosure are described in detail with reference to the accompanying drawings, the present disclosure is not limited thereto and may be embodied in many different forms without departing from the technical concept of the present disclosure. Therefore, example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. The same or similar elements are designated by the same reference numerals throughout the specification unless otherwise specified.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In the present specification, where the terms “comprise,” “have,” “include,” and the like are used, one or more other elements may be added unless the term, such as “only,” is used. As used herein, the term “and/or” includes a single associated listed item and any and all of the combinations of two or more of the associated listed items. An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

In construing an element or numerical value, the element or the numerical value is to be construed as including an error or tolerance range even where no explicit description of such an error or tolerance range is provided.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present. In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used.

Further, as used herein, when a layer, film, region, plate, or the like may be disposed “on” or “on a top” of another layer, film, region, plate, or the like, the former may directly contact the latter or another layer, film, region, plate, or the like may be disposed between the former and the latter. As used herein, when a layer, film, region, plate, or the like is directly disposed “on” or “on a top” of another layer, film, region, plate, or the like, the former directly contacts the latter and another layer, film, region, plate, or the like is not disposed between the former and the latter. Further, as used herein, when a layer, film, region, plate, or the like may be disposed “below” or “under” another layer, film, region, plate, or the like, the former may directly contact the latter or another layer, film, region, plate, or the like may be disposed between the former and the latter. As used herein, when a layer, film, region, plate, or the like is directly disposed “below” or “under” another layer, film, region, plate, or the like, the former directly contacts the latter and another layer, film, region, plate, or the like is not disposed between the former and the latter.

In descriptions of temporal relationships, for example, temporal precedent relationships between two events such as “after”, “subsequent to”, “before”, “next,” etc., another event may occur therebetween unless a more limiting term, “just,” “immediate(ly),” or “direct(ly)” (“directly after”, “directly subsequent”, “directly before”) is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or overall combined with each other, and may be variously inter-operated with each other and driven technically as those skilled in the art can sufficiently understand. The embodiments may be implemented independently of each other and may be implemented together in an co-dependent relationship.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term “or” means “inclusive or” rather than “exclusive or”. That is, unless otherwise stated or clear from the context, the expression that “x uses a or b” means any one of natural inclusive permutations.

The terms used in the description below may be general and universal in the relevant art. However, there may be other terms depending on the development and/or change of technology, convention, preference of technicians, etc. Therefore, the terms used in the description below should not be understood as limiting the disclosure, and should be understood as examples of the terms for describing embodiments.

Further, in some example embodiments, a term may be arbitrarily selected by the applicant, and in this case, the detailed meaning thereof will be described in a corresponding description section. Therefore, such terms used in the description below may be understood based on the name of the terms, and the meaning of the terms and the contents throughout the Detailed Description.

As used herein, the term “hetero ring” refers to a ring structure in which one or more carbon atoms, for example, 1 to 5 carbon atoms among carbon atoms constituting an aromatic ring, an alicyclic ring, or an aralkyl ring are substituted with heteroatoms such as nitrogen (N), oxygen (O), and sulfur (S).

As used herein and unless otherwise indicated, the term “substituted” means that the specified group or moiety bears one or more substituents. The term “unsubstituted” means that the specified group bears no substituents.

As used herein and unless otherwise indicated, the term “substituent” means a non-hydrogen moiety, for example, deuterium, hydroxy, halogen (e.g. fluoro, chloro or bromo), carboxy, carboxamido, imino, alkanoyl, cyano, cyanomethyl, nitro, amino, alkyl, alkenyl, alkynyl, cycloalkyl, arylalkyl, aryl, heterocycle, heteroaryl, hydroxyl, amino, alkoxy, halogen, carboxy, carbalkoxy, carboxamido, monoalkylaminosulfmyl, dialkylaminosulfmyl, monoalkylaminosulfonyl, dialkylaminosulfonyl, alkylsulfonylamino, hydroxysulfonyloxy, alkoxysulfonyloxy, alkylsulfonyloxy, hydroxysulfonyl, alkoxysulfonyl, alkylsulfonylalkyl, monoalkylaminosulfonylalkyl, dialkylaminosulfonylalkyl, monoalkylaminosulfmylalkyl, dialkylaminosulfmylalkyl and the like.

Hereinafter, example embodiments of the present disclosure will be described in detail with reference to the accompanying drawings. In adding reference numerals to elements of each of the drawings, although the same elements are illustrated in other drawings, like reference numerals may refer to like elements.

Hereinafter, example embodiments of an organometallic compound according to the present disclosure and of an organic light-emitting diode including the same will be described.

Conventionally, an organometallic compound has been used as a dopant in a light-emitting layer of an organic light-emitting diode. For example, the main ligand(s) in the organometallic compound may have a skeletal structure based on, for example, 2-phenylpyridine. However, the conventional light-emitting dopant has a limit in improving efficiency and lifetime of the organic light-emitting diode. Accordingly, the inventors of the present disclosure have arrived at a light-emitting dopant material that may further improve the efficiency and lifespan of the organic light-emitting diode, and complete the present disclosure.

The organometallic compound according to an example embodiment of the present disclosure may be represented by Chemical Formula I, wherein a main ligand of the Chemical Formula I has a hetero ring structure in which at least one of two rings connected to a central coordination metal (M) contains nitrogen (N). For example, the main ligand may have a quinoline ring structure, an isoquinoline structure, and the like. In some embodiment, the main ligand may have an isoquinoline structure. Moreover, an aromatic ring and an aliphatic ring may be fused with the nitrogen (N)-containing hetero ring to enhance rigidity of the compound molecule and achieve a stable structure.

The inventors of the present disclosure have experimentally identified that when a dopant material of a phosphorescent light-emitting layer of the organic light-emitting diode includes the organometallic compound represented by the Chemical Formula 1, the light-emitting efficiency and the lifespan of the organic light-emitting diode are improved and the operation voltage thereof are lowered.

The organometallic compound according to the present disclosure having the above characteristics may be represented by the Chemical Formula I.

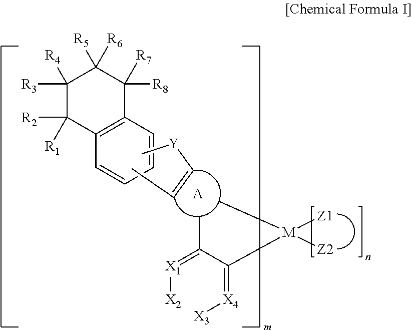

In the above Chemical Formula I,
M may represent a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au);
each of R₁ to R₈ may independently represent one selected from the group consisting of hydrogen, deuterium, a substituted or unsubstituted C1 to C20 alkyl group, and a substituted or unsubstituted C3 to C20 bicycloalkyl group, wherein at least one of R₁ to R₈ may be a methyl group;
Y may represent one selected from the group consisting of BR₉, CR₉R₁₀, C═O, CNR₉, SiR₉R₁₀, NR₉, PR₉, AsR₉, SbR₉, P(O)R₉, P(S)R₉, P(Se)R₉, As(O)R₉, As(S)R₉, As(Se)R₉, Sb(O)R₉, Sb(S)R₉, Sb(Se)R₉, O, S, Se, Te, SO, SO₂, SeO, SeO₂, TeO, and TeO₂;
each of R₉ and R₁₀ may independently represent one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
A may represent a ring structure of isoquinoline;
each of X₁ to X₄ may independently represent one selected from CR₁₁ and nitrogen (N);
each R₁₁ may independently represent one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted cyclic C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group and a phosphino group;
when at least two of X₁ to X₄ are each independently represented by CR₁₁, two adjacent R₁₁ may be optionally fused with each other to form one ring structure selected from a 5-membered carbon ring, a 5-membered hetero ring, a 6-membered carbon ring, and a 6-membered hetero ring;

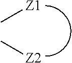

may represent a bidentate ligand;
m may be an integer of 1, 2 or 3, n may be an integer of 0, 1 or 2, and m+n may be an oxidation number of the metal M.

The organometallic compound according to example embodiments of the present disclosure may be represented by one selected from the group consisting of Chemical Formula II-1 and Chemical Formula II-2 based on a connection position between two rings of the isoquinoline ring structure of the ring structure (A) as the main ligand connected to the central coordination metal (M) in the Chemical Formula I. However, the present disclosure is not necessarily limited to the above structure. Moreover, each of the Chemical Formula II-1 and Chemical Formula II-2 specifies a structure of an ancillary ligand of the Chemical Formula I. However, the present disclosure is not necessarily limited thereto.

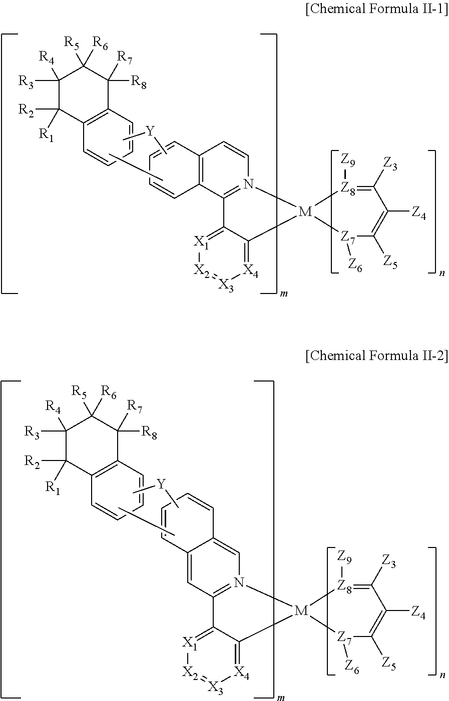

In the Chemical Formula II-1 and the Chemical Formula II-2,
each of Z₃ to Z₆ and Z₉ may independently represent one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
two adjacent substituents among Z₃ to Z₆ and Z₉ may form a C3-C20 carbon ring or a C3-C20 hetero ring;
each of Z₇ and Z₈ may be one selected from oxygen (O) and nitrogen (N).

In the organometallic compound according to example embodiments of the present disclosure, an ancillary ligand bound to the central coordination metal may be the bidentate ligand. The bidentate ligand may contain an electron donor. An ancillary ligand containing an electron donor may increase an electron density of the central coordination metal to reduce an energy of MLCT (metal to ligand charge transfer) and to increase the contribution percentage of ³MLCT to a T₁ state. As a result, the organic light-emitting diode including the organometallic compound of the present disclosure may achieve improved light-emitting characteristics such as high light-emitting efficiency and high external quantum efficiency.

Phosphorescence may be efficiently obtained at room temperature using an iridium (Ir) or platinum (Pt) metal complex with a large atomic number. Thus, in the organometallic compound according to example embodiments of the present disclosure, the central coordination metal (M) may be, for example, iridium (Ir) or platinum (Pt). In some embodiments, the central coordination metal (M) may be iridium (Ir). However, the disclosure is not limited thereto.

The compound represented by the Chemical Formula I of the present disclosure may include one selected from the group consisting of compounds 1 to 183. However, the disclosure is not limited thereto as long as the compound falls within the scope of the Chemical Formula I.

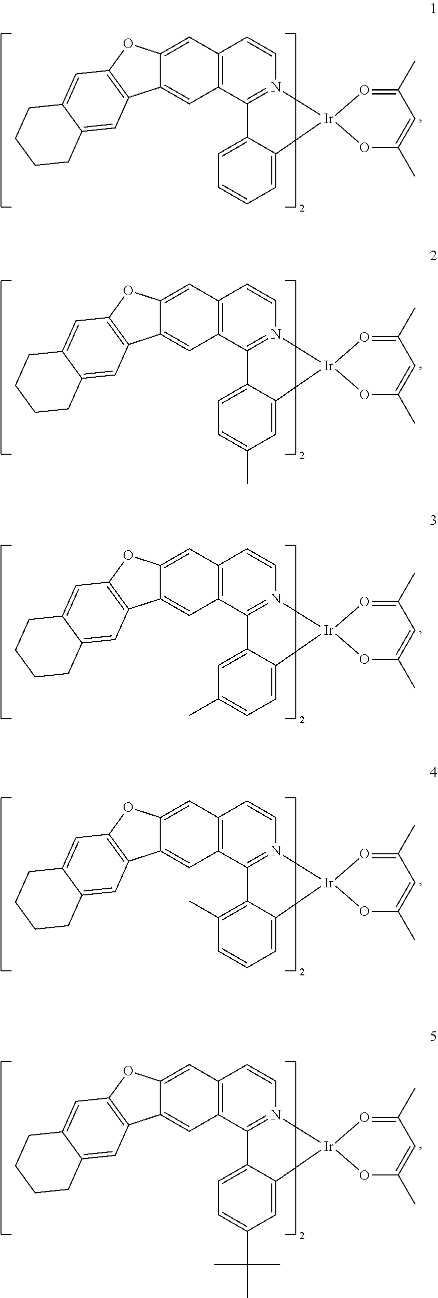

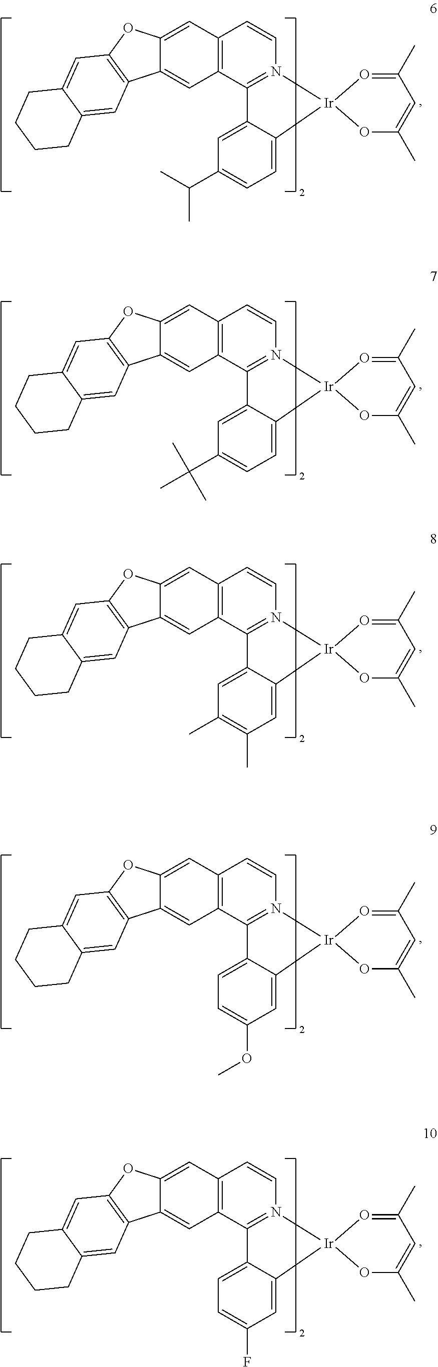

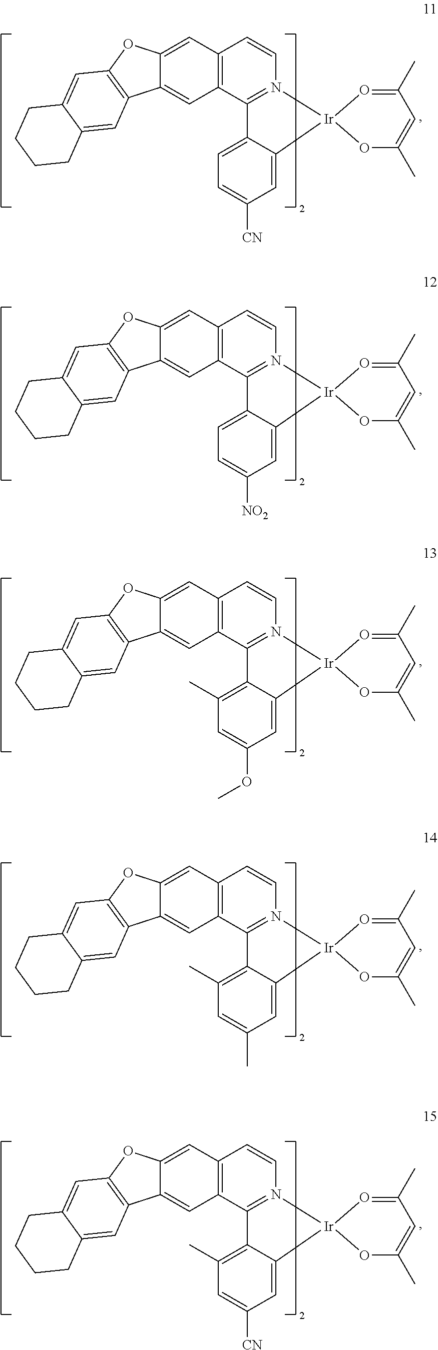

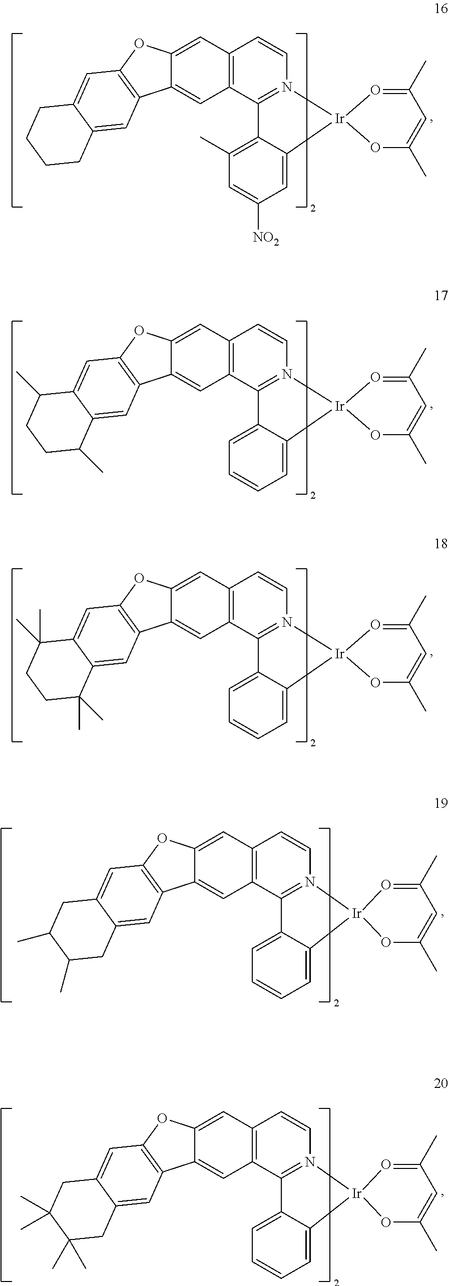

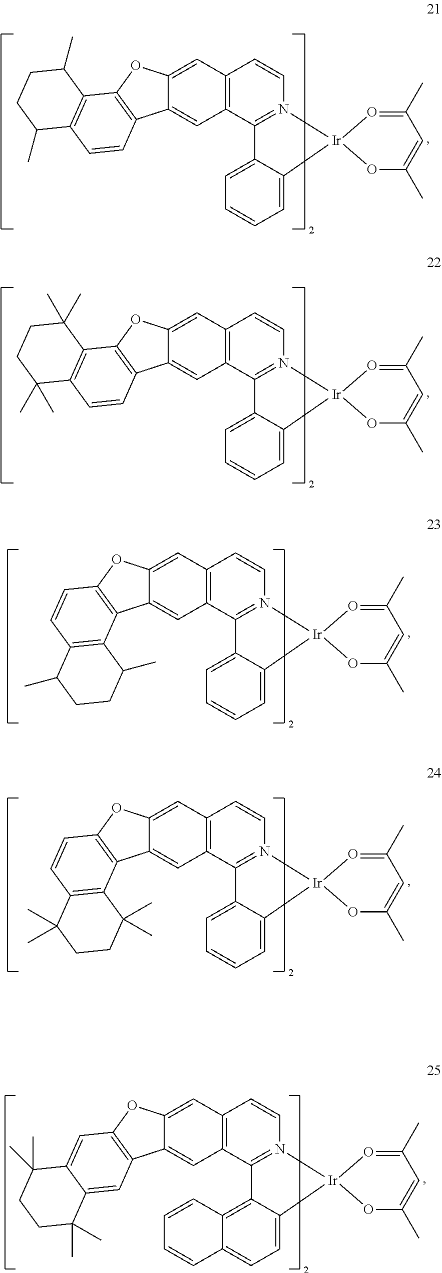

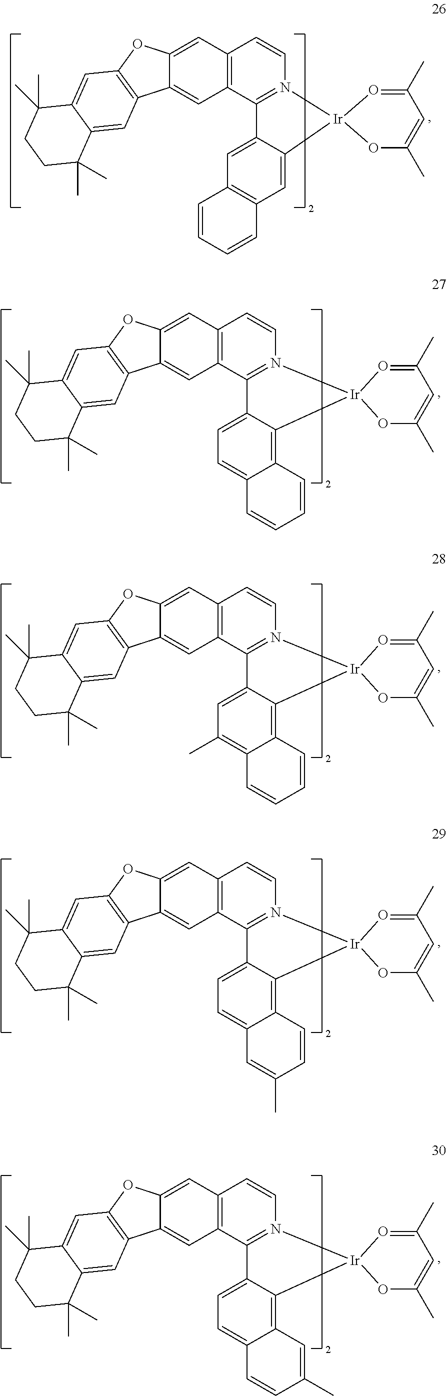

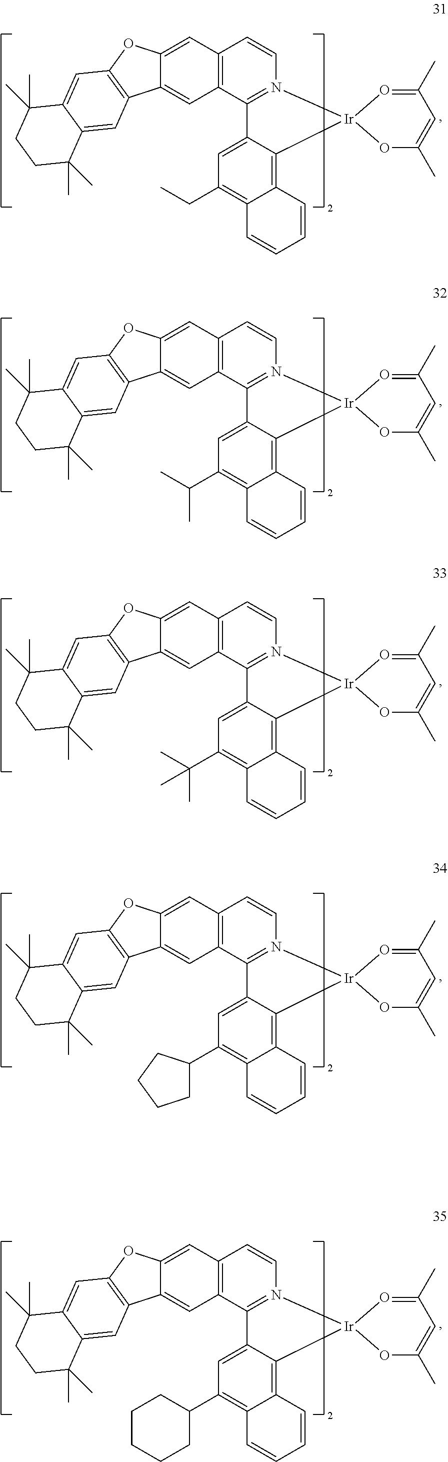

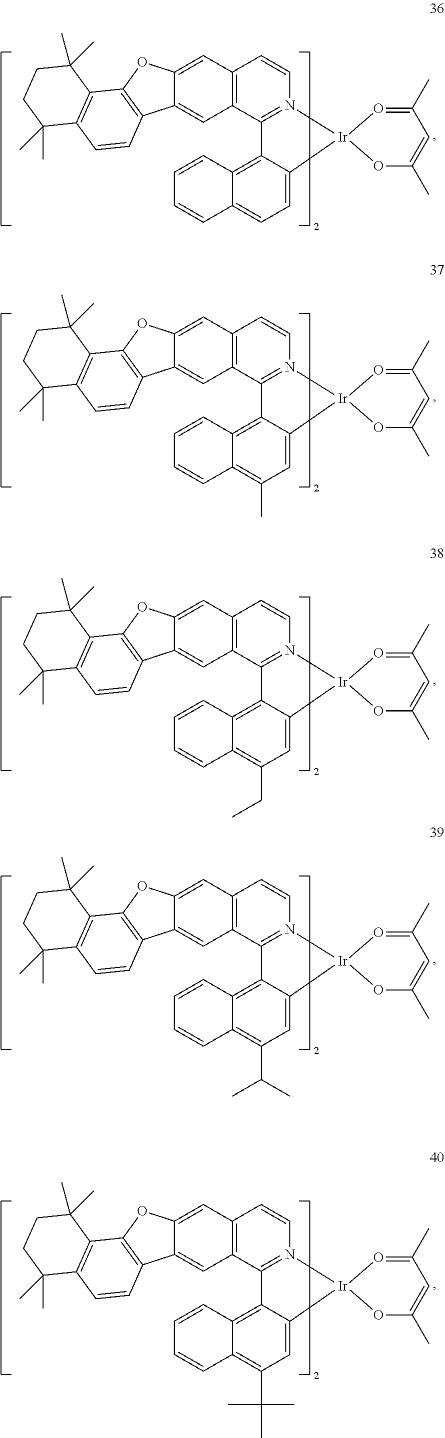

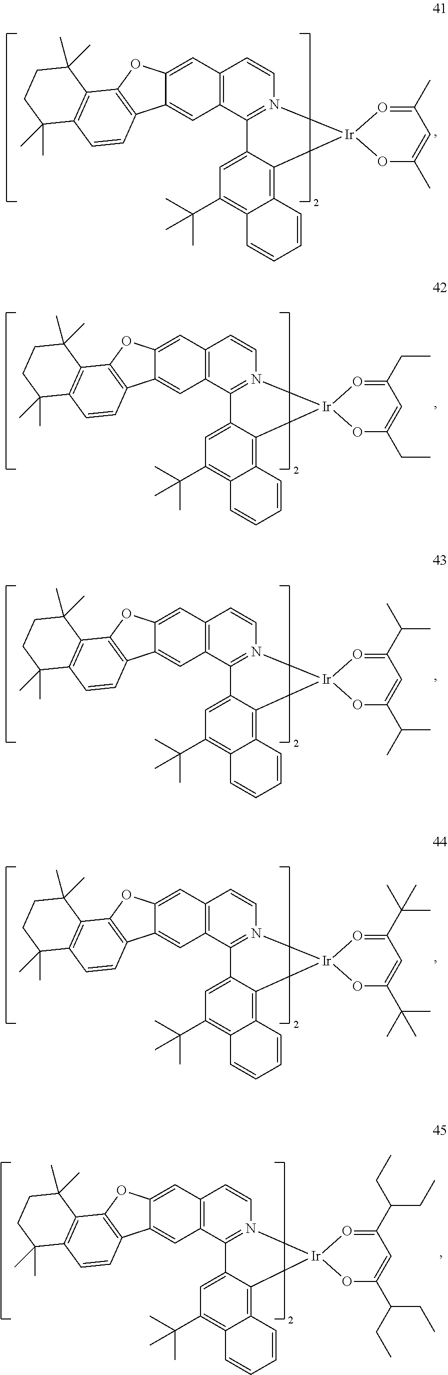

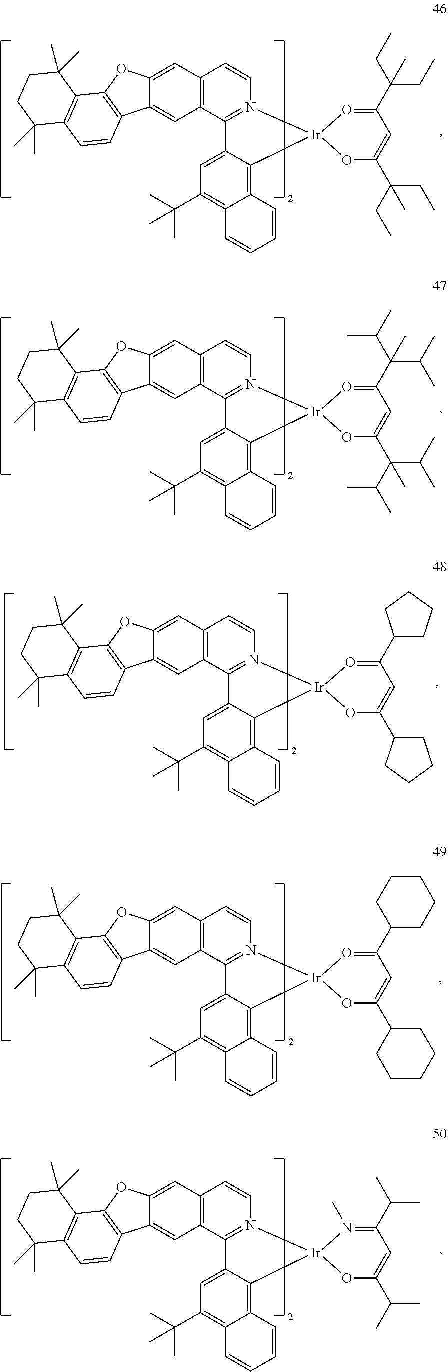

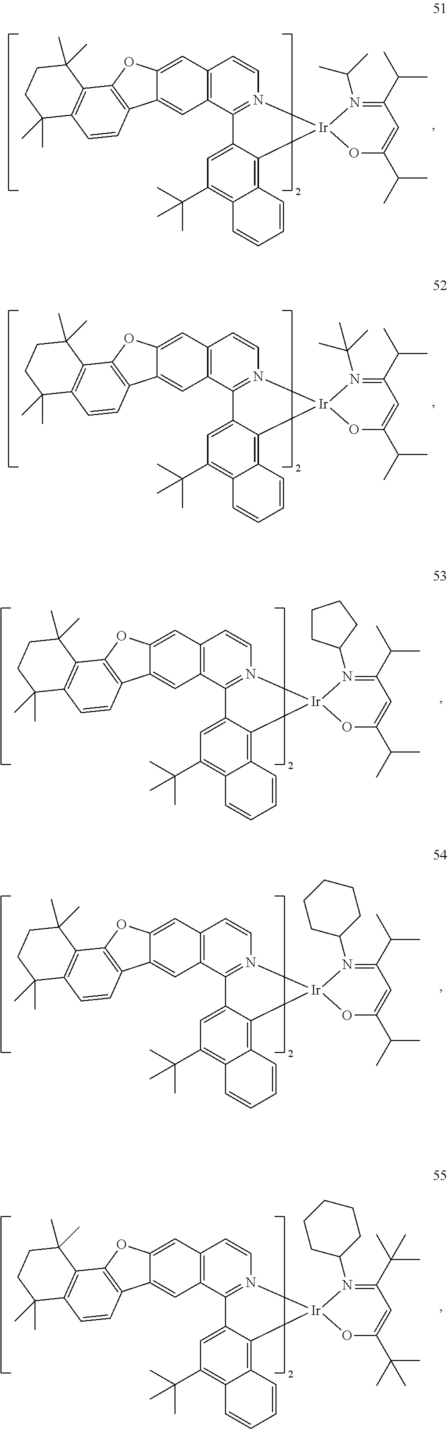

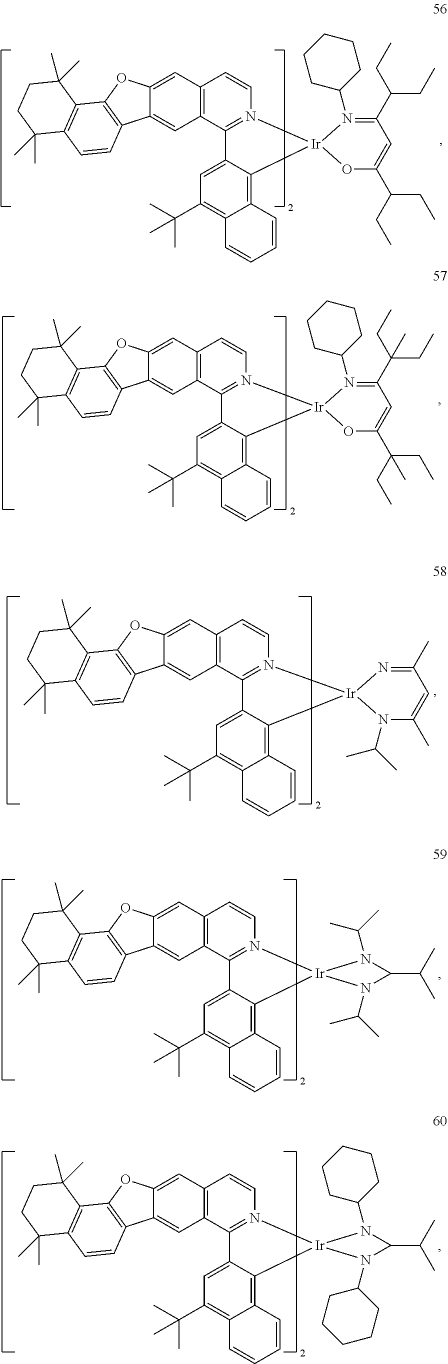

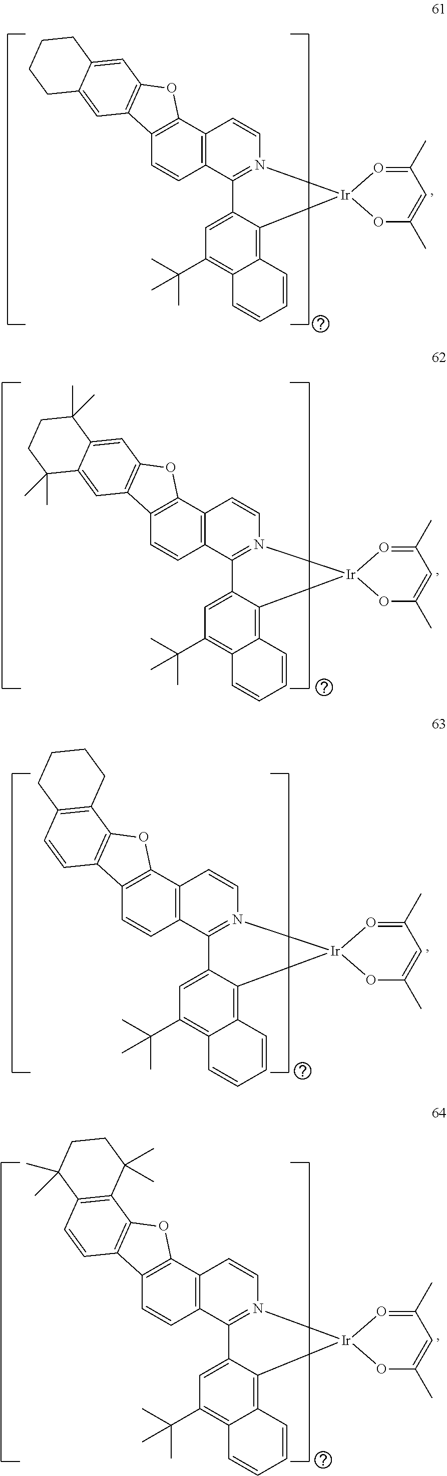

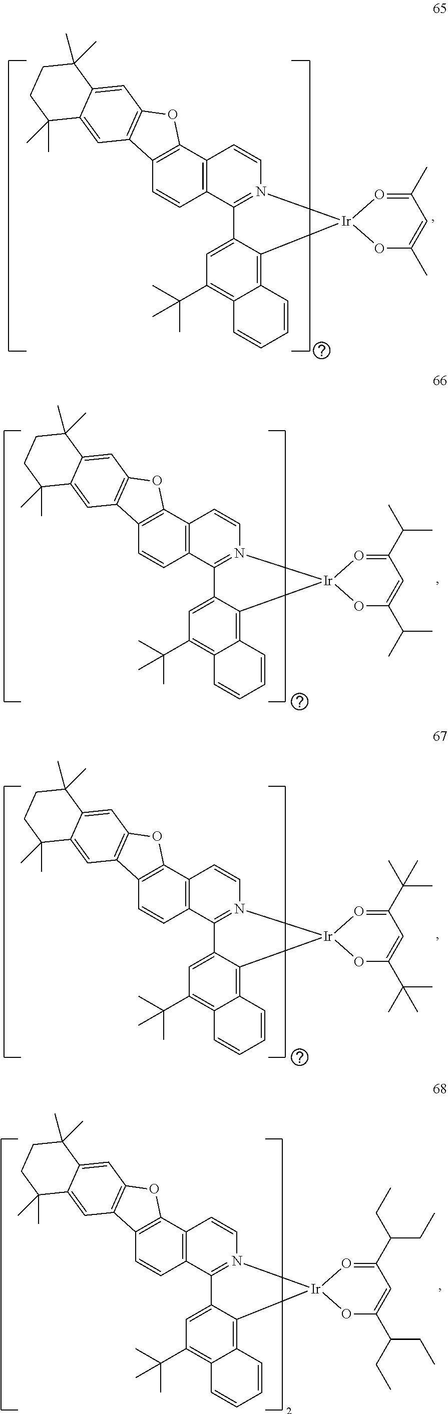

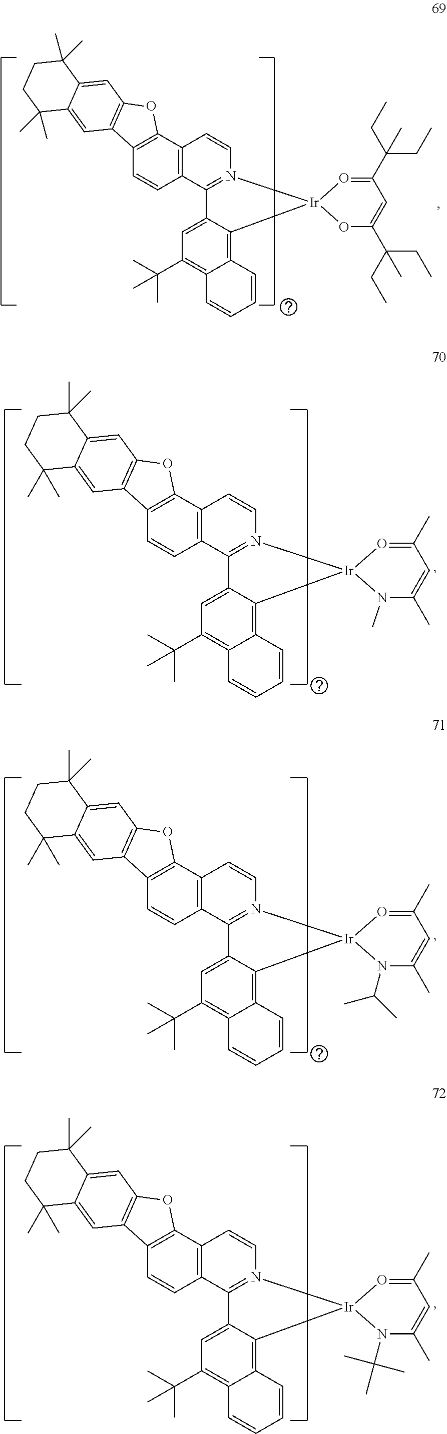

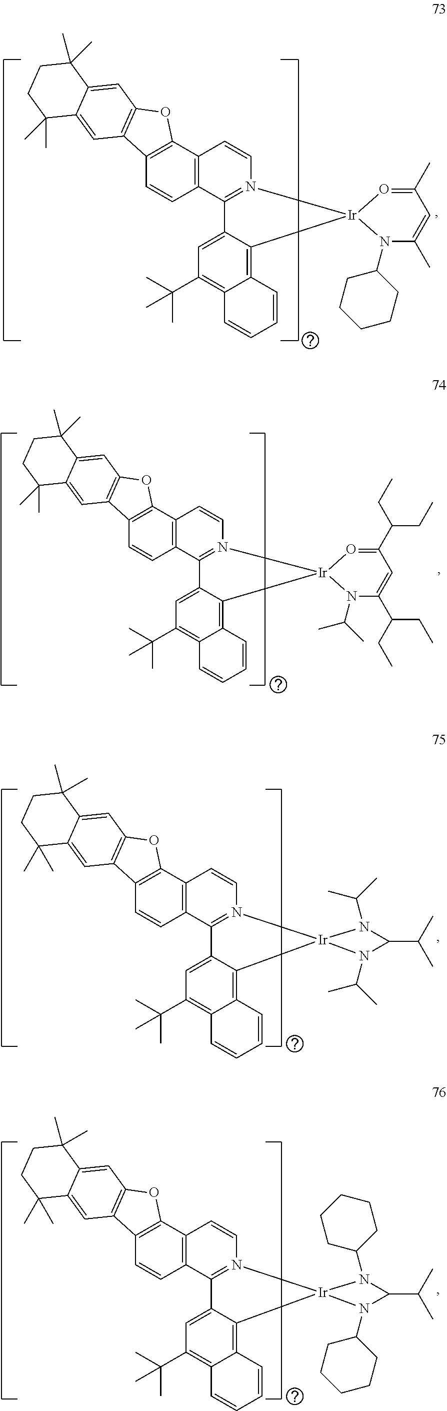

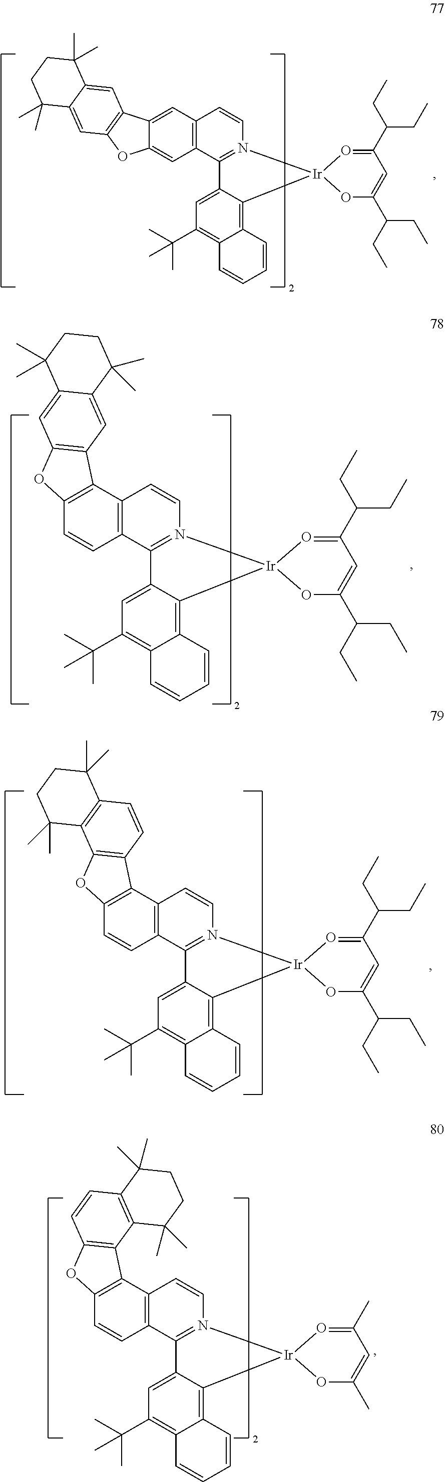

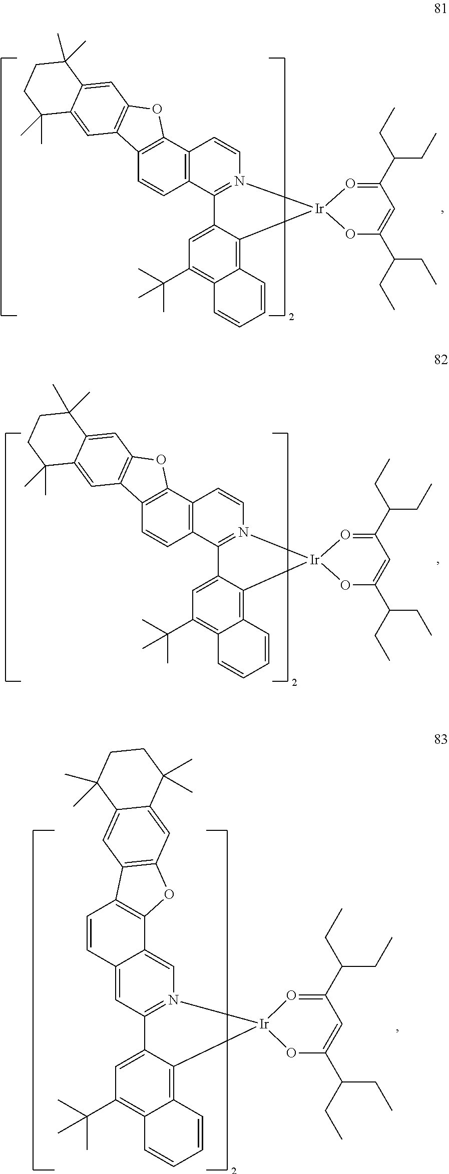

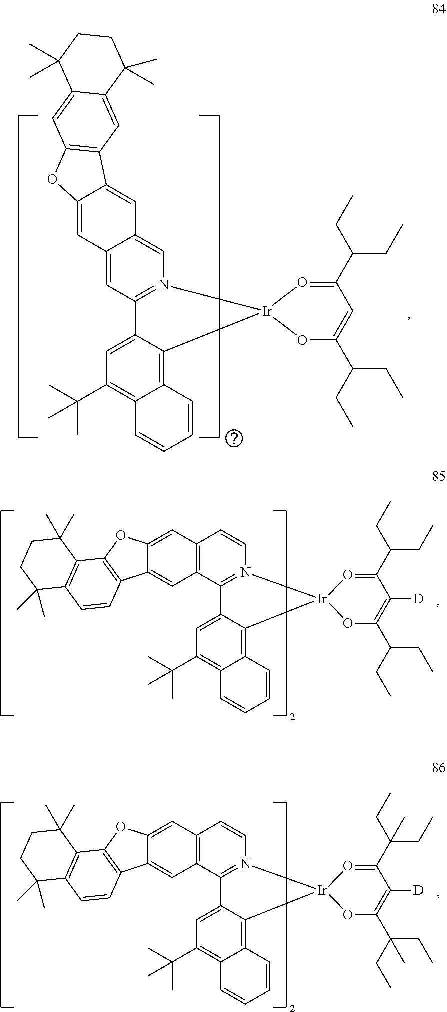

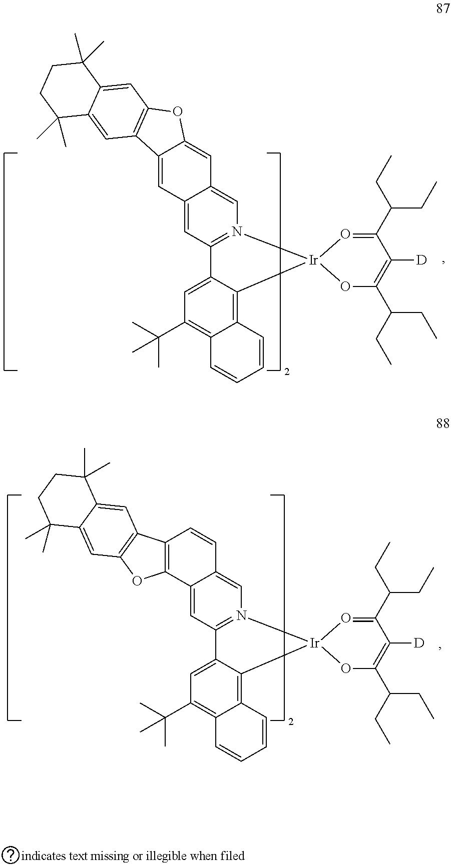

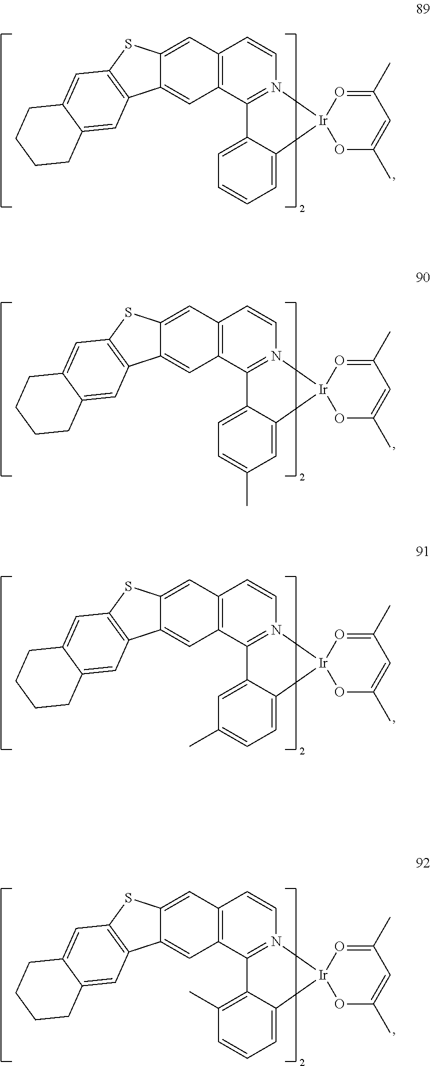

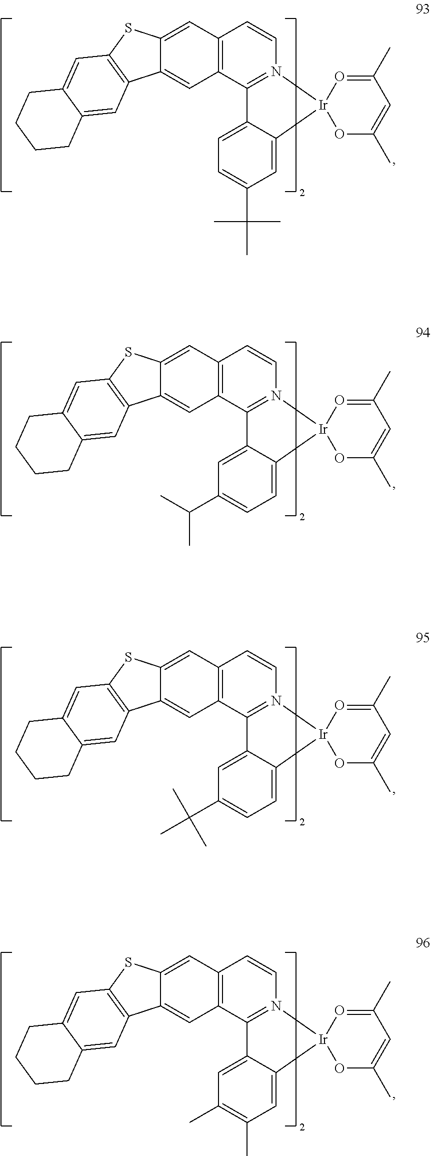

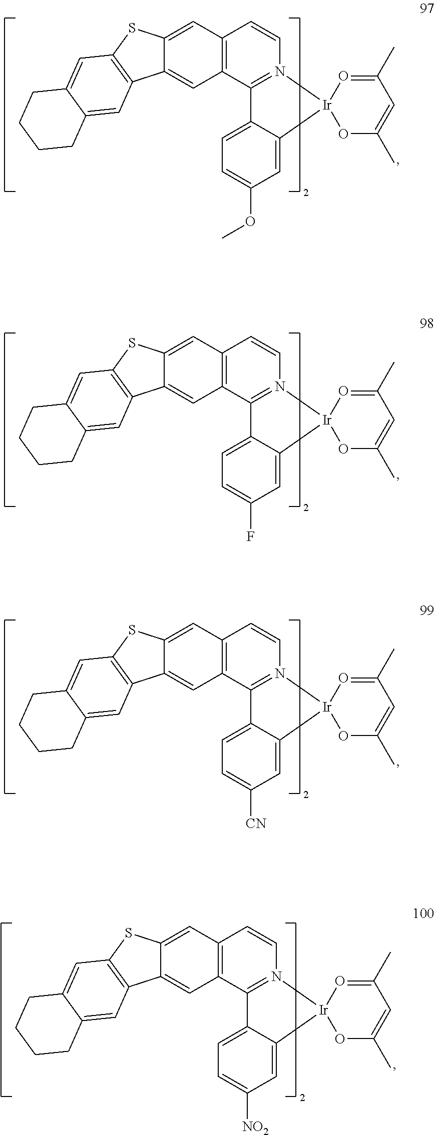

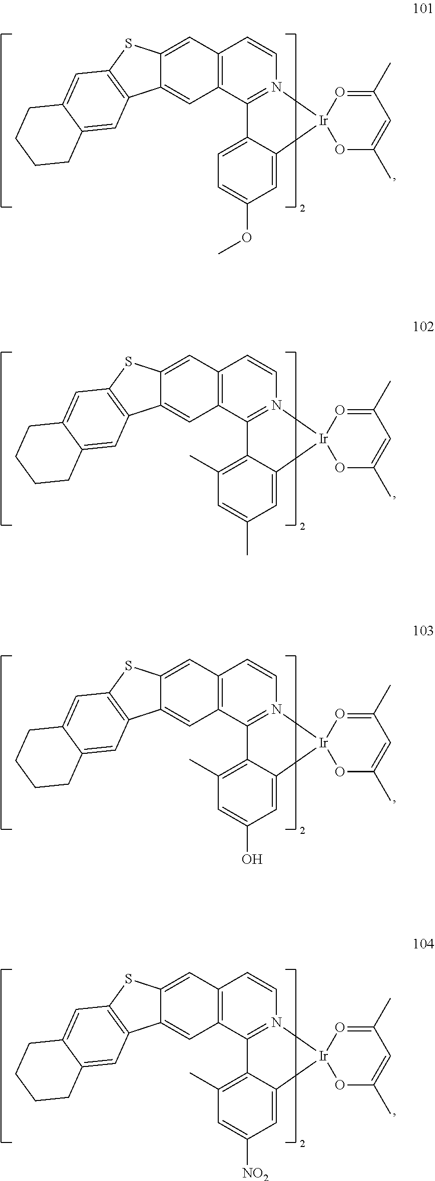

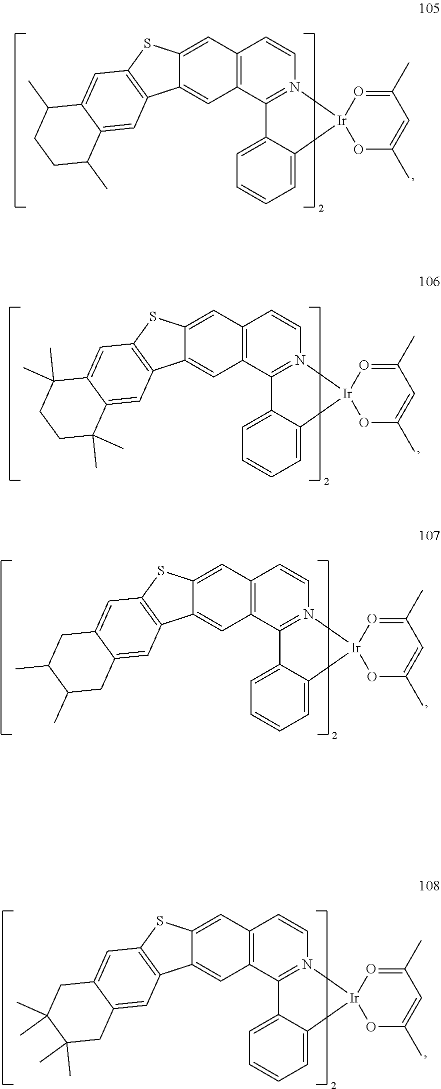

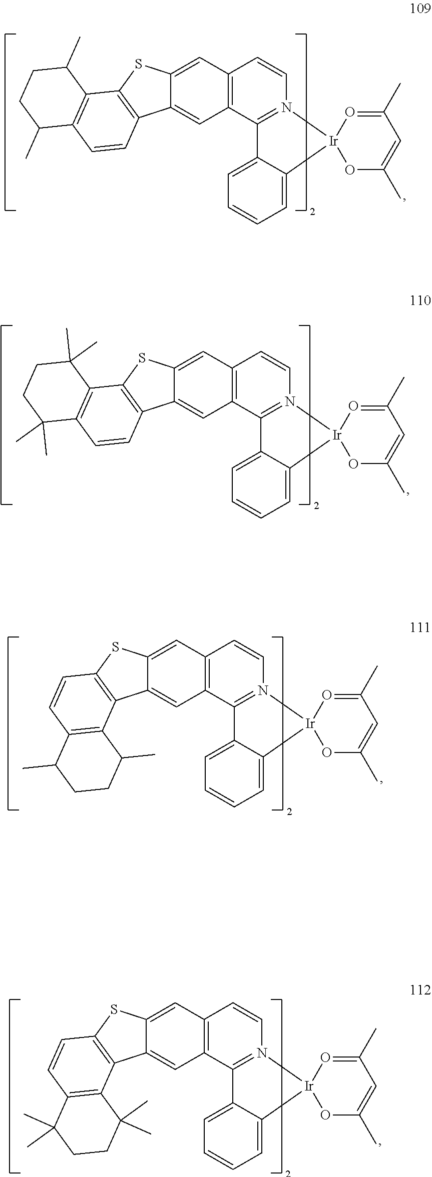

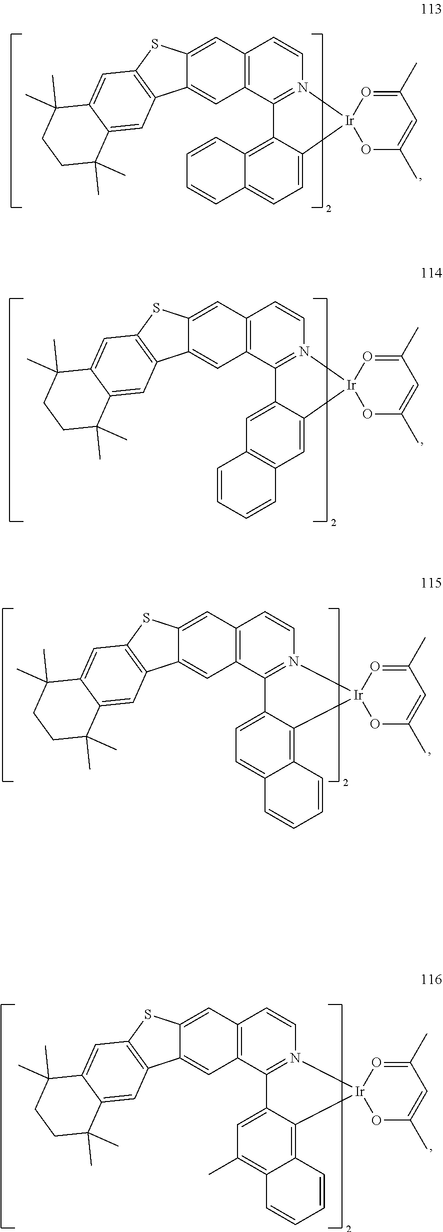

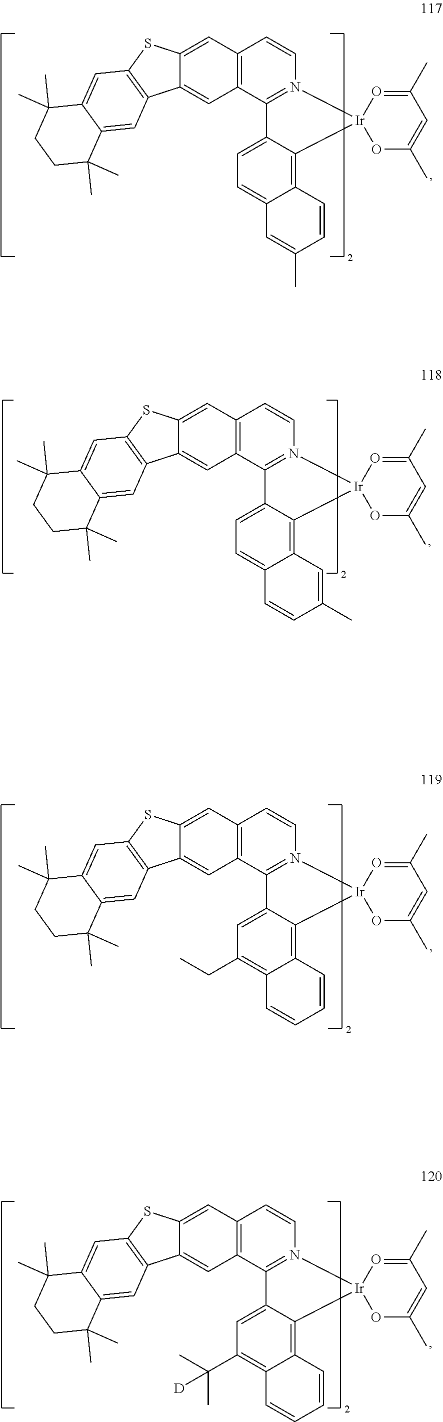

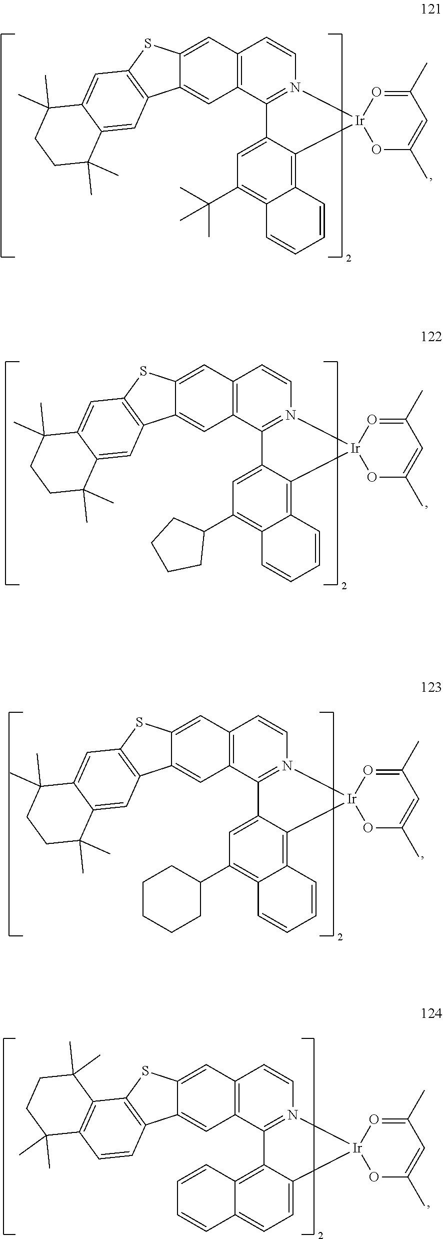

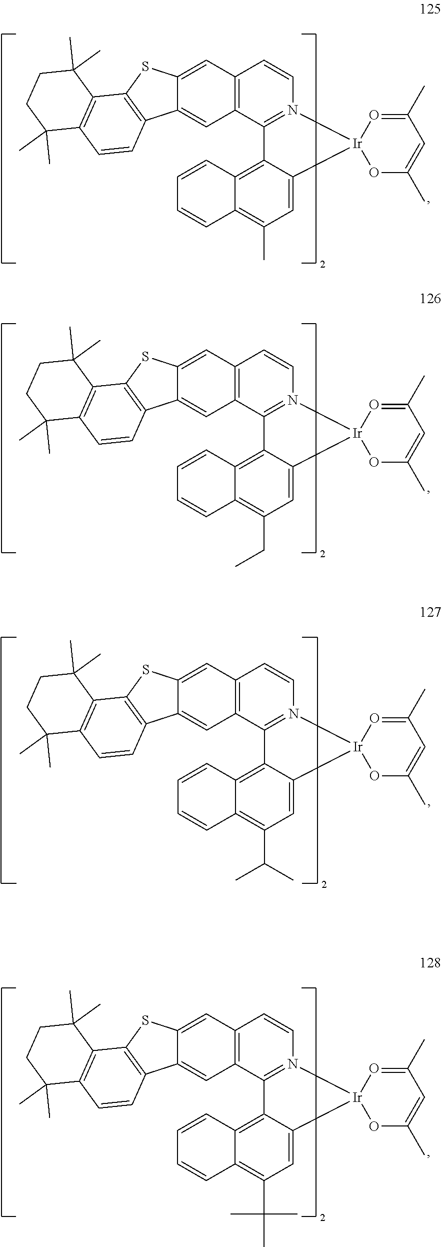

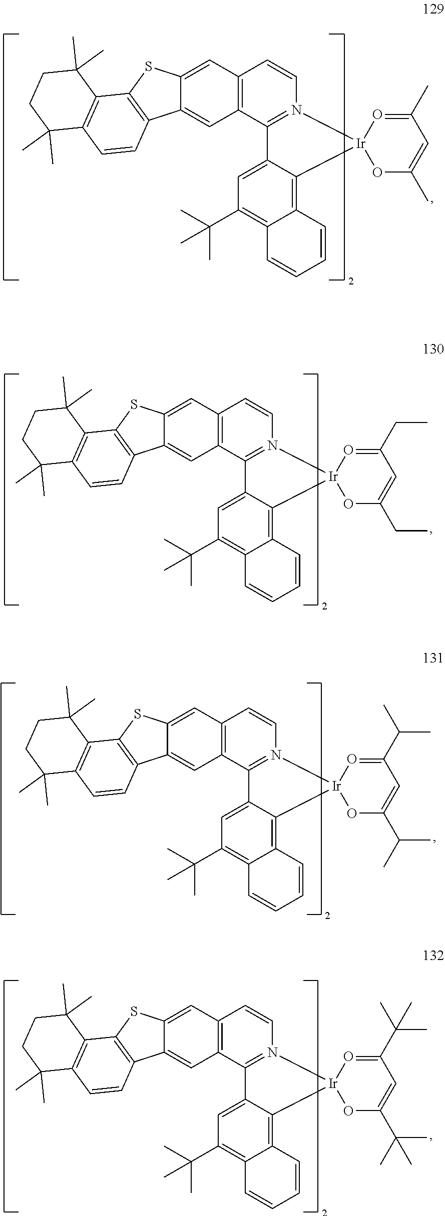

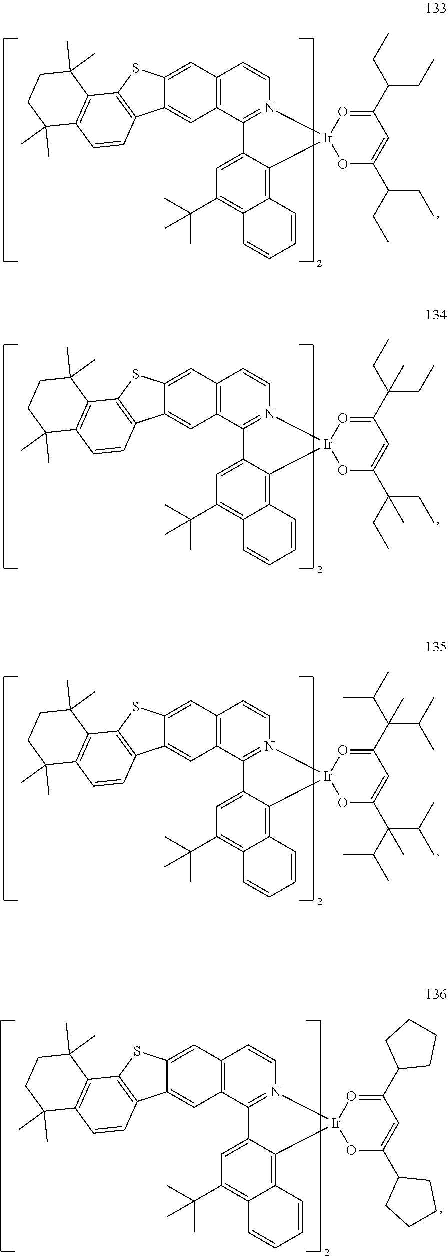

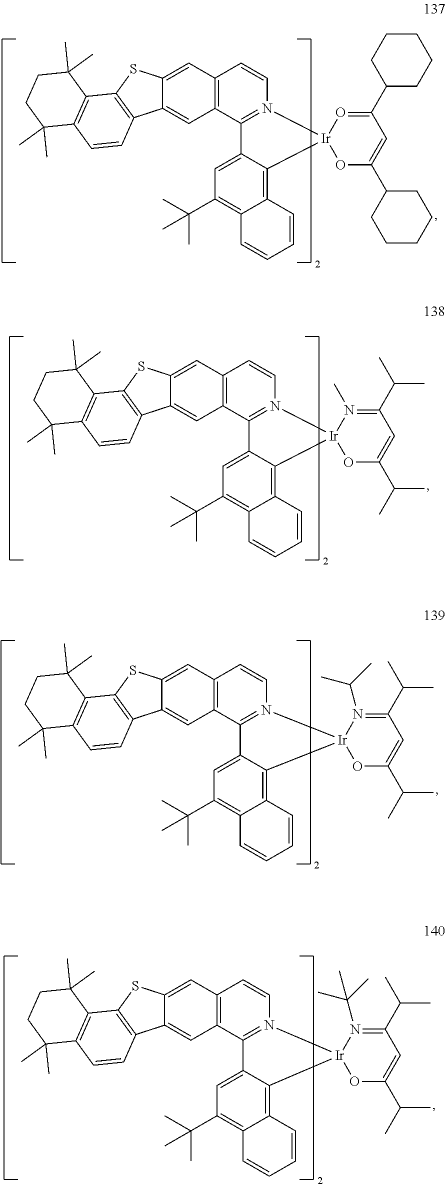

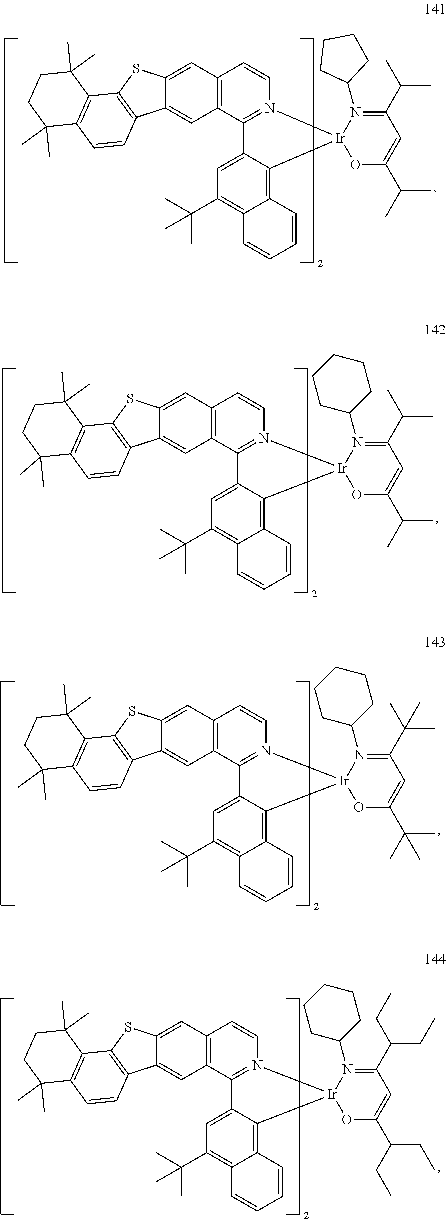

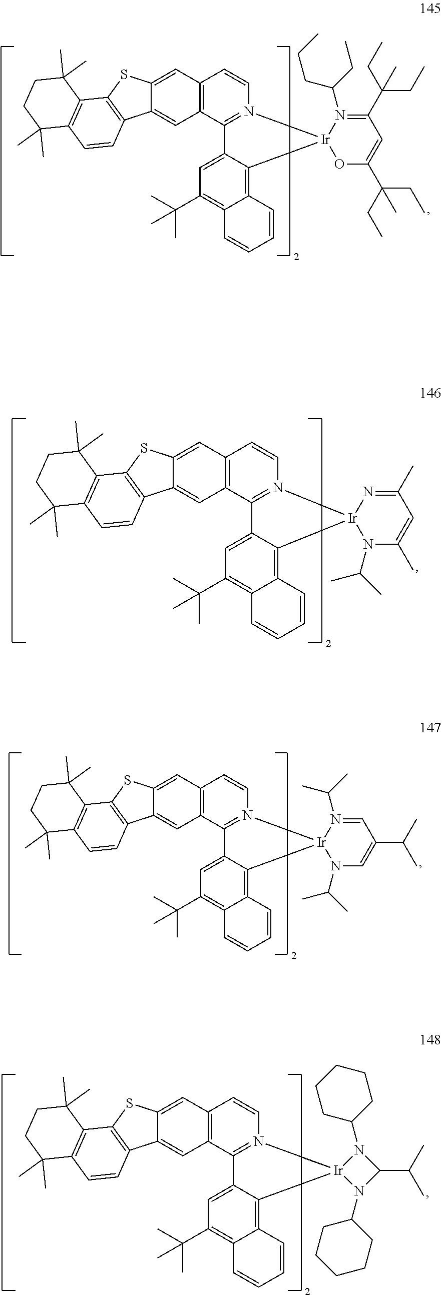

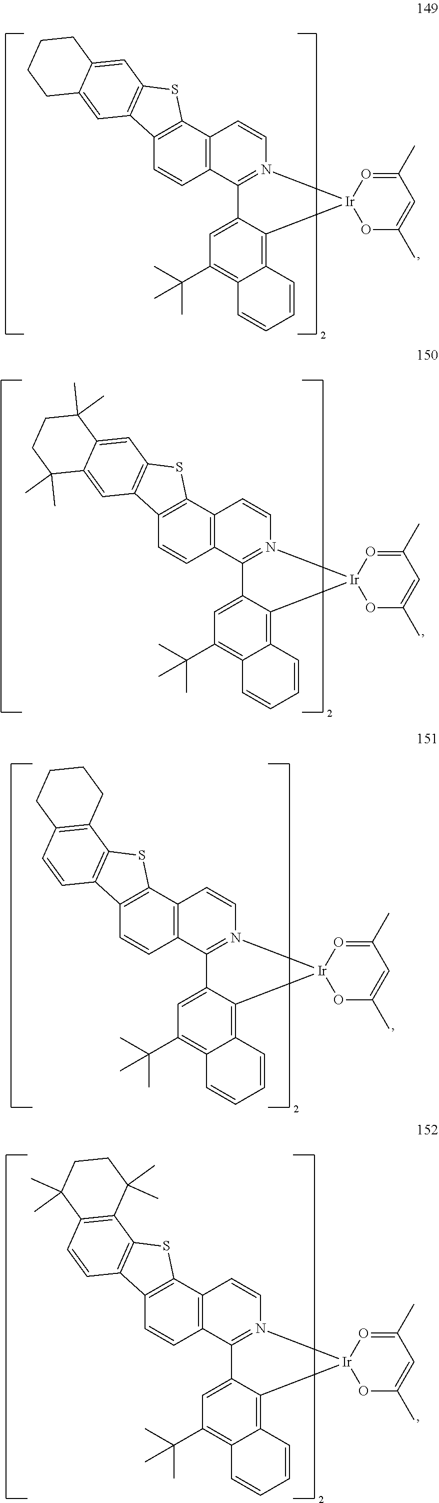

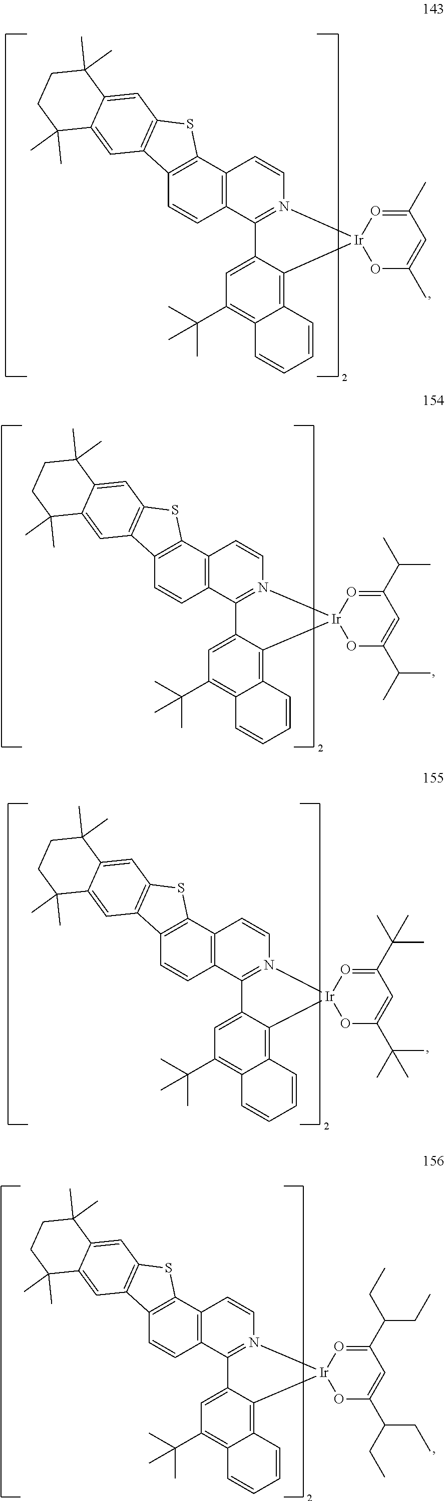

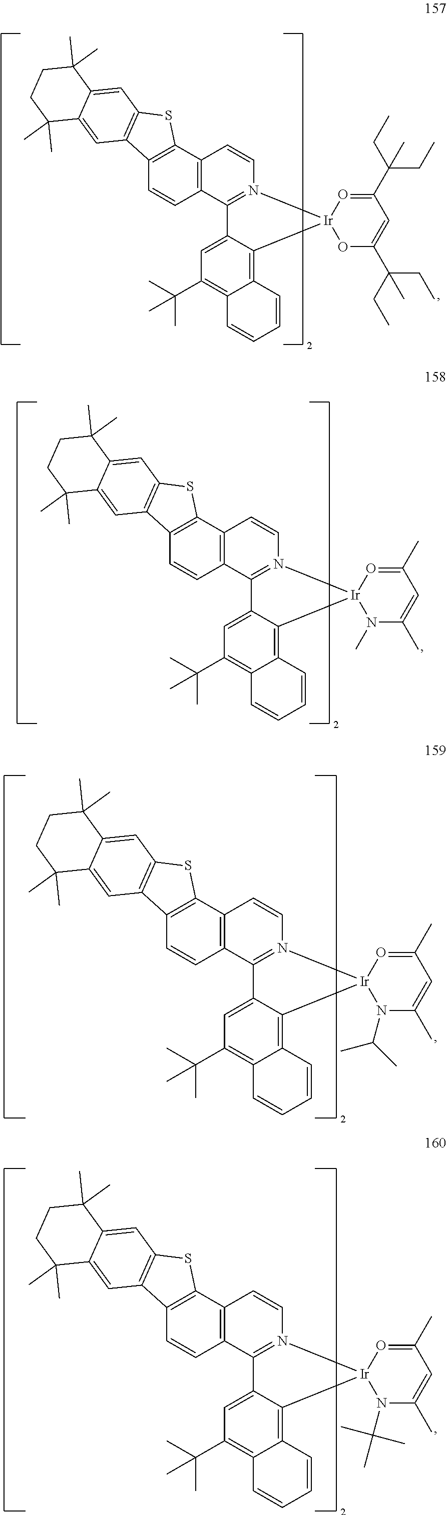

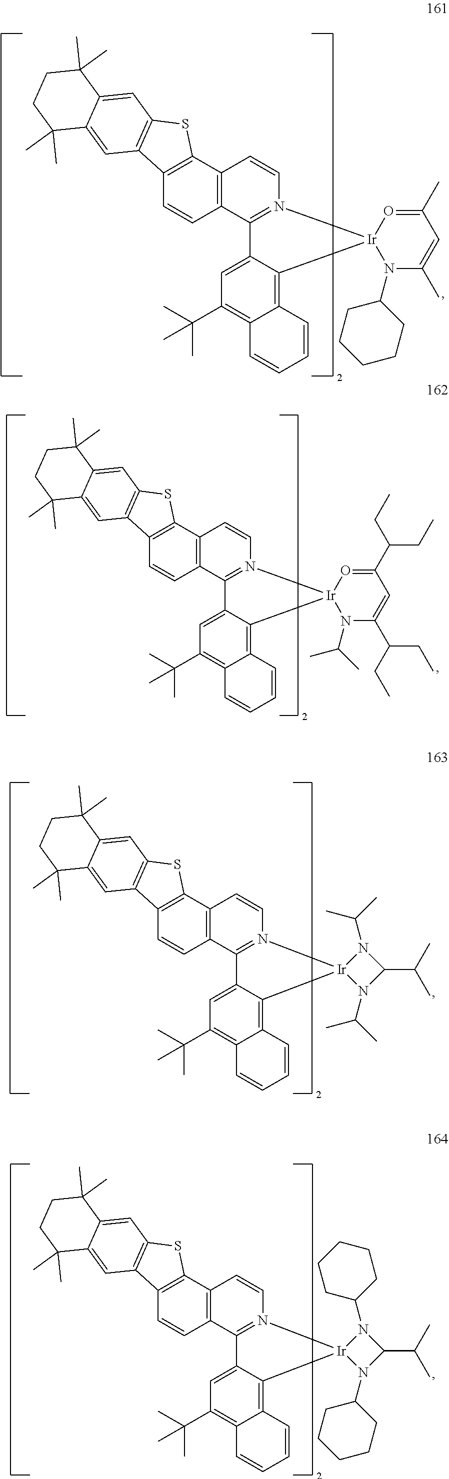

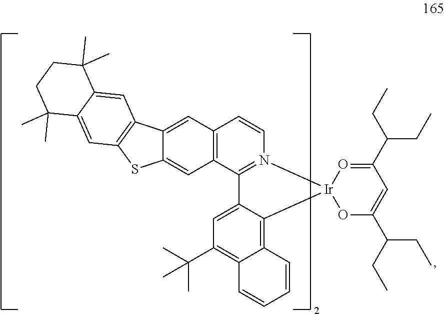

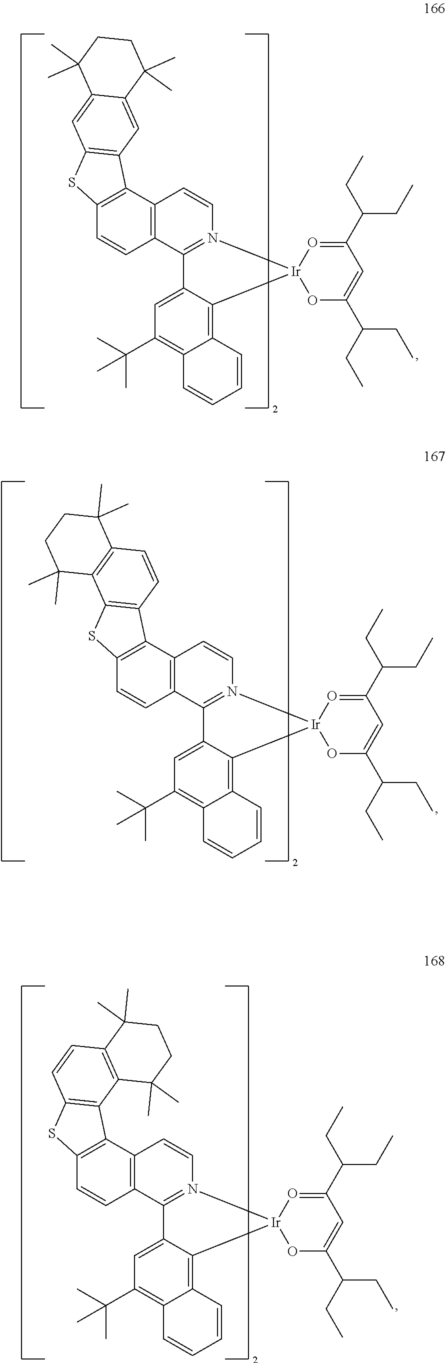

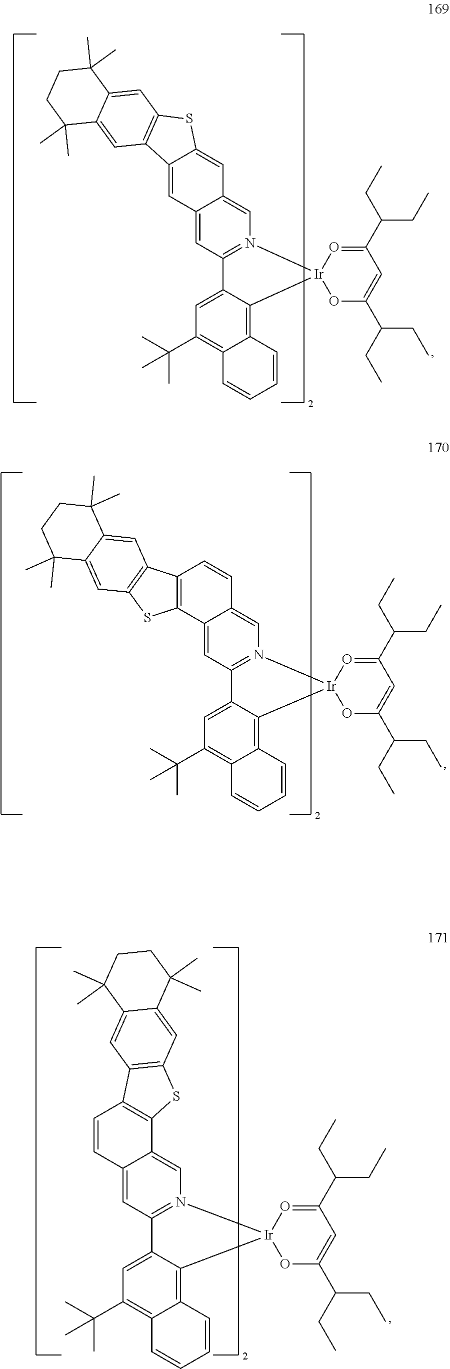

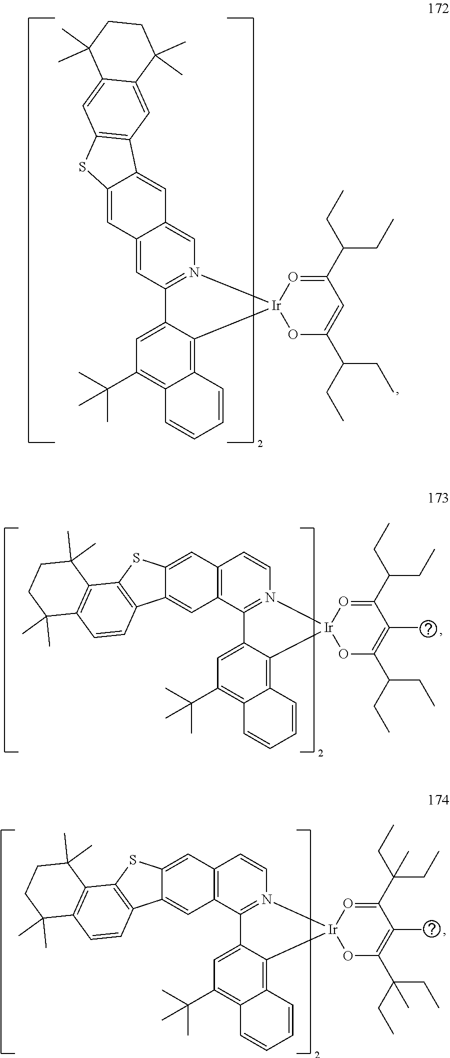

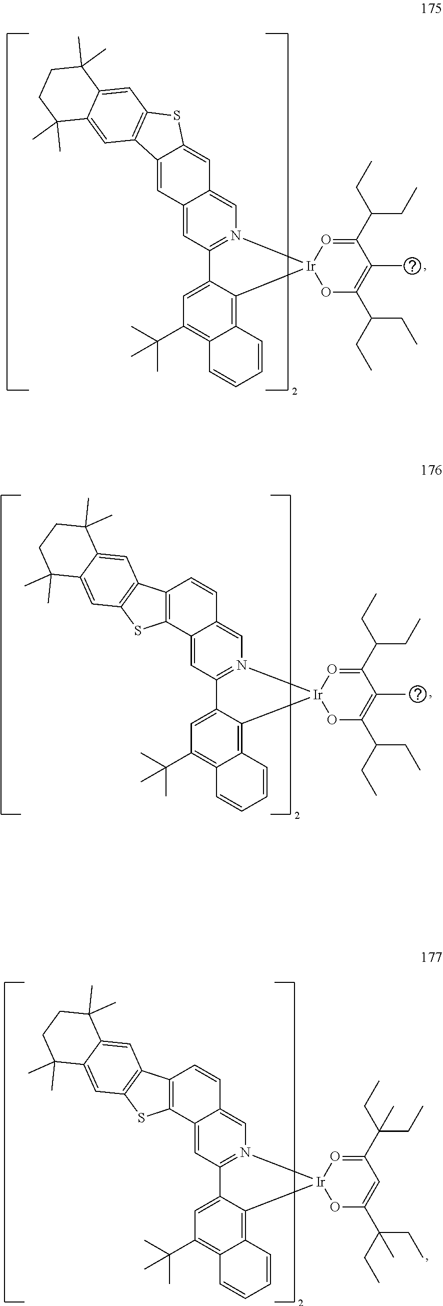

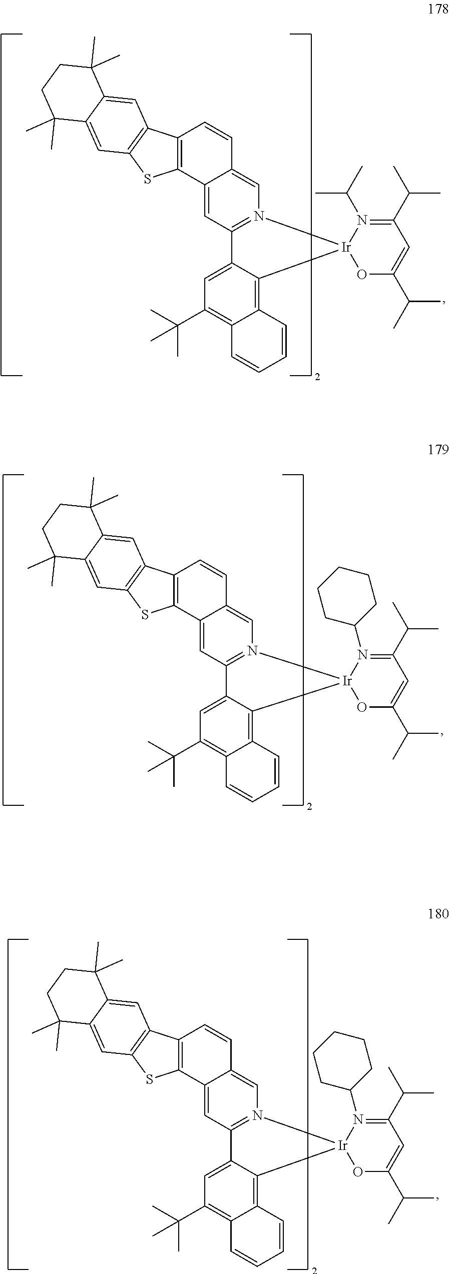

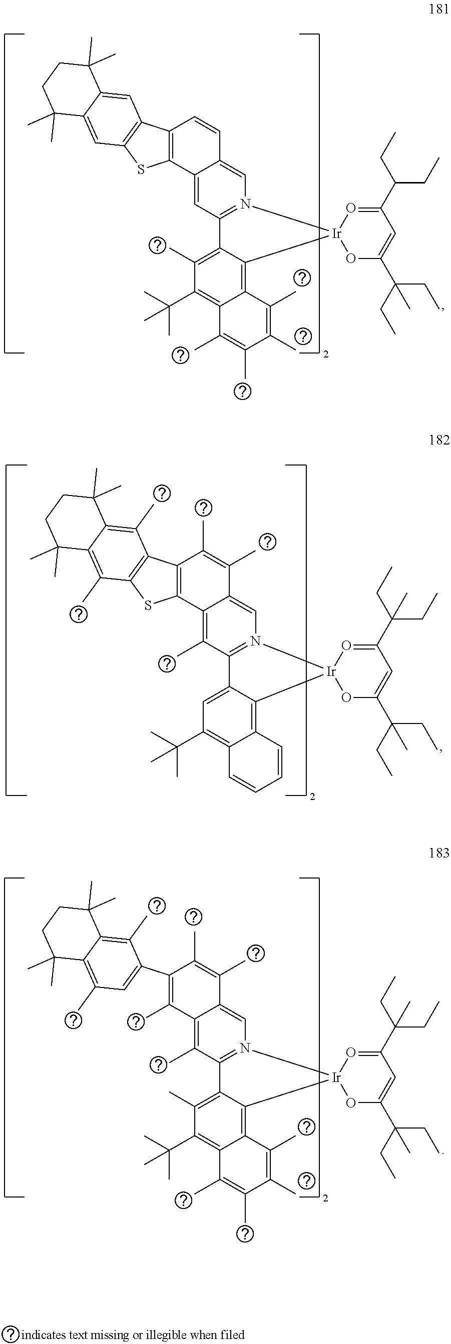

According to an example embodiment of the present disclosure, the organometallic compound represented by the Chemical Formula I of the present disclosure may be used as a dopant material achieving red phosphorescent or a green phosphorescence. In some embodiments, the organometallic compound represented by the Chemical Formula I of the present disclosure may be used as a dopant material achieving the red phosphorescence.

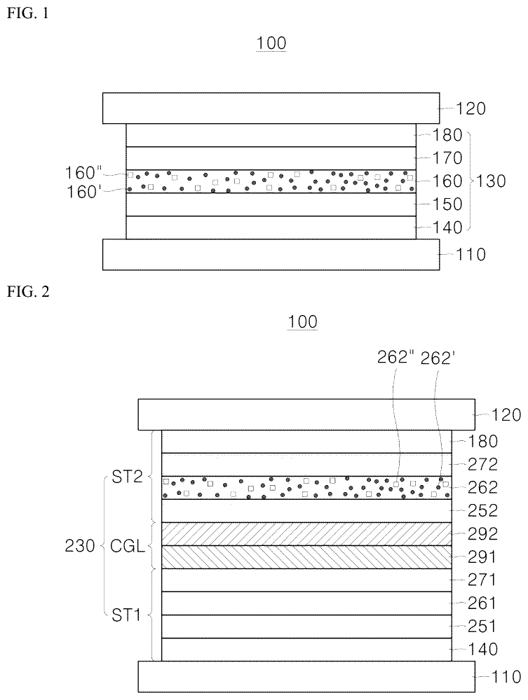

FIG. 1 is a cross-sectional view schematically illustrating an organic light-emitting diode in which a light-emitting layer contains an organometallic compound represented by the Chemical Formula I according to an example embodiment of the present disclosure. As illustrated in FIG. 1, according to an example embodiment of the present disclosure, an organic light-emitting diode 100 may include a first electrode 110; a second electrode 120 facing the first electrode 110; and an organic layer 130 disposed between the first electrode 110 and the second electrode 120. The organic layer 130 may include a light-emitting layer 160, and the light-emitting layer 160 may include a host material 160′ and dopants 160″. The dopants 160″ may be made of or include the organometallic compound represented by the Chemical Formula I. In addition, in the organic light-emitting diode 100, the organic layer 130 disposed between the first electrode 110 and the second electrode 120 may be formed by sequentially stacking a hole injection layer 140 (HIL), a hole transport layer 150, (HTL), a light emission layer 160 (EML), an electron transport layer 170 (ETL) and an electron injection layer 180 (EIL) on the first electrode 110. The second electrode 120 may be formed or disposed on the electron injection layer 180, and a protective layer (not shown) may be formed or disposed thereon.

Further, although not shown in FIG. 1, a hole transport auxiliary layer may be further added between the hole transport layer 150 and the light-emitting layer 160. The hole transport auxiliary layer may contain a compound having good hole transport properties, and may reduce a difference between HOMO energy levels of the hole transport layer 150 and the light-emitting layer 160 so as to adjust the hole injection properties. Thus, accumulation of holes at an interface between the hole transport auxiliary layer and the light-emitting layer 160 may be reduced, thereby reducing a quenching phenomenon in which excitons disappear at the interface due to polarons. Accordingly, deterioration of the element may be reduced and the element may be stabilized, thereby improving efficiency and lifespan thereof.

The first electrode 110 may act as a positive electrode, and may be made of or include ITO, IZO, tin-oxide, or zinc-oxide as a conductive material having a relatively large work function value. However, the present disclosure is not limited thereto.

The second electrode 120 may act as a negative electrode, and may include Al, Mg, Ca, or Ag as a conductive material having a relatively small work function value, or an alloy or combination thereof. However, the present disclosure is not limited thereto.

The hole injection layer 140 may be positioned between the first electrode 110 and the hole transport layer 150. The hole injection layer 140 may have a function of improving interface characteristics between the first electrode 110 and the hole transport layer 150, and may be selected from a material having appropriate conductivity. The hole injection layer 140 may include a compound selected from the group consisting of MTDATA, CuPc, TCTA, HATCN, TDAPB, PEDOT/PSS, and N1,N1′-([1,1′-biphenyl]-4,4′-diyl)bis(N1,N4,N4)-triphenylbenzene-1,4-diamine). In some embodiments, the hole injection layer 140 may include N1,N1′-([1,1′-biphenyl]-4,4′-diyl)bis(N1,N4,N4-triphenylbenzene-1,4-diamine). However, the present disclosure is not limited thereto.

The hole transport layer 150 may be positioned adjacent to the light-emitting layer and between the first electrode 110 and the light-emitting layer 160. A material of the hole transport layer 150 may include a compound selected from the group consisting of TPD, NPB, CBP, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, etc. In some embodiments, the material of the hole transport layer 150 may include NPB. However, the present disclosure is not limited thereto.

According to the present disclosure, the light-emitting layer 160 may be formed by doping a host material 160′ with the organometallic compound represented by the Chemical Formula I as a dopant 160″ to improve luminous efficiency of the diode 100. The dopant 160″ may be used as a green or red light-emitting material. In some embodiments, the dopant 160″ may be used as a red phosphorescent material.

A doping concentration of the dopant 160″ according to the present disclosure may be adjusted to be within a range of 1 to 30% by weight based on a total weight of the host material 160′. However, the disclosure is not limited thereto. For example, the doping concentration may be in a range of 2 to 20 wt %, for example, 3 to 15 wt %, for example, 5 to 10 wt %, for example, 3 to 8 wt %, for example, 2 to 7 wt %, for example, 5 to 7 wt %, or for example, 5 to 6 wt %.

The light-emitting layer 160 according to the present disclosure contains the host material 160′ which may be known in the art and may achieve an effect of the present disclosure while the layer 160 contains the organometallic compound represented by the Chemical Formula I as the dopant 160″. For example, in accordance with the present disclosure, the host material 160′ may include a compound containing a carbazole group. In some embodiments, the host material 160′ may include one host material selected from the group consisting of CBP (carbazole biphenyl), mCP (1,3-bis(carbazol-9-yl), and the like. However, the disclosure is not limited thereto.

Further, the electron transport layer 170 and the electron injection layer 180 may be sequentially stacked between the light-emitting layer 160 and the second electrode 120. A material of the electron transport layer 170 may exhibit high electron mobility such that electrons may be stably supplied to the light-emitting layer under smooth electron transport.

For example, the material of the electron transport layer 170 may be known in the art and may include a compound selected from the group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4-oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzothiazole, and 2-(4-(9,10-di(naphthalen-2-yl)anthracen-2-yl)phenyl)-1-phenyl-1H-benzo[d]imidazole. In some embodiments, the material of the electron transport layer 170 may include 2-(4-(9,10-di(naphthalen-2-yl)anthracen-2-yl)phenyl)-1-phenyl-1H-benzo[d]imidazole. However, the present disclosure is not limited thereto.

The electron injection layer 180 may facilitate electron injection. A material of the electron injection layer may be known in the art and may include a compound selected from the group consisting of Alq3 (tris(8-hydroxyquinolino)aluminum), PBD, TAZ, spiro-PBD, BAlq, SAlq, etc. However, the present disclosure is not limited thereto. Alternatively, the electron injection layer 180 may be made of or include a metal compound. The metal compound may include, for example, one or more selected from the group consisting of Liq, LiF, NaF, KF, RbF, CsF, FrF, BeF₂, MgF₂, CaF₂, SrF₂, BaF₂ and RaF₂. However, the present disclosure is not limited thereto.

The organic light-emitting diode according to the present disclosure may be embodied as a white light-emitting diode having a tandem structure. The tandem organic light-emitting diode according to example embodiments of the present disclosure may include a structure in which adjacent two or more light-emitting stacks are connected to each other via a charge generation layer (CGL). The organic light-emitting diode may include at least two light-emitting stacks disposed on a substrate, and the light-emitting layer disposed between the first and second electrodes to emit light in a specific wavelength band. Each of the at least two light-emitting stacks may include first and second electrodes facing each other. The plurality of light-emitting stacks may emit light of same or different colors. In addition, one or more light-emitting layers may be included in one light-emitting stack, and the one or more light-emitting layers may emit light of same or different colors.

In example embodiments, the light-emitting layer included in at least one of the plurality of light-emitting stacks may contain the organometallic compound represented by the Chemical Formula I according to the present disclosure as the dopant. Adjacent light-emitting stacks in the tandem structure may be connected to each other via the charge generation layer CGL including an N-type charge generation layer and a P-type charge generation layer.

FIG. 2 is a cross-sectional view schematically illustrating an organic light-emitting diode having a tandem structure having two light-emitting stacks and containing an organometallic compound represented by the Chemical Formula I according to an example embodiment of the present disclosure.

As illustrated in FIG. 2, an organic light-emitting diode 100 according to the present disclosure include a first electrode 110 and a second electrode 120 facing each other, and an organic layer 230 positioned between the first electrode 110 and the second electrode 120. The organic layer 230 may be positioned between the first electrode 110 and the second electrode 120 and may include a first light-emitting stack ST1 including a first light-emitting layer 261, a second light-emitting stack ST2 positioned between the first light-emitting stack ST1 and the second electrode 120 and including a second light-emitting layer 262, and the charge generation layer CGL positioned between the first and second light-emitting stacks ST1 and ST2. The charge generation layer CGL may include an N-type charge generation layer 291 and a P-type charge generation layer 292. At least one of the first light-emitting layer 261 and the second light-emitting layer 262 may contain the organometallic compound represented by the Chemical Formula I according to the present disclosure as the dopants. For example, as illustrated in FIG. 2, the second light-emitting layer 262 of the second light-emitting stack ST2 may contain a host material 262′, and dopants 262″ made of or include the organometallic compound represented by the Chemical Formula I doped therein. Although not shown in FIG. 2, each of the first and second light-emitting stacks ST1 and ST2 may further include, in addition to each of the first light-emitting layer 261 and the second light-emitting layer 262, an additional light-emitting layer.

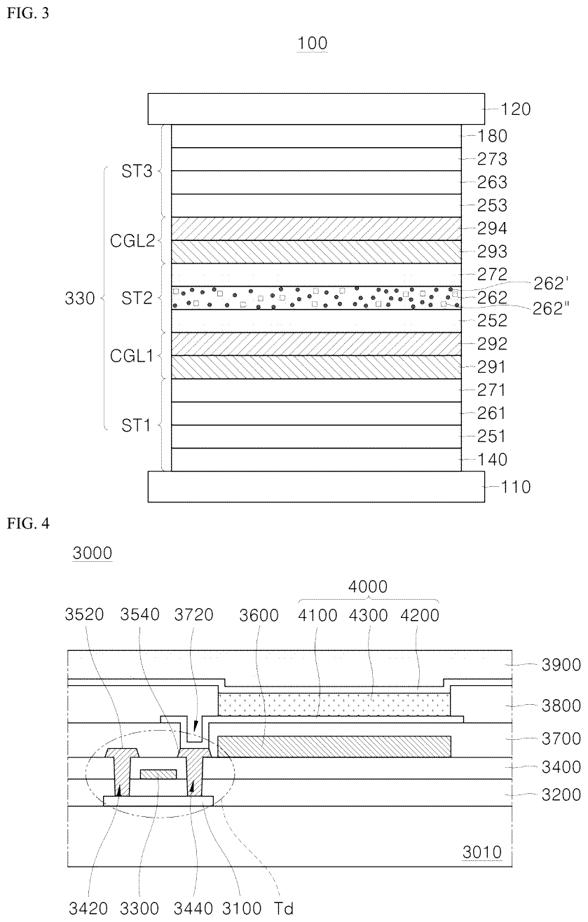

FIG. 3 is a cross-sectional view schematically illustrating an organic light-emitting diode having a tandem structure having three light-emitting stacks and containing an organometallic compound represented by the Chemical Formula I according to an example embodiment of the present disclosure.

As illustrated in FIG. 3, the organic light-emitting diode 100 according to the present disclosure include the first electrode 110 and the second electrode 120 facing each other, and an organic layer 330 positioned between the first electrode 110 and the second electrode 120. The organic layer 330 may be positioned between the first electrode 110 and the second electrode 120 and may include the first light-emitting stack ST1 including the first light-emitting layer 261, the second light-emitting stack ST2 including the second light-emitting layer 262, a third light-emitting stack ST3 including a third light-emitting layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 may include a N-type charge generation layers 291 and a P-type charge generation layer 292. The second charge generation layer CGL2 may include a N-type charge generation layers 293 and a P-type charge generation layer 294. At least one of the first light-emitting layer 261, the second light-emitting layer 262, and the third light-emitting layer 263 may contain the organometallic compound represented by the Chemical Formula I according to the present disclosure as the dopants. For example, as illustrated in FIG. 3, the second light-emitting layer 262 of the second light-emitting stack ST2 may contain the host material 262′, and the dopants 262″ made of or include the organometallic compound represented by the Chemical Formula I doped therein. Although not shown in FIG. 3, each of the first, second and third light-emitting stacks ST1, ST2 and ST3 may further include an additional light-emitting layer, in addition to each of the first light-emitting layer 261, the second light-emitting layer 262 and the third light-emitting layer 263.

Furthermore, an organic light-emitting diode according to an embodiment of the present disclosure may include a tandem structure in which four or more light-emitting stacks and three or more charge generating layers are disposed between the first electrode and the second electrode.

The organic light-emitting diode according to the present disclosure may be used as a light-emitting element of each of an organic light-emitting display device and a lighting device. FIG. 4 is a cross-sectional view schematically illustrating an organic light-emitting display device including an organic light-emitting diode according to an example embodiment of the present disclosure. FIG. 4 illustrates an organic light-emitting display device including the organic light-emitting diode according to some example embodiments of the present disclosure as a light-emitting element thereof.

As illustrated in FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

Although not shown explicitly in FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed or disposed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 may be formed or disposed on the substrate 3010 and may be made of or include an oxide semiconductor material or polycrystalline silicon. When the semiconductor layer 3100 is made of or include an oxide semiconductor material, a light-shielding pattern (not shown) may be formed or disposed under the semiconductor layer 3100. The light-shielding pattern may prevent or reduce light from being incident into the semiconductor layer 3100 to prevent the semiconductor layer 3100 from being deteriorated due to the light. Alternatively, the semiconductor layer 3100 may be made of or include polycrystalline silicon. In some example embodiments, both edges of the semiconductor layer 3100 may be doped with impurities.

The gate insulating layer 3200 made of or include an insulating material is formed or disposed over an entirety of a surface of the substrate 3010 and on the semiconductor layer 3100. The gate insulating layer 3200 may be made of or include an inorganic insulating material such as silicon oxide or silicon nitride.

The gate electrode 3300 made of or include a conductive material such as a metal is formed or disposed on the gate insulating layer 3200 and corresponds to a center of the semiconductor layer 3100. The gate electrode 3300 is connected to the switching thin film transistor.

The interlayer insulating layer 3400 made of or include an insulating material is formed or disposed over the entirety of the surface of the substrate 3010 and on the gate electrode 3300. The interlayer insulating layer 3400 may be made of or include an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of or include a conductive material such as metal are formed or disposed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line (not shown).

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td may have an inverted staggered structure in which the gate electrode is disposed under the semiconductor layer while the source electrode and the drain electrode are disposed above the semiconductor layer. In some example embodiments, the semiconductor layer may be made of or include amorphous silicon. In an example embodiment, the switching thin-film transistor (not shown) may have substantially the same structure as that of the driving thin-film transistor (Td).

In an example embodiment, the organic light-emitting display device 3000 may include a color filter 3600 absorbing the light generated from the electroluminescent element (light-emitting diode) 4000. For example, the color filter 3600 may absorb red (R), green (G), blue (B), and white (W) light. In some example embodiments, red, green, and blue color filter patterns that absorb light may be formed or disposed separately in different pixel areas. Each of these color filter patterns may be disposed to overlap each organic layer 4300 of the organic light-emitting diode 4000 to emit light of a wavelength band corresponding to each color filter. Adopting the color filter 3600 may allow the organic light-emitting display device 3000 to realize full-color.

For example, when the organic light-emitting display device 3000 is of a bottom emission type, the color filter 3600 absorbing light may be positioned on a portion of the interlayer insulating layer 3400 corresponding to the organic light-emitting diode 4000. In some example embodiments, when the organic light-emitting display device 3000 is of a top emission type, the color filter may be positioned on top of the organic light-emitting diode 4000, that is, on top of a second electrode 4200. For example, the color filter 3600 may be formed to have a thickness of 2 to 5 μm.

In an example embodiment, a planarization layer 3700 having a drain contact hole 3720 defined therein exposing the drain electrode 3540 of the driving thin-film transistor Td is formed or disposed to cover the driving thin-film transistor Td.

On the planarization layer 3700, each first electrode 4100 connected to the drain electrode 3540 of the driving thin-film transistor Td via the drain contact hole 3720 is formed or disposed individually in each pixel area.

The first electrode 4100 may act as a positive electrode (anode), and may be made of or include a conductive material having a relatively large work function value. For example, the first electrode 4100 may be made of or include a transparent conductive material such as ITO, IZO or ZnO.

In an example embodiment, when the organic light-emitting display device 3000 is of a top-emission type, a reflective electrode or a reflective layer may be further formed or disposed under the first electrode 4100. For example, the reflective electrode or the reflective layer may be made of or include one of aluminum (Al), silver (Ag), nickel (Ni), and an aluminum-palladium-copper (APC) alloy.

A bank layer 3800 covering an edge of the first electrode 4100 is formed or disposed on the planarization layer 3700. The bank layer 3800 exposes a center of the first electrode 4100 corresponding to the pixel area.

An organic layer 4300 is formed or disposed on the first electrode 4100. Optionally, the organic light-emitting diode 4000 may have a tandem structure. Regarding the tandem structure, reference may be made to FIG. 2 to FIG. 3, which illustrate some example embodiments of the present disclosure, and the above descriptions thereof.

The second electrode 4200 is formed or disposed on the substrate 3010 on which the organic layer 4300 has been formed or disposed. The second electrode 4200 is disposed over the entirety of the surface of the display area and is made of or include a conductive material having a relatively small work function value and may be used as a negative electrode (a cathode). For example, the second electrode 4200 may be made of or include one of aluminum (Al), magnesium (Mg), and an aluminum-magnesium alloy (Al—Mg).

The first electrode 4100, the organic layer 4300, and the second electrode 4200 constitute the organic light-emitting diode 4000.

An encapsulation film 3900 is formed or disposed on the second electrode 4200 to prevent or reduce external moisture from penetrating into the organic light-emitting diode 4000. Although not shown explicitly in FIG. 4, the encapsulation film 3900 may have a triple-layer structure in which a first inorganic layer, an organic layer, and an inorganic layer are sequentially stacked. However, the present disclosure is not limited thereto.

Hereinafter, Preparation Examples and Present Examples of the present disclosure will be described. The present disclosure is not limited thereto.

### PREPARATION EXAMPLES

### Preparation Example 1: Preparation of Compound 1

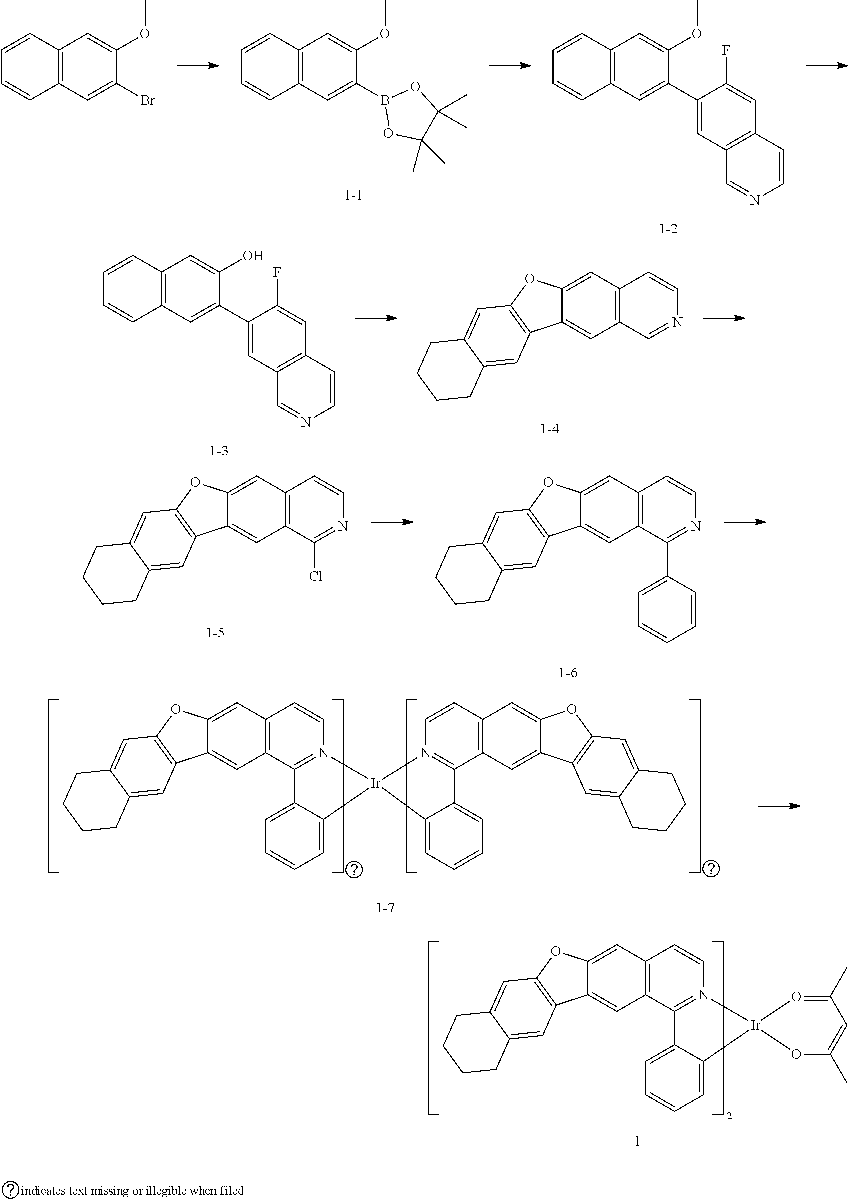

### Preparation of Compound 1-1

6-bromo-7-methoxy-1,2,3,4-tetrahydronaphthalene (10 g, 41.4 mmol, 1.0 eq) was dissolved in 1,4-dioxane to produce a solution, and then bis(pinacolato)diboron (15.8 g, 62.2 mmol, 1.5 eq), Pd(dppf)Cl₂ (1.5 g, 2.07 mmol, 0.05 eq), and KOAc (12.1 g, 124 mmol, 3.0 eq) were added to the solution which in turn, was stirred at 110° C. for 8 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator, and then, the residue was purified by column chromatography using dichloromethane and hexane as a developing solvent. Thus, a compound 1-1 (11.7 g, 98%) was obtained.

MS (m/z): 288.19

### Preparation of Compound 1-2

The compound 1-1 (11.7 g, 40.5 mmol, 1.0 eq) was dissolved in 1,4-dioxane and distilled water to produce a solution, and then, 7-bromo-6-fluoroisoquinoline (9.15 g, 40.5 mmol, 1.0 eq), Pd(PPh₃)₄ (2.3 g, 2.02 mmol, 0.05 eq) and K₂CO₃ (16.7 g, 121 mmol, 3.0 eq) were added to the solution, which in turn, was stirred at 110° C. for 12 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 1-2 (10.9 g, 88%) was obtained.

MS (m/z): 307.14

### Preparation of Compound 1-3

The compound 1-2 (10.9 g, 35.6 mmol, 1.0 eq) was dissolved in dichloromethane to produce a solution, and then BBr₃ was slowly added thereto at 0° C., followed by stirring for 1 hour. After completion of a reaction, methanol was slowly added thereto at 0° C., followed by extraction using distilled water and dichloromethane. An organic layer was dried with anhydrous MgSO₄, and then, filtered. The solvent was removed from the filtrate with a rotary evaporator, and then, the residue was purified by column chromatography using dichloromethane and hexane as a developing solvent to obtain a compound 1-3 (9.9 g, 95%).

MS (m/z): 293.12

### Preparation of Compound 1-4

The compound 1-3 (9.9 g, 33.8 mmol, 1.0 eq) was dissolved in N-methyl-2-pyrrolidone to produce a solution, and then, K₂CO₃ (14.0 g, 101.4 mmol, 3.0 eq) was added thereto, followed by stirring at 120° C. for 12 hours. After completion of a reaction, extraction was performed with distilled water and ethyl acetate at room temperature. An organic layer was dried with anhydrous MgSO₄, and then, filtered. The solvent was removed from the filtrate with a rotary evaporator, and subsequently, the residue was purified by column chromatography using dichloromethane and hexane as a developing solvent to obtain a compound 1-4 (8.1 g, 88%).

MS (m/z): 273.12

### Preparation of Compound 1-5

The compound 1-4 (8.1 g, 29.7 mmol, 1.0 eq) was dissolved in dichloromethane to produce a solution, and then, m-CPBA was added to the solution which in turn was stirred at room temperature for 24 hours. After completion of the reaction, work-up was performed with distilled water and dichloromethane, and then, an organic layer was concentrated. A concentrated residue was dissolved in POCl₃ (40 ml) to produce a solution which in turn was stirred at 80° C. for 4 hours. After a reaction was completed, POCl₃ was removed therefrom with a rotary evaporator, and then, sat. NaHCO₃ aqueous solution was added thereto for neutralization thereof. Further work-up was performed with distilled water and dichloromethane, and then, an organic layer was dried with anhydrous MgSO₄, and then filtered. The solvent was removed from the filtrate with a rotary evaporator, and, subsequently, the residue was purified by column chromatography using dichloromethane and hexane as a developing solvent to obtain a compound 1-5 (7.4 g, 81%).

MS (m/z): 307.08

### Preparation of Compound 1-6

The compound 1-5 (7.4 g, 24.0 mmol, 1.0 eq) was dissolved in 1,4-dioxane and distilled water to produce a solution, and then, phenylboronic acid (3.2 g, 26.7 mmol, 1.1 eq), Pd(PPh₃)₄ (1.4 g, 1.21 mmol, 0.05 eq) and K₂CO₃ (10.0 g, 72.9 mmol, 3.0 eq) were added to the solution, which in turn, was stirred at 110° C. for 8 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator, and subsequently, the residue was purified by column chromatography using dichloromethane and hexane as a developing solvent to obtain a compound 1-6 (7.7 g, 93%).

MS (m/z): 349.15

### Preparation of Compound 1-7

The compound 1-6 (7.7 g, 22.3 mmol, 2.0 eq) and iridium(III) chloride hydrate (3.3 g, 11.2 mmol, 1.0 eq) were dissolved in 2-ethoxyethanol and distilled water, followed by stirring at 110° C. under nitrogen reflux for 24 hours. A reaction mixture was cooled to room temperature, and then, a resulting solid was filtered and washed with methanol. The solid was vacuum dried to obtain a compound 1-7 (8.6 g, 98%).

MS (m/z): 1572.51

### Preparation of Compound 1

The compound 1-7 (8.6 g, 21.8 mmol, 1.0 eq) and pentane-2,4-dione (6.5 g, 42.0 mmol, 2.0 eq) were dissolved in 2-ethoxyethanol, followed by stirring at 110° C. for 24 hours under nitrogen reflux. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 1 (9.0 g, 84%) was obtained.

MS (m/z): 988.29

### Preparation Example 2: Preparation of Compound 7

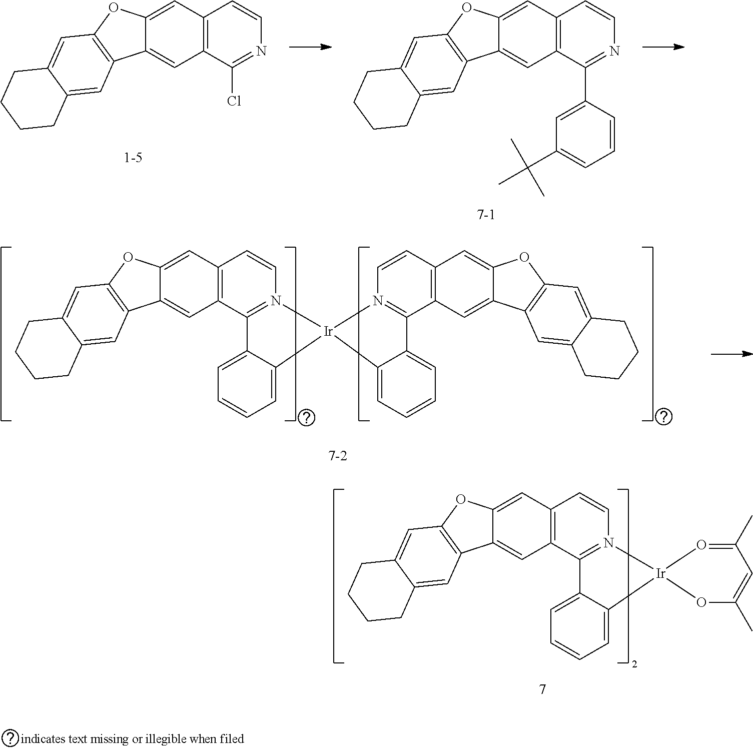

### Preparation of Compound 7-1

The compound 1-5 (10.0 g, 32.5 mmol, 1.0 eq) was dissolved in 1,4-dioxane and distilled water to produce a solution, and then (3-(tert-butyl)phenyl)boronic acid (6.3 g, mmol, 1.1 eq), Pd(PPh₃)₄ (1.8 g, 1.62 mmol, 0.05 eq) and K₂CO₃ (13.4 g, 97.5 mmol, 3.0 eq) were added to the solution, which in turn, was stirred at 110° C. for 8 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator, and subsequently, the residue was purified by column chromatography using dichloromethane and hexane as a developing solvent to obtain a compound 7-1 (11.8 g, 90%).

MS (m/z): 405.21

### Preparation of Compound 7-2

The compound 7-1 (11.8 g, 29.2 mmol, 2.0 eq) and iridium (III) chloride hydrate (4.3 g, 14.6 mmol, 1.0 eq) were dissolved in 2-ethoxyethanol and distilled water, followed by stirring at 110° C. under nitrogen reflux 24 hours. A reaction mixture was cooled to room temperature, and then, a resulting solid was filtered and washed with methanol. The solid was vacuum dried to obtain a compound 7-2 (9.0 g, 98%).

MS (m/z): 1572.51

### Preparation of Compound 7

The compound 7-2 (9.0 g, 28.6 mmol, 1.0 eq) and pentane-2,4-dione (5.6 g, 57.2 mmol, 2.0 eq) were dissolved in 2-ethoxyethanol, followed by stirring at 110° C. for 24 hours under nitrogen reflux. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 7 (11.8 g, 84%) was obtained.

MS (m/z): 988.29

### Preparation Example 3: Preparation of Compound 18

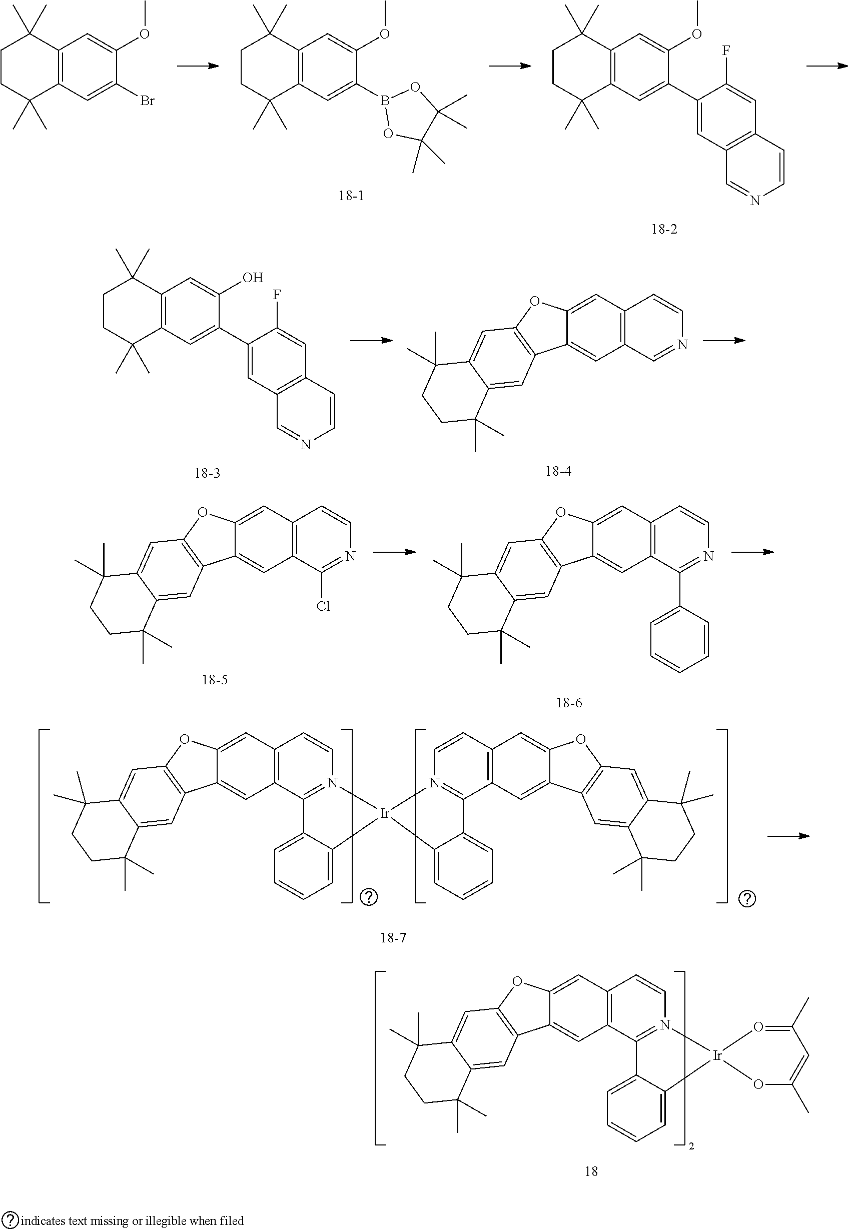

### Preparation of Compound 18-1

6-bromo-7-methoxy-1,1,4,4-tetramethyl-1,2,3,4-tetrahydronaphthalene (10 g, 33.6 mmol, 1.0 eq) was dissolved in 1,4-dioxane to produce a solution, and then bis(pinacolato)diboron (12.8 g, 50.4 mmol, 1.5 eq), Pd(dppf)Cl₂ (1.3 g, 1.68 mmol, 0.05 eq), and KOAc (9.9 g, 100.8 mmol, 3.0 eq) were added thereto, followed by stirring at 110° C. for 8 hours. After completion of the reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 18-1 (11.7 g, 97%) was obtained.

MS (m/z): 344.25

### Preparation of Compound 18-2

The compound 18-1 (11.2 g, 32.5 mmol, 1.0 eq) was dissolved in 1,4-dioxane and distilled water to produce a solution, and then 7-bromo-6-fluoroisoquinoline (7.3 g, 32.5 mmol, 1.0 eq), Pd(PPh₃)₄ (1.8 g, 1.62 mmol, 0.05 eq) and K₂CO₃ (13.4 g, 97.5 mmol, 3.0 eq) were added to the solution, which in turn, was stirred at 110° C. for 12 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 18-2 (10.3 g, 88%) was obtained.

MS (m/z): 363.20

### Preparation of Compound 18-3

The compound 18-2 (10.3 g, 28.6 mmol, 1.0 eq) was dissolved in dichloromethane to produce a solution, and then BBr₃ was slowly added thereto at 0° C., followed by stirring for 1 hour. After completion of a reaction, methanol was slowly added thereto at 0° C., followed by extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as the developing solvent. Thus, a compound 18-3 (9.5 g, 96%) was obtained.

MS (m/z): 349.18

### Preparation of Compound 18-4

The compound 18-3 (9.5 g, 27.4 mmol, 1.0 eq) was dissolved in N-methyl-2-pyrrolidone to produce a solution, and then, K₂CO₃ (11.3 g, 82.2 mmol, 3.0 eq) was added thereto, followed by stirring at 120° C. for 12 hours. After completion of a reaction, extraction was performed with distilled water and ethyl acetate at room temperature. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 18-4 (8.1 g, 90%) was obtained.

MS (m/z): 329.18

### Preparation of Compound 18-5

The compound 18-4 (8.1 g, 24.6 mmol, 1.0 eq) was dissolved in dichloromethane to produce a solution, and then, m-CPBA was added to the solution which in turn was stirred at room temperature for 24 hours. After completion of a reaction, work-up was performed with distilled water and dichloromethane, and then, an organic layer was concentrated. A concentrated residue was dissolved in POCl₃ (40 ml), followed by stirring at 80° C. for 4 hours. After a reaction was completed, POCl₃ was removed therefrom with a rotary evaporator, and then, sat. NaHCO₃ aqueous solution was added thereto for neutralization thereof. Further work-up was performed with distilled water and dichloromethane, and an organic layer was dried with anhydrous MgSO₄, and then filtered. The solvent was removed from the filtrate with a rotary evaporator. Subsequently, the residue was purified by column chromatography using dichloromethane and hexane as a developing solvent to obtain a compound 18-5 (7.4 g, 83%).

MS (m/z): 363.14

### Preparation of Compound 18-6

The compound 18-5 (7.4 g, 24.0 mmol, 1.0 eq) was dissolved in 1,4-dioxane and distilled water to produce a solution, and then phenylboronic acid (3.2 g, 26.4 mmol, 1.1 eq), Pd(PPh₃)₄ (1.4 g, 1.21 mmol, 0.05 eq) and K₂CO₃ (10.0 g, 72.9 mmol, 3.0 eq) were added to the solution, which in turn, was stirred at 110° C. for 8 hours. After completion of a reaction, the mixed solution was cooled to room temperature and was subjected to extraction using distilled water and dichloromethane. An organic layer was dried with anhydrous MgSO₄, and then filtered. The solvent was removed from the filtrate using a rotary evaporator. Then, the residue was purified by column chromatography using dichloromethane and hexane as a developing solvent. Thus, a compound 18-6 (9.0 g, 93%) was obtained.

MS (m/z): 405.21

### Preparation of Compound 18-7

The compound 18-6 (9.0 g, 22.3 mmol, 2.0 eq) and iridium(III) chloride hydrate (3.3 g, 11.2 mmol, 1.0 eq) were dissolved in 2-ethoxyethanol and distilled water, followed by stirring at 110° C. under nitrogen reflux 24 hours. A reaction mixture was cooled to room temperature, and then, a resulting solid was filtered and washed with methanol. The solid was vacuum dried to obtain a compound 18-7 (9.5 g, 95%).

MS (m/z): 1796.76

### Preparation of Compound 18

The compound 18-7 (9.5 g, 21.1 mmol, 1.0 eq) and pentane-2,4-dione (6.5 g, 42.0 mmol, 2.0 eq) were dissolved in 2-ethoxyethanol, followed by stirring for 24 hours at 110° C. under nitrogen reflux. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 18 (9.6 g, 83%) was obtained.

MS (m/z): 1100.41

### Preparation Example 4: Preparation of Compound 22

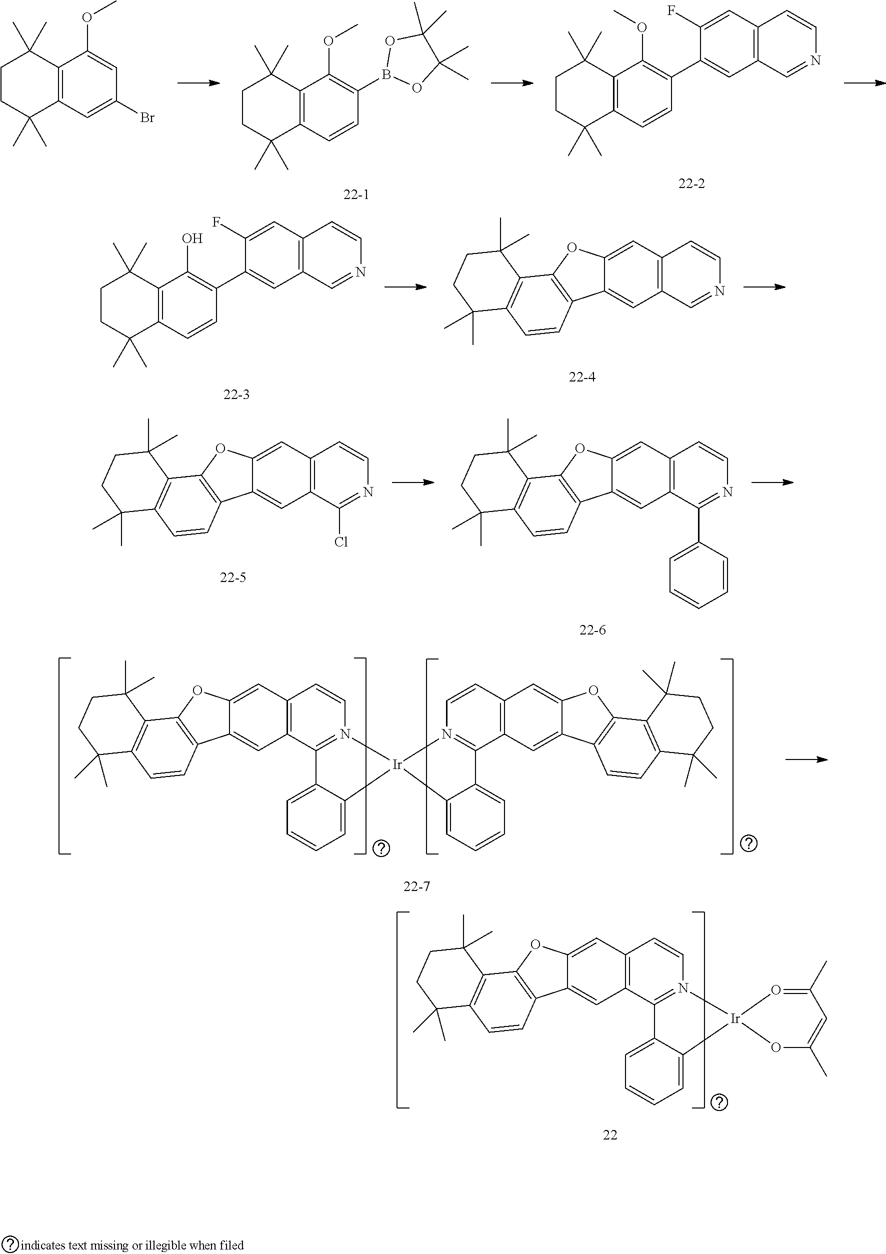

### Preparation of Compound 22-1

6-bromo-5-methoxy-1,1,4,4-tetramethyl-1,2,3,4-tetrahydronaphthalene (10 g, 33.6 mmol, 1.0 eq) was dissolved in 1,4-dioxane to produce a solution, and then, bis(pinacolato)diboron (1.5 eq), Pd(dppf)Cl₂ (0.05 eq), and KOAc (3.0 eq) added thereto, followed by stirring at 110° C. for 8 hours. After completion of a reaction, the mixed solution was cooled to room temperature and was subjected to extraction using distilled water and dichloromethane. An organic layer was dried with anhydrous MgSO₄, and then, filtered. The solvent was removed therefrom with a rotary evaporator. Then, the residue was purified by column chromatography using dichloromethane and hexane as a developing solvent. Thus, a compound 22-1 (10.8 g, 94%) was obtained.

MS (m/z): 344.25

### Preparation of Compound 22-2

The compound 22-1 (10.8 g, 31.5 mmol, 1.0 eq) was dissolved in 1,4-dioxane and distilled water to produce a solution, and then 7-bromo-6-fluoroisoquinoline (1.0 eq), Pd(PPh₃)₄ (0.05 eq), and K₂CO₃ (3.0 eq) eq) were added to the solution which in turn was stirred at 110° C. for 12 hours. After completion of a reaction, the mixed solution was cooled to room temperature and was subjected to extraction using distilled water and dichloromethane. An organic layer was dried with anhydrous MgSO₄, and then, filtered. The solvent was removed therefrom with a rotary evaporator. Then, the residue was purified by column chromatography using dichloromethane and hexane as a developing solvent. Thus, a compound 22-2 (9.6 g, 84%) was obtained.

MS (m/z): 363.20

### Preparation of Compound 22-3

The compound 22-2 (9.6 g, 26.4 mmol, 1.0 eq) was dissolved in dichloromethane to produce a solution, and BBr₃ was slowly added thereto at 0° C., followed by stirring for 1 hour. After completion of a reaction, methanol was slowly added thereto at 0° C., followed by extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as the developing solvent. Thus, a compound 22-3 (9.2 g, 96%) was obtained.

MS (m/z): 363.20

### Preparation of Compound 22-4

The compound 22-3 (9.2 g, 25.3 mmol, 1.0 eq) was dissolved in N-methyl-2-pyrrolidone, and then K₂CO₃ (3.0 eq) was added thereto, followed by stirring at 120° C. for 12 hours. After completion of a reaction, extraction was performed with distilled water and ethyl acetate at room temperature. An organic layer was dried with anhydrous MgSO₄, and then, filtered. The solvent was removed from the filtrate with a rotary evaporator. Then, the residue was purified by column chromatography using dichloromethane and hexane as the developing solvent. Thus, a compound 22-4 (7.9 g, 95%) was obtained.

MS (m/z): 329.18

### Preparation of Compound 22-5

The compound 22-4 (7.9 g, 24.0 mmol, 1.0 eq) was dissolved in dichloromethane to produce a solution, and then, m-CPBA was added to the solution which in turn was stirred at room temperature for 24 hours. After completion of a reaction, work-up was performed with distilled water and dichloromethane, and then, an organic layer was concentrated. A concentrated residue was dissolved in POCl₃ (40 ml), followed by stirring at 80° C. for 4 hours. After a reaction was completed, POCl₃ was removed therefrom with a rotary evaporator, and then, sat. NaHCO₃ aqueous solution was added thereto for neutralization thereof. Further work-up was performed with distilled water and dichloromethane, the organic layer was dried with anhydrous MgSO₄, and then filtered. The solvent was removed from the filtrate with a rotary evaporator, and then, the residue was purified by column chromatography using dichloromethane and hexane as a developing solvent to obtain a compound 22-5 (7.4 g, 85%).

MS (m/z): 363.14

### Preparation of Compound 22-6

The compound 22-5 (7.4 g, 24.0 mmol, 1.0 eq) was dissolved in 1,4-dioxane and distilled water to produce a solution, and then phenylboronic acid (1.1 eq), Pd(PPh₃)₄ (0.05 eq), and K₂CO₃ (3.0 eq) were added to the solution which in turn was stirred for 8 hours at 110 degrees C. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as the developing solvent. Thus, a compound 22-6 (8.9 g, 92%) was obtained.

MS (m/z): 405.21

### Preparation of Compound 22-7

The compound 22-6 (8.9 g, 22.0 mmol, 2.0 eq) and iridium (III) chloride hydrate (1.0 eq) were dissolved in 2-ethoxyethanol and distilled water, followed by stirring for 24 hours at 110° C. under nitrogen reflux. A reaction mixture was cooled to room temperature, and then, a resulting solid was filtered and washed with methanol. The solid was vacuum dried to obtain a compound 22-7 (8.9 g, 92%).

MS (m/z): 1766.71

### Preparation of Compound 22

The compound 22-7 (8.9 g, 20.2 mmol, 1.0 eq) and pentane-2,4-dione (2.0 eq) were dissolved in 2-ethoxyethanol, followed by stirring at 110° C. for 24 hours under nitrogen reflux. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 22 (9.4 g, 85%) was obtained.

MS (m/z): 1100.41

### Preparation Example 5: Preparation of Compound 40

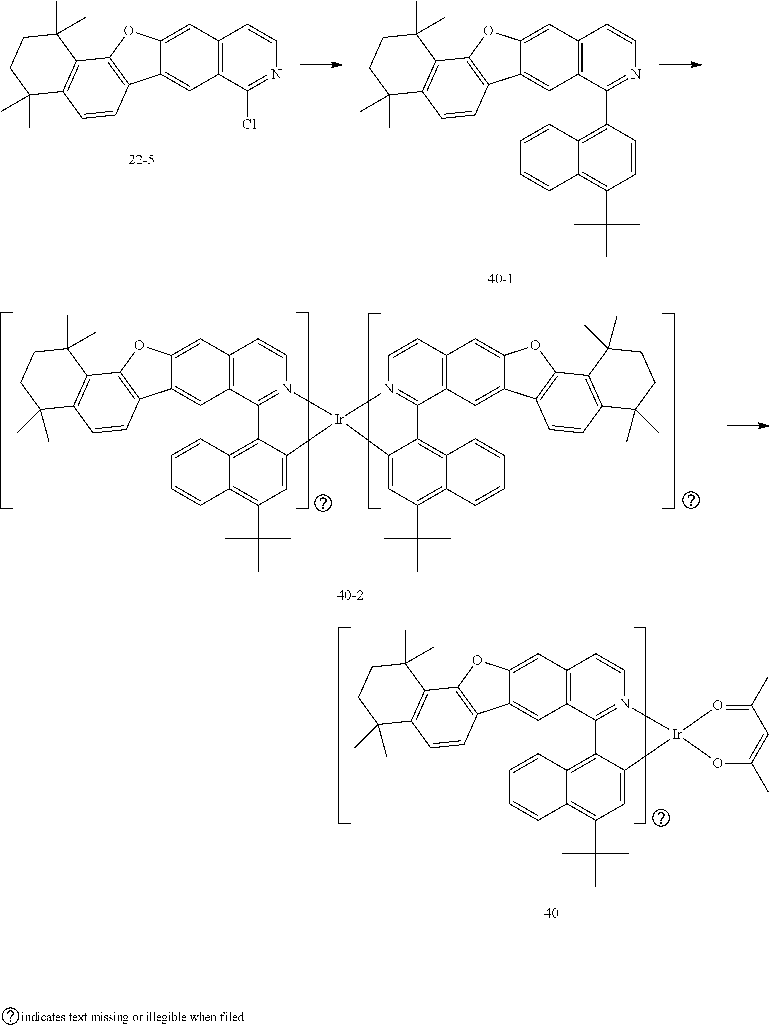

### Preparation of Compound 40-1

The compound 22-5 (10.0 g, 27.5 mmol, 1.0 eq) was dissolved in 1,4-dioxane and distilled water to produce a solution, and then, 2-(4-(tert-butyl)naphthalen-1-yl)-4,4,5,5-tetramethyl-1,3,2-dioxaborolane (1.1 eq), Pd(PPh₃)₄ (0.05 eq), and K₂CO₃ (3.0 eq) were added thereto, followed by stirring at 110° C. for 8 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 40-1 (13.9 g, 93%) was obtained.

MS (m/z): 511.29

### Preparation of Compound 40-2

The compound 40-1 (13.9 g, 25.6 mmol, 2.0 eq) and iridium (III) chloride hydrate (1.0 eq) were dissolved in 2-ethoxyethanol and distilled water, followed by stirring at 110° C. for 24 hours under nitrogen reflux. A reaction mixture was cooled to room temperature, and then, a resulting solid was filtered and washed with methanol. The solid was vacuum dried to obtain a compound 40-2 (11.8 g, 90%).

MS (m/z): 2064.89

### Preparation of Compound 40

The compound 40-2 (11.8 g, 23.0 mmol, 1.0 eq) and pentane-2,4-dione (2.0 eq) were dissolved in 2-ethoxyethanol, followed by stirring at 110° C. for 24 hours under nitrogen reflux. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 40 (11 g, 82%) was obtained.

MS (m/z): 1255.50

### Preparation Example 6: Preparation of Compound 41

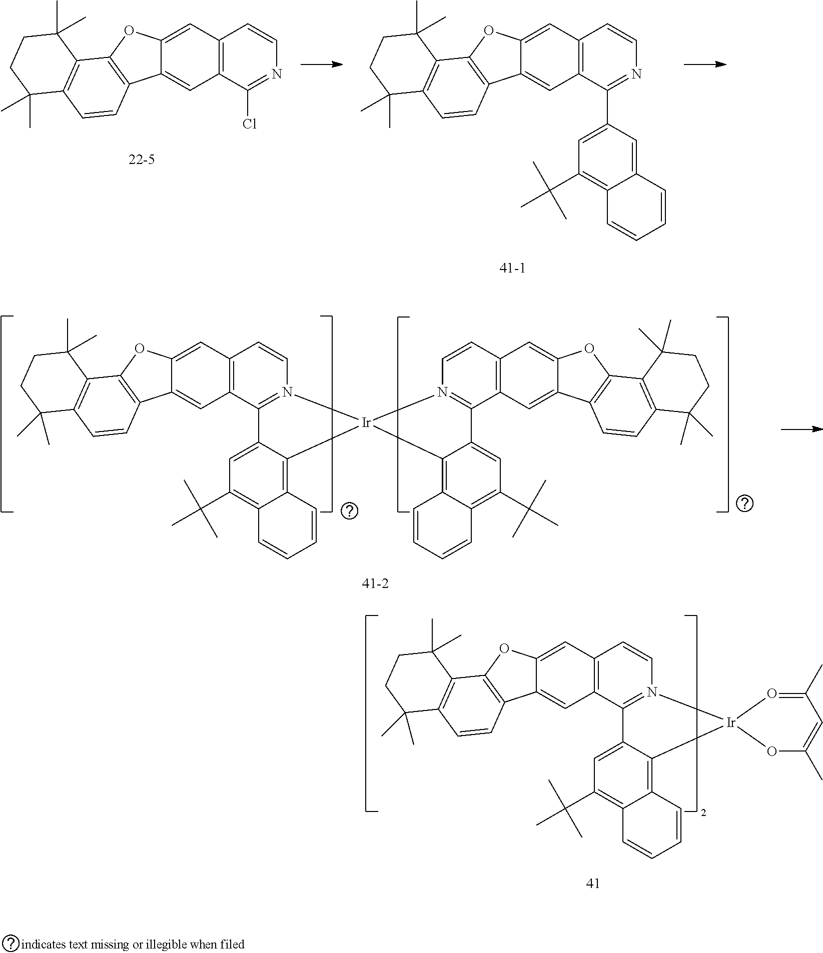

### Preparation of Compound 41-1

The compound 22-5 (10.0 g, 27.5 mmol, 1.0 eq) was dissolved in 1,4-dioxane and distilled water to produce a solution, and then 2-(4-(tert-butyl)naphthalen-2-yl)-4,4,5,5-tetramethyl-1,3,2-dioxaborolane (1.1 eq), Pd(PPh₃)₄ (0.05 eq), and K₂CO₃ (3.0 eq) were added thereto, followed by stirring at 110° C. for 8 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as the developing solvent. Thus, a compound 41-1 (13.9 g, 93%) was obtained.

MS (m/z): 511.29

### Preparation of Compound 41-2

The compound 41-1 (13.9 g, 25.6 mmol, 2.0 eq) and iridium (III) chloride hydrate (1.0 eq) were dissolved in 2-ethoxyethanol and distilled water, followed by stirring at 110° C. for 24 hours under nitrogen reflux. A reaction mixture was cooled to room temperature, and then, a resulting solid was filtered and washed with methanol. The solid was vacuum dried to obtain a compound 41-2 (11.9 g, 92%).

MS (m/z): 2028.89

### Preparation of Compound 41

The compound 41-2 (11.9 g, 23.5 mmol, 1.0 eq) and pentane-2,4-dione (2.0 eq) was dissolved in 2-ethoxyethanol, followed by stirring at 110° C. for 24 hours under nitrogen reflux. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 41 (12 g, 83%) was obtained.

MS (m/z): 1243.50

### Preparation Example 7: Preparation of Compound 44

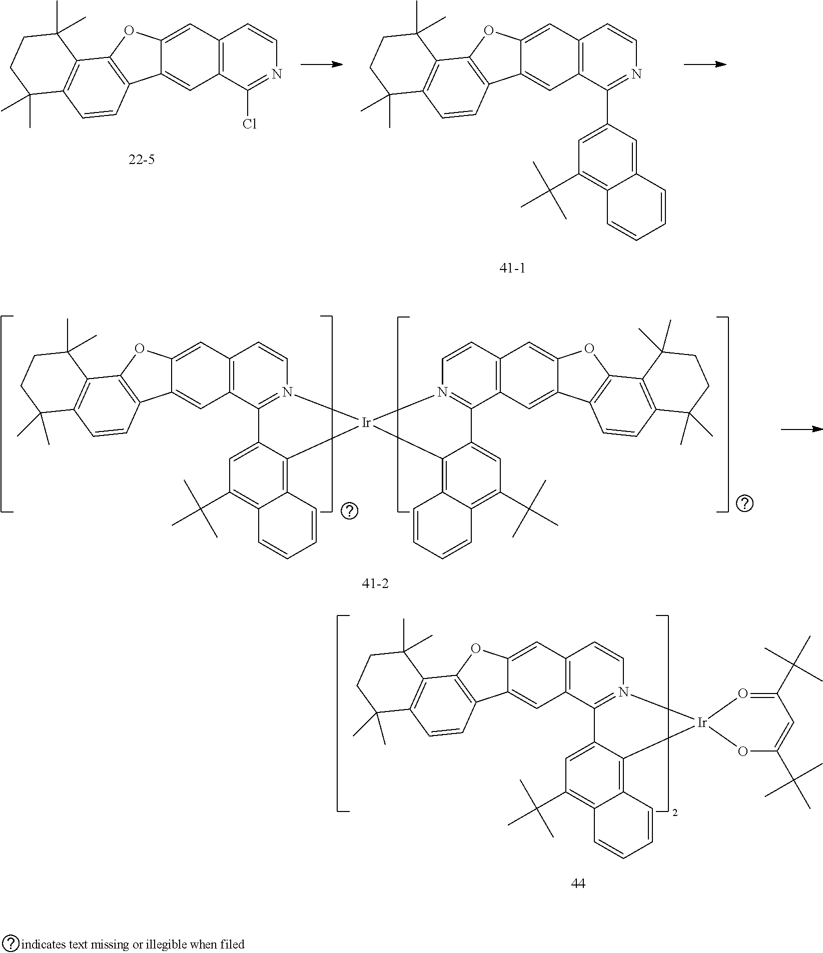

### Preparation of Compound 44

A compound 44 was obtained in the same manner as the preparation method of the compound 41 in Preparation Example 6, except for using 2,2,6,6-tetramethylheptane-3,5-dione instead of pentane-2,4-dione as in Preparation Example 6.

MS (m/z): 1327.59

### Preparation Example 8: Preparation of Compound 45

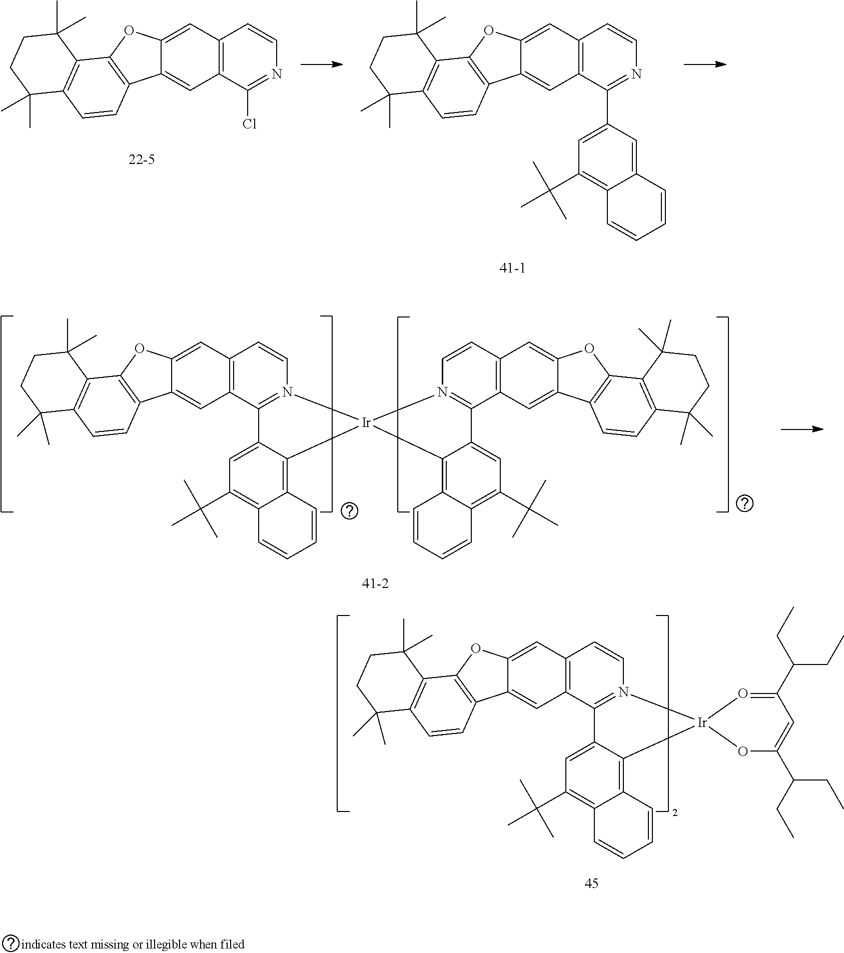

A compound 45 was obtained in the same manner as the preparation method of the compound 41 in Preparation Example 6, except for using 3,7-diethylnonane-4,6-Dione instead of pentane-2,4-dione as in Preparation Example 6.

MS (m/z): 1355.62

### Preparation Example 9: Preparation of Compound 46

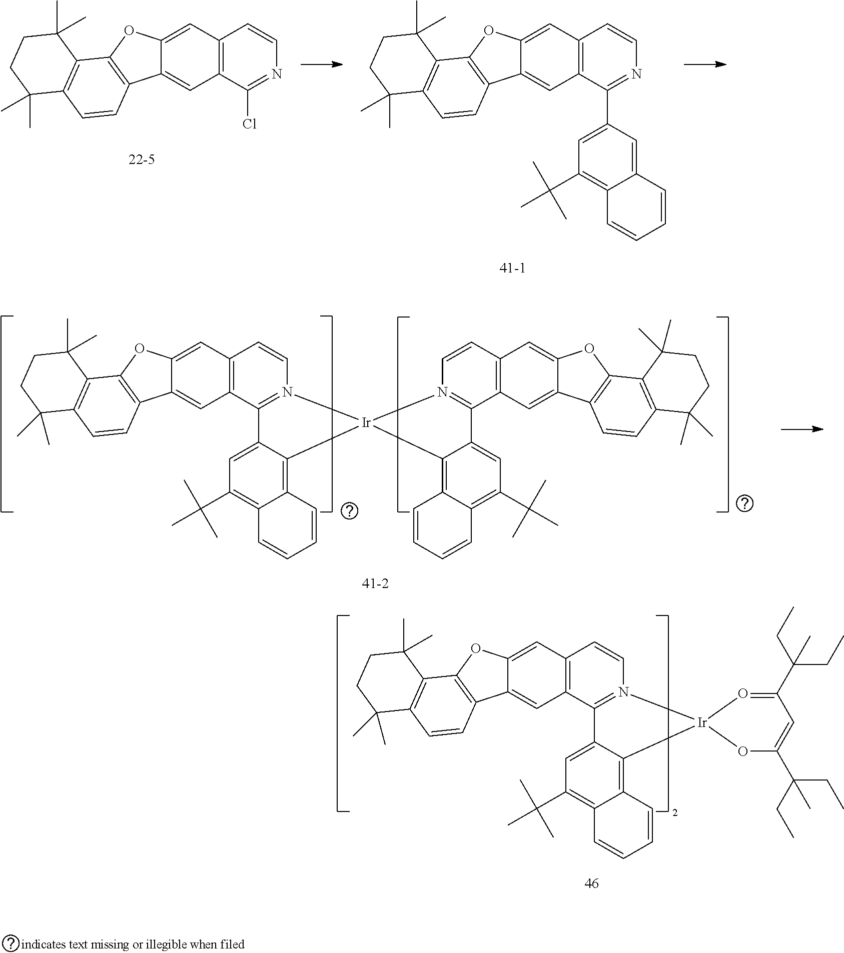

A compound 46 was obtained in the same manner as the preparation method of the compound 41 in Preparation Example 6, except for using 3,7-diethyl-3,7-dimethylnonane-4,6-dione instead of pentane-2,4-dione as in Preparation Example 6.

MS (m/z): 1383.65

### Preparation Example 10: Preparation of Compound 47

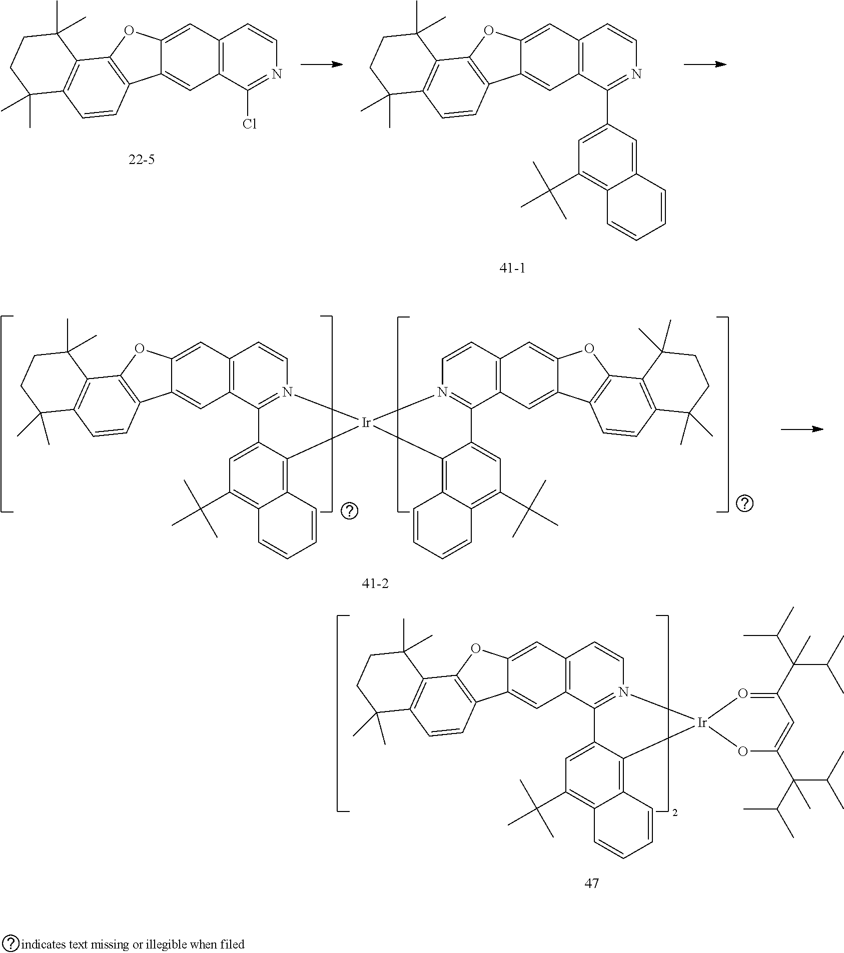

### Preparation of Compound 47

A compound 47 was obtained in the same manner as the preparation method of the compound 41 in Preparation Example 6, except for using 3,7-diisopropyl-2,3,7,8-tetramethylnonane-4,6-dione instead of pentane-2,4-dione as in Preparation Example 6.

MS (m/z): 1439.72

### <Preparation Example 11: Preparation of Compound 54> Preparation of Compound 54

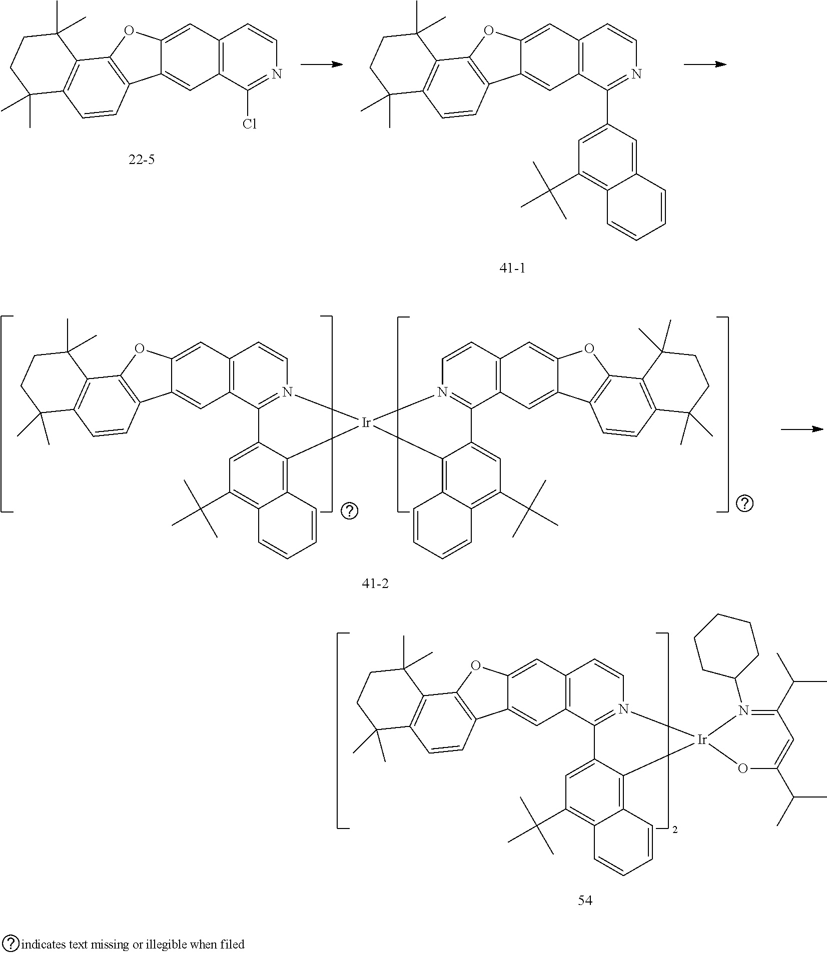

A compound 54 was obtained in the same manner as the preparation method of the compound 41 in Preparation Example 6, except for using (Z)-5-(cyclohexylimino)-2,6-dimethylheptan-3-one instead of pentane-2,4-dione as in Preparation Example 6.

MS (m/z): 1380.65

### Preparation Example 12: Preparation of Compound 77

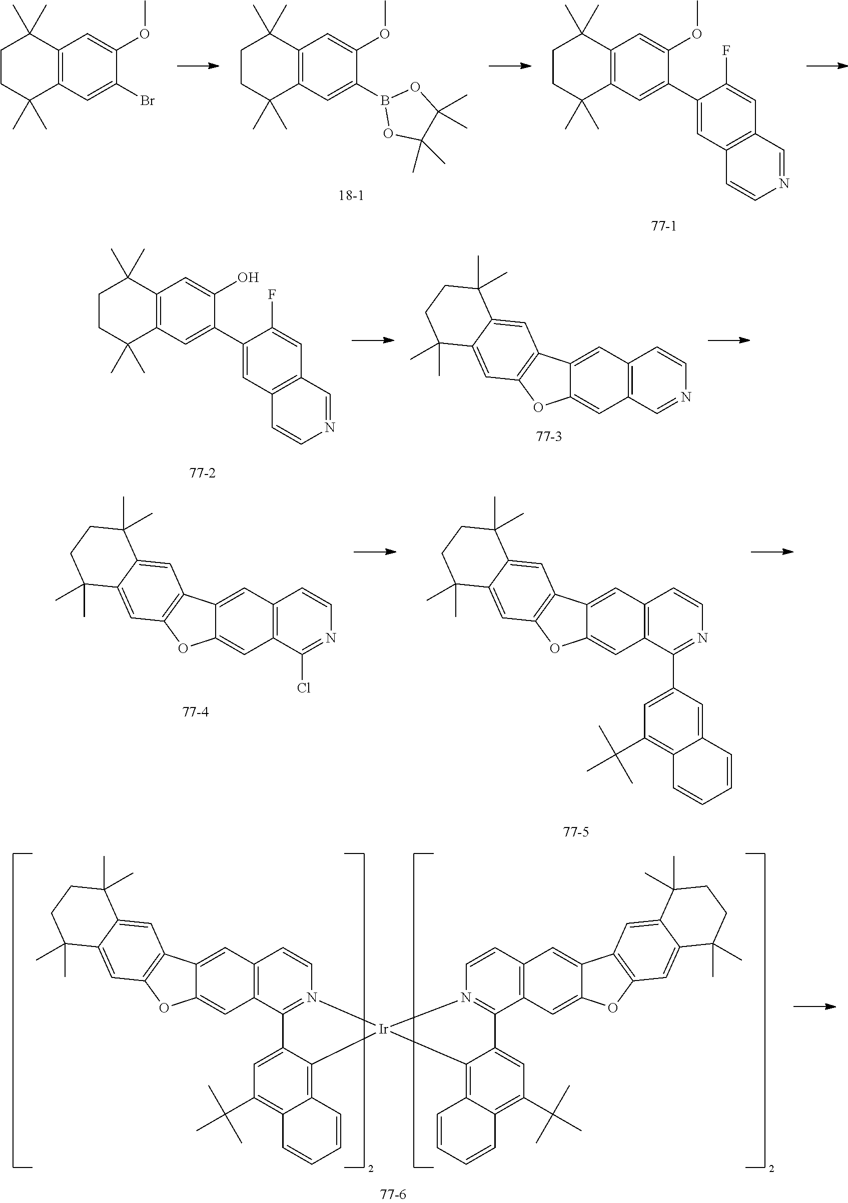

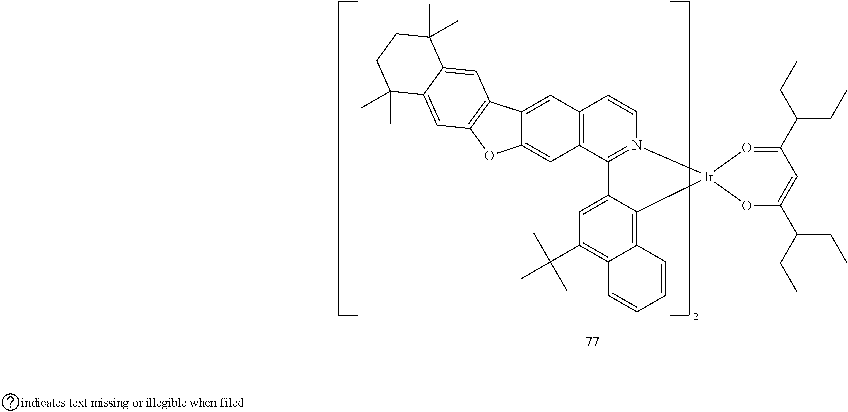

### Preparation of Compound 77-1

The compound 18-1 (10.0 g, 29.0 mmol, 1.0 eq) was dissolved in 1,4-dioxane and distilled water to produce a solution, and then 6-bromo-7-fluoroisoquinoline (1.0 eq), Pd(PPh₃)₄ (0.05 eq), and K₂CO₃ (3.0 eq) were added to the solution which in turn was stirred at 110° C. for 12 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 77-1 (9.5 g, 90%) was obtained.

MS (m/z): 363.20

### Preparation of Compound 77-2

The compound 77-1 (9.5 g, 26.1 mmol, 1.0 eq) was dissolved in dichloromethane to produce a solution, and then, BBr₃ was slowly added thereto at 0° C., followed by stirring for 1 hour. After completion of a reaction, methanol was slowly added thereto at 0° C., followed by extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as the developing solvent. Thus, a compound 77-2 (8.7 g, 96%) was obtained.

MS (m/z): 349.18

### Preparation of Compound 77-3

The compound 77-2 (8.7 g, 25.0 mmol, 1.0 eq) was dissolved in N-methyl-2-pyrrolidone, and K₂CO₃ (3.0 eq) was added thereto, followed by stirring at 120° C. for 12 hours. After completion of a reaction, extraction was performed with distilled water and ethyl acetate at room temperature. An organic layer was dried with anhydrous MgSO₄, and then, filtered. The solvent was removed from the filtrate with a rotary evaporator. Then, the residue was purified by column chromatography using dichloromethane and hexane as the developing solvent. Thus, a compound 77-3 (7.6 g, 93%) was obtained.

MS (m/z): 329.18

### Preparation of Compound 77-4

The compound 77-3 (7.6 g, 23.2 mmol, 1.0 eq) was dissolved in dichloromethane to produce a solution, and then, m-CPBA was added to the solution which in turn was stirred at room temperature for 24 hours. After completion of a reaction, work-up was performed with distilled water and dichloromethane, and then, an organic layer was concentrated. A concentrated residue was dissolved in POCl₃ (40 ml), followed by stirring at 80° C. for 4 hours. After a reaction was completed, POCl₃ was removed therefrom with a rotary evaporator, and then, sat. NaHCO₃ aqueous solution was added thereto for neutralization thereof. Further work-up was performed with distilled water and dichloromethane, the organic layer was dried with anhydrous MgSO₄, and then filtered. The solvent was removed from the filtrate with a rotary evaporator, and, subsequently, the residue was purified by column chromatography using dichloromethane and hexane as a developing solvent to obtain a compound 77-4 (7.1 g, 85%).

MS (m/z): 363.14

### Preparation of Compound 77-5

The compound 77-4 (7.1 g, 19.7 mmol, 1.0 eq) was dissolved in 1,4-dioxane and distilled water to produce a solution, and then 2-(4-(tert-butyl)naphthalen-2-yl)-4,4,5,5-tetramethyl-1,3,2-dioxaborolane (1.1 eq), Pd(PPh₃)₄ (0.05 eq), and K₂CO₃ (3.0 eq) were added thereto, followed by stirring at 110° C. for 8 hours. After completion of a reaction, the mixed solution was cooled to room temperature and was subjected to extraction using distilled water and dichloromethane. An organic layer was dried with anhydrous MgSO₄, and then filtered. The solvent was removed from the filtrate with a rotary evaporator, and, subsequently, the residue was purified by column chromatography using dichloromethane and hexane as a developing solvent to obtain a compound 77-5 (9.3 g, 93%).

MS (m/z): 511.29

### Preparation of Compound 77-6

The compound 77-5 (9.3 g, 18.3 mmol, 2.0 eq) and iridium (III) chloride hydrate (1.0 eq) were dissolved in 2-ethoxyethanol and distilled water, followed by stirring for 24 hours at 110° C. under nitrogen reflux. A reaction mixture was cooled to room temperature, and then, a resulting solid was filtered and washed with methanol. The solid was vacuum dried to obtain a compound 77-6 (9.4 g, 94%).

MS (m/z): 2191.03

### Preparation of Compound 77

The compound 77-6 (9.4 g, 17.2 mmol, 1.0 eq) and 3,7-diethylnonane-4,6-dione (2.0 eq) were dissolved in 2-ethoxyethanol, followed by stirring at 110 degrees Celsius for 24 hours under nitrogen reflux. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 77 (11.1 g, 81%) was obtained.

MS (m/z): 1411.68

### Preparation Example 13: Preparation of Compound 85

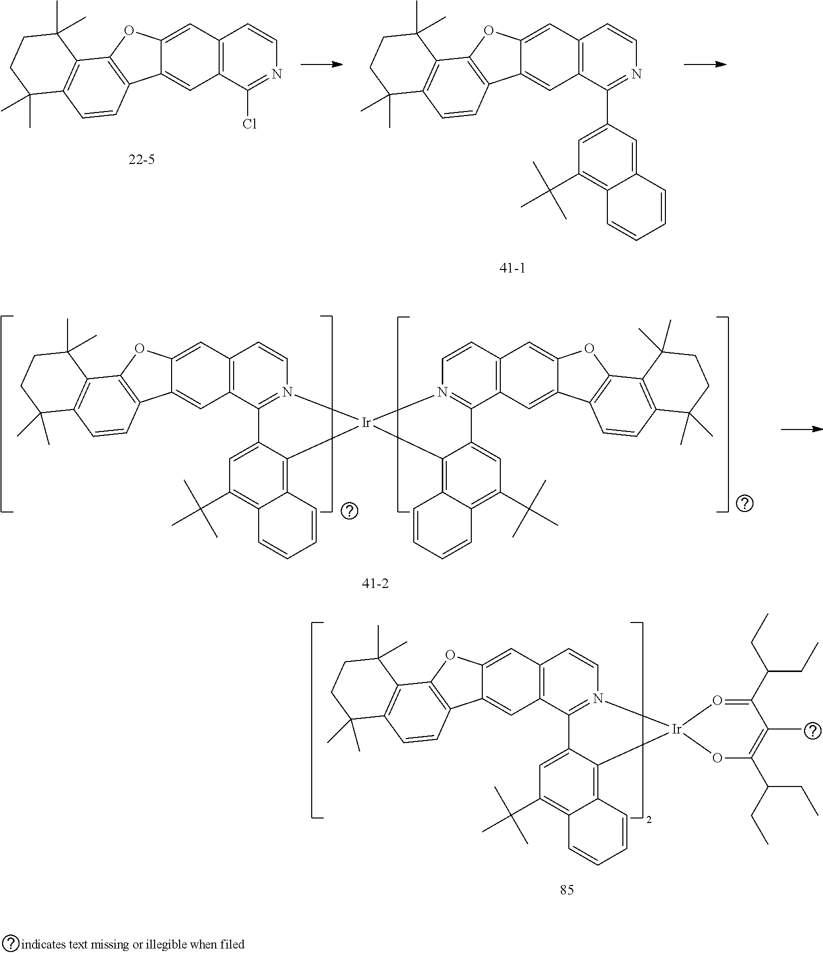

### Preparation of Compound 85

A compound 85 was obtained in the same manner as the preparation method of the compound 41 in Preparation Example 6, except for using (Z)-3,7-diethyl-6-hydroxy-3,7-dimethylnon-5-en-4-one-5-d instead of pentane-2,4-dione as in Preparation Example 6.

MS (m/z): 1356.63

### Preparation Example 14: Preparation of Compound 86

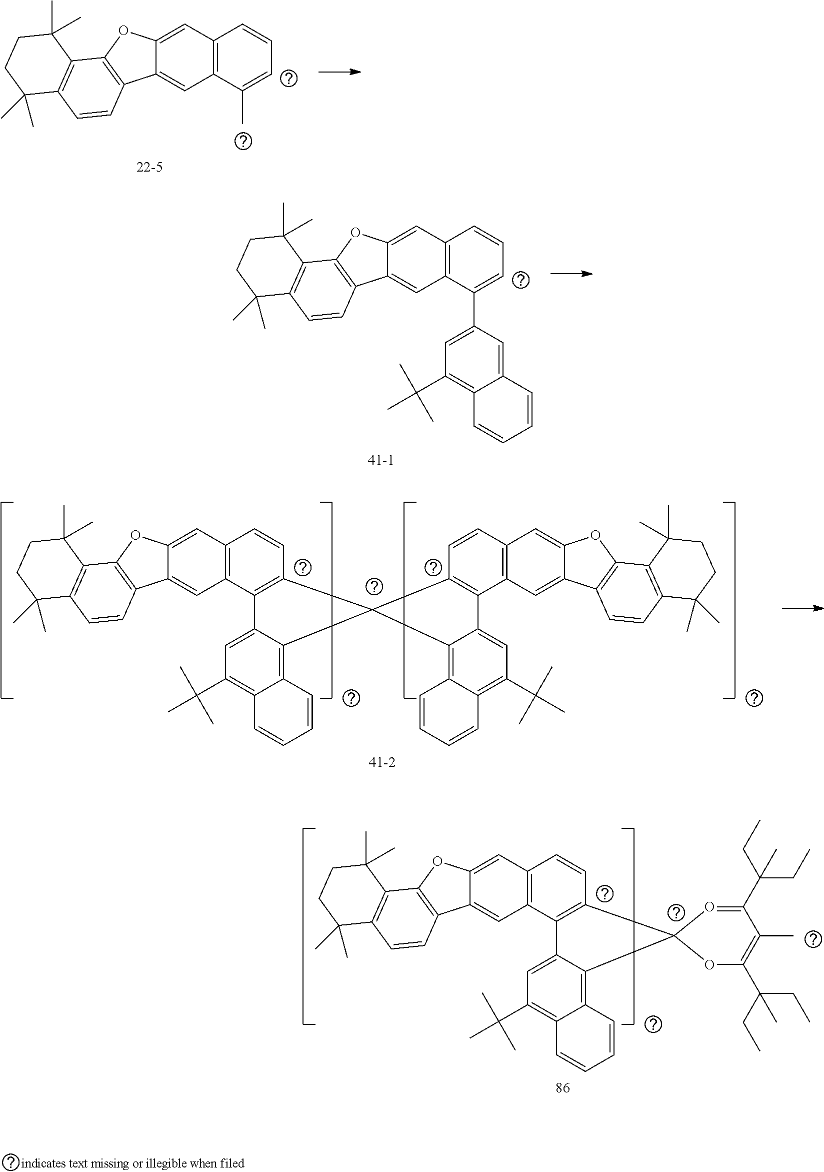

### Preparation of Compound 86

A compound 86 was obtained in the same manner as the preparation method of the compound 41 in Preparation Example 6, except for using (Z)-3,7-diethyl-6-hydroxy-3,7-dimethylnon-5-en-4-one-5-d instead of pentane-2,4-dione as in Preparation Example 6.

MS (m/z): 1384.66

### Preparation Example 15: Preparation of Compound 106

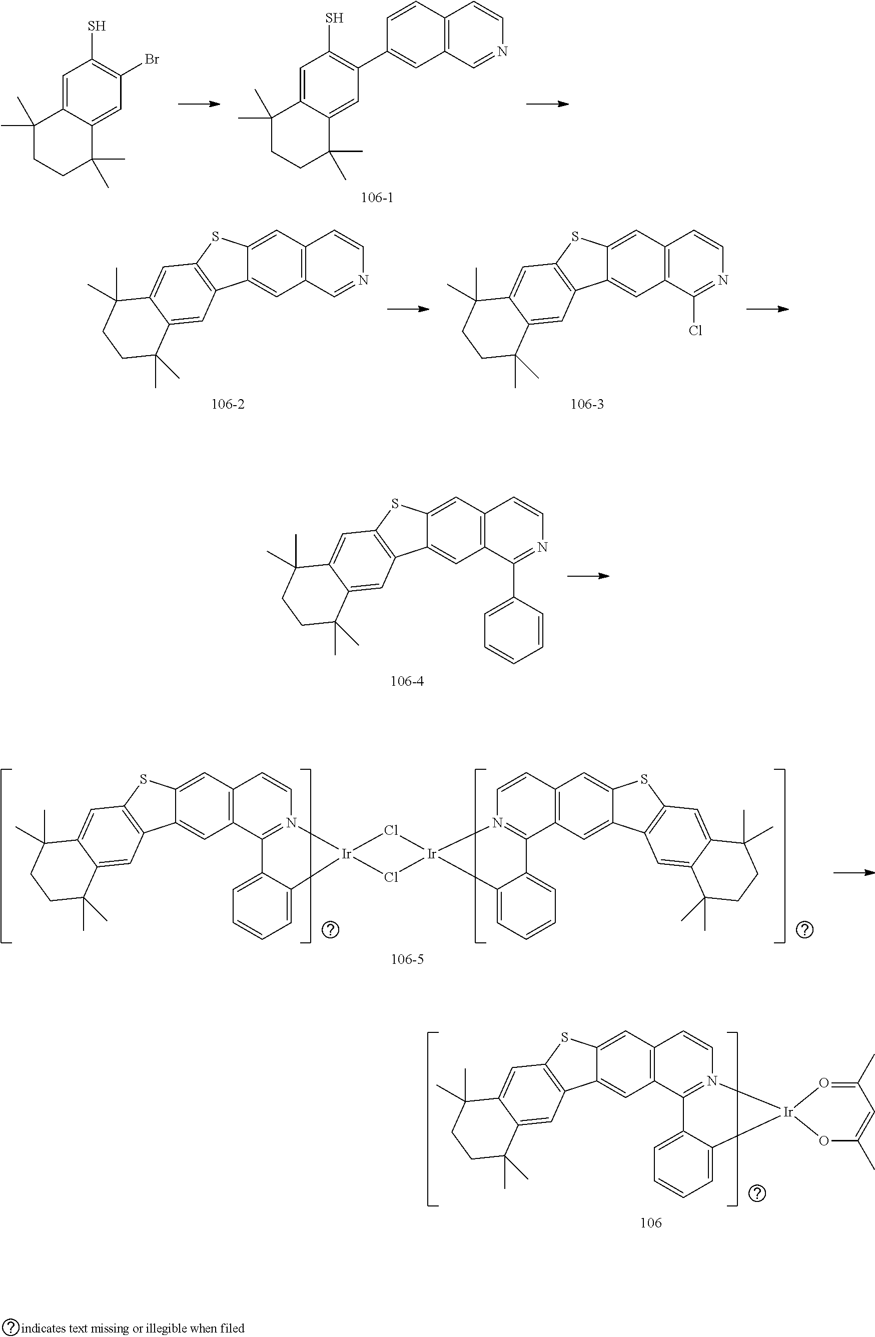

### Preparation of Compound 106-1

3-bromo-5,5,8,8-tetramethyl-5,6,7,8-tetrahydronaphthalene-2-thiol (10 g, 33.4 mmol, 1.0 eq) was dissolved in 1,4-dioxane and distilled water to produce a solution, and then 7-(4,4,5,5-tetramethyl-1,3,2-dioxaborolan-2-yl)isoquinoline (1.1 eq), Pd(PPh₃)₄ (0.05 eq), and K₂CO₃ (3.0 eq) were added thereto, followed by stirring at 110° C. for 8 hours. After completion of a reaction, the mixed solution was cooled to room temperature and was subjected to extraction using distilled water and dichloromethane. An organic layer was dried with anhydrous MgSO₄, and then filtered. The solvent was removed from the filtrate using a rotary evaporator, and then, the residue was purified by column chromatography using dichloromethane and hexane as a developing solvent to obtain a compound 106-1 (11.0 g, 95%).

MS (m/z): 347.17

### Preparation of Compound 106-2

The compound 106-1 (11.0 g, 31.7 mmol, 1.0 eq) was dissolved in DMSO, and then PdCl₂ (0.05 eq) was added thereto, followed by stirring at 140° C. for 12 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 106-2 (5.2 g, 48%) was obtained.

MS (m/z): 345.16

### Preparation of Compound 106-3

The compound 106-2 (5.2 g, 15.2 mmol, 1.0 eq) was dissolved in dichloromethane to produce a solution, and then, m-CPBA was added to the solution which in turn was stirred at room temperature for 24 hours. After completion of a reaction, work-up was performed with distilled water and dichloromethane, and then, an organic layer was concentrated. A concentrated residue was dissolved in POCl₃ (40 ml), followed by stirring at 80° C. for 4 hours. After a reaction was completed, POCl₃ was removed therefrom with a rotary evaporator, and then, sat. NaHCO₃ aqueous solution was added thereto for neutralization thereof. Further work-up was performed with distilled water and dichloromethane, the organic layer was dried with anhydrous MgSO₄, and then filtered. The solvent was removed from the filtrate with a rotary evaporator, and then, the residue was purified by column chromatography using dichloromethane and hexane as a developing solvent. Thus, a compound 106-3 (5.0 g, 88%) was obtained.

MS (m/z): 379.12

### Preparation of Compound 106-4

The compound 106-3 (5.0 g, 13.3 mmol, 1.0 eq) was dissolved in 1,4-dioxane and distilled water to produce a solution, and then phenylboronic acid (1.1 eq), Pd(PPh₃)₄ (0.05 eq), and K₂CO₃ (3.0 eq) were added to the solution which in turn was stirred for 8 hours at 110 degrees C. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 106-4 (5.2 g, 93%) was obtained.

MS (m/z): 421.19

### Preparation of Compound 106-5

The compound 106-4 (5.2 g, 12.3 mmol, 2.0 eq) and iridium (III) chloride hydrate (1.0 eq) were dissolved in 2-ethoxyethanol and distilled water, followed by stirring at 110° C. for 24 hours under nitrogen reflux. A reaction mixture was cooled to room temperature, and then, a resulting solid was filtered and washed with methanol. The solid was vacuum dried to obtain a compound 106-5 (6.0 g, 92%).

MS (m/z): 2136.58

### Preparation of Compound 106

The compound 106-5 (6.0 g, 11.3 mmol, 1.0 eq) and pentane-2,4-dione (2.0 eq) was dissolved in 2-ethoxyethanol, followed by stirring for 24 hours at 110° C. under nitrogen reflux. After completion of a reaction, the mixed solution was cooled to room temperature and was subjected to extraction using distilled water and dichloromethane. An organic layer was dried with anhydrous MgSO₄, and then filtered. The solvent was removed from the filtrate using a rotary evaporator. Then, the residue was purified by column chromatography using dichloromethane and hexane as a developing solvent. Thus, a compound 106 (5.6 g, 88%) was obtained.

MS (m/z): 1132.36

### Preparation Example 16: Preparation of Compound 120

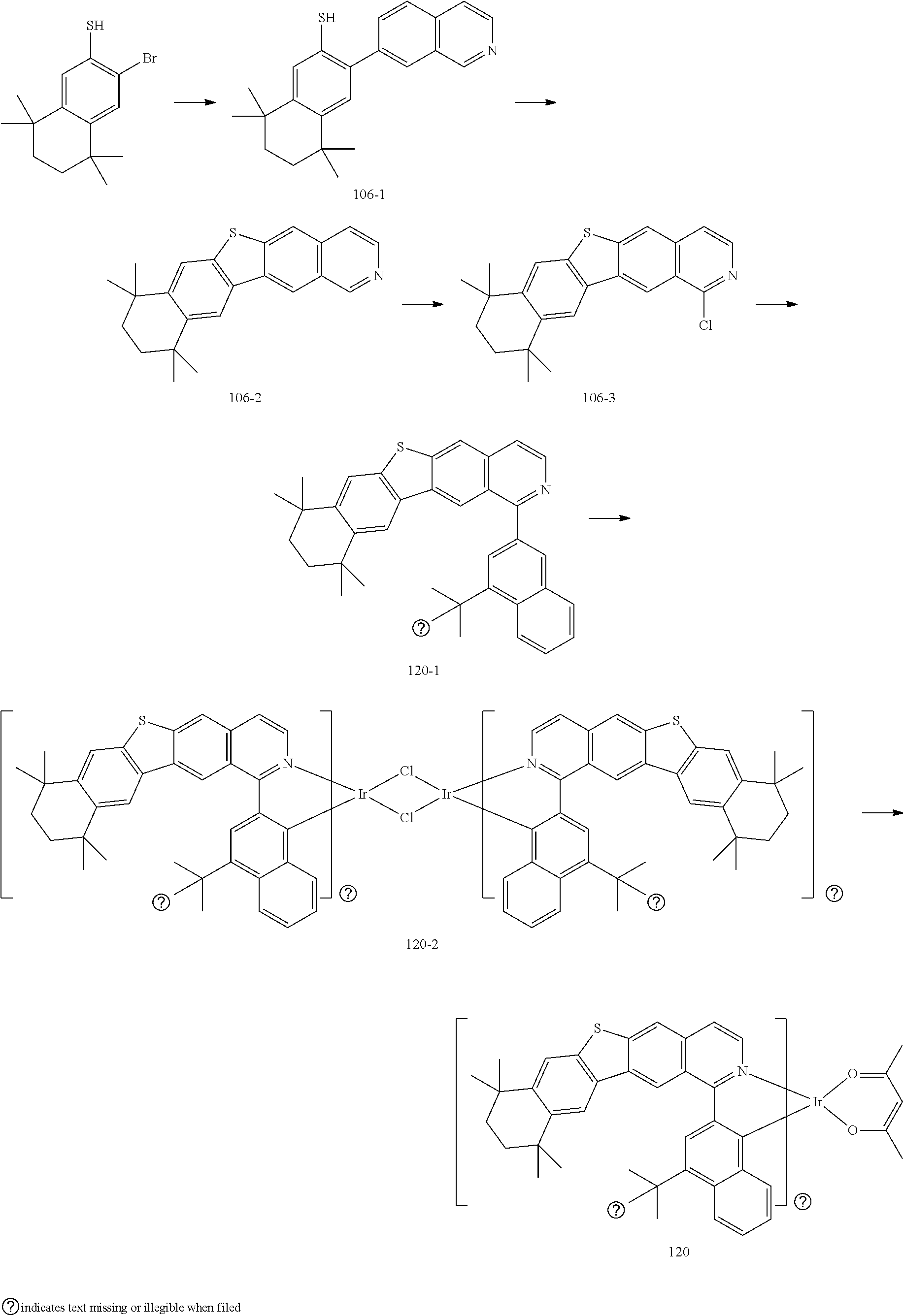

### Preparation of Compound 120-1

The compound 106-3 (10.0 g, 26.3 mmol, 1.0 eq) was dissolved in 1,4-dioxane and distilled water to produce a solution, and then 4,4,5,5-tetramethyl-2-(4-(propan-2-yl-2-d)naphthalen-2-yl)-1,3,2-dioxaborolane (1.1 eq), Pd(PPh₃)₄ (0.05 eq), and K₂CO₃ (3.0 eq) were added to the solution, which in turn, was stirred at 110° C. for 8 hours. After completion of a reaction, the mixed solution was cooled to room temperature and was subjected to extraction using distilled water and dichloromethane. An organic layer was dried with anhydrous MgSO₄, and then filtered. The solvent was removed from the filtrate with a rotary evaporator, and, subsequently, the residue was purified by column chromatography using dichloromethane and hexane as a developing solvent to obtain a compound 120-1 (12.4 g, 92%).

MS (m/z): 514.26

### Preparation of Compound 120-2

The compound 120-1 (12.4 g, 24.2 mmol, 2.0 eq) and iridium (III) chloride hydrate (1.0 eq) were dissolved in 2-ethoxyethanol and distilled water, followed by stirring at 110° C. for 24 hours under nitrogen reflux. A reaction mixture was cooled to room temperature, and then, a resulting solid was filtered and washed with methanol. The solid was vacuum dried to obtain a compound 120-2 (13.0 g, 90%).

MS (m/z): 2396.73

### Preparation of Compound 120

The compound 120-2 (13.0 g, 21.7 mmol, 1.0 eq) and pentane-2,4-dione (2.0 eq) was dissolved in 2-ethoxyethanol, followed by stirring for 24 hours at 110° C. under nitrogen reflux. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 120 (11.6 g, 85%) was obtained.

MS (m/z): 1262.44

### Preparation Example 17: Preparation of Compound 121

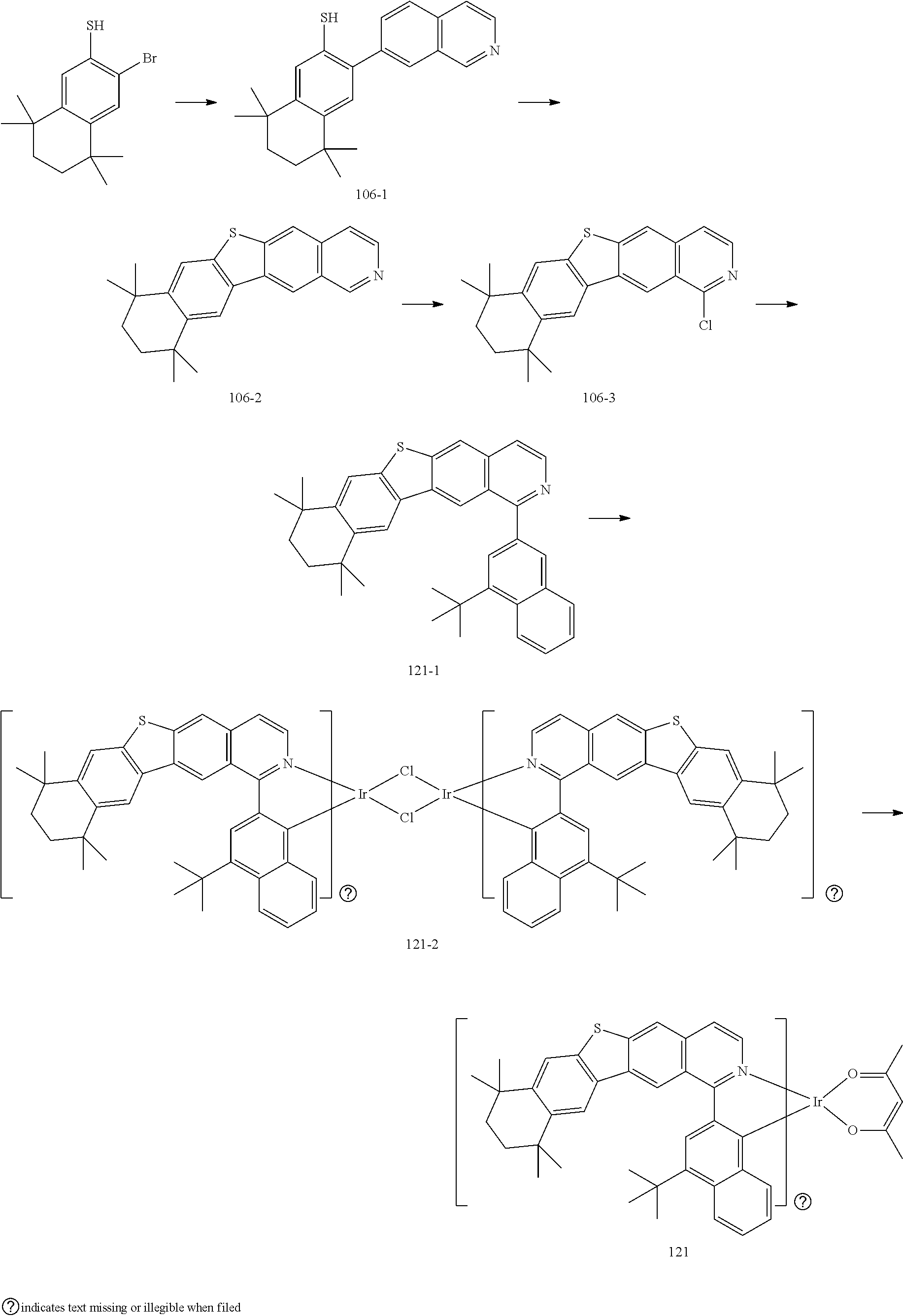

### Preparation of Compound 121

A compound 121 was obtained in the same manner as the preparation method of the compound 120 in Preparation Example 16 except that 2-(4-(tert-butyl)naphthalen-2-yl)-4,4,5,5-tetramethyl-1,3,2-dioxaborolane was used instead of 4,4,5,5-tetramethyl-2-(4-(propan-2-yl-2-d)naphthalen-2-yl)-1,3,2-dioxaborolane in the preparation of the compound 120-1 of Preparation Example 16.

MS (m/z): 1275.45

### Preparation Example 18: Preparation of Compound 133

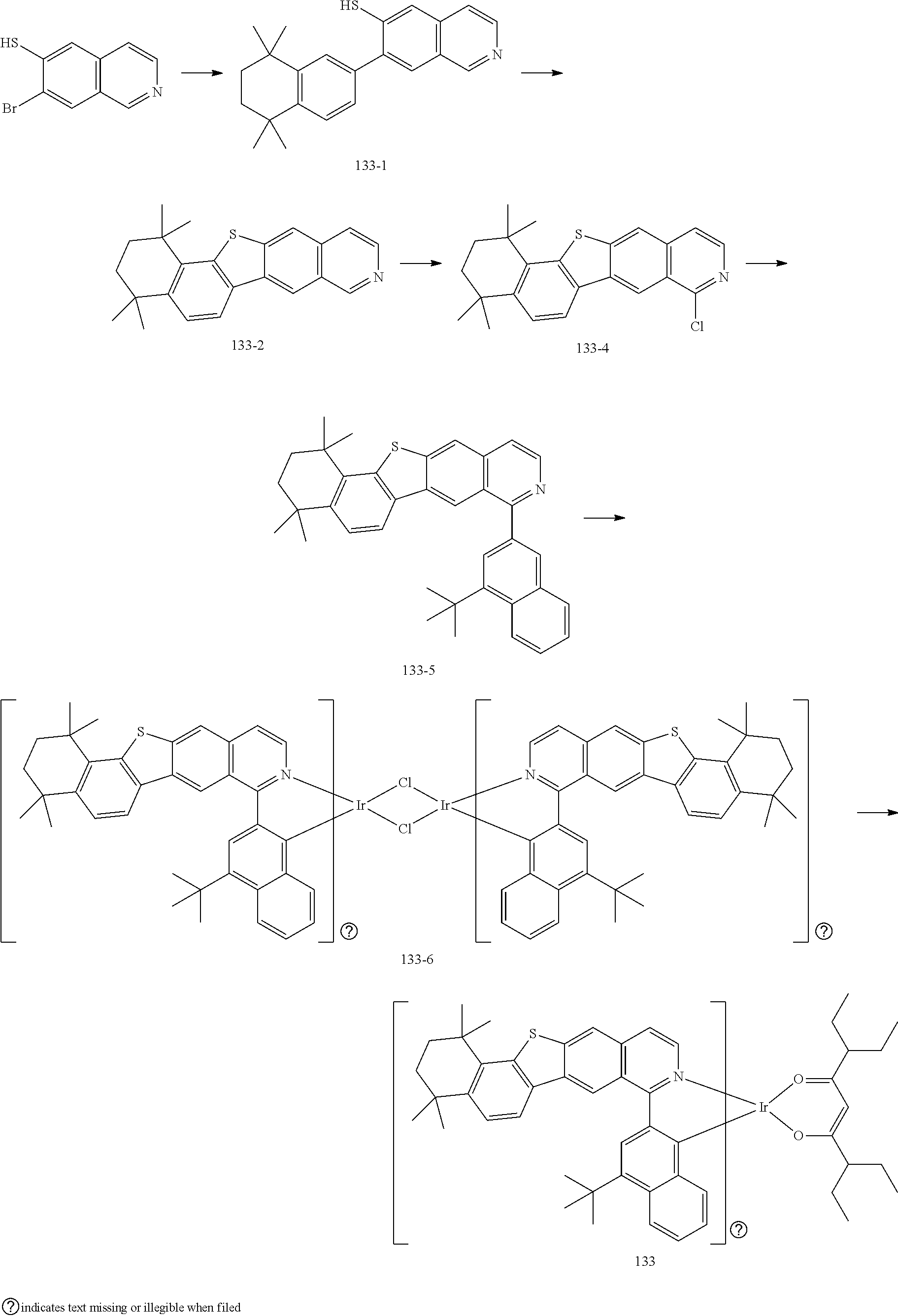

### Preparation of Compound 133-1

7-bromoisoquinoline-6-thiol (10 g, 41.6 mmol, 1.0 eq) was dissolved in 1,4-dioxane and distilled water to produce a solution, and then 4,4,5,5-tetramethyl-2-(5,5,8,8-tetramethyl-5,6,7,8-tetrahydronaphthalen-2-yl)-1,3,2-dioxaborolane (1.1 eq), Pd(PPh₃)₄ (0.05 eq), and K₂CO₃ (3.0 eq) were added to the solution which in turn was stirred for 8 hours at 110 degrees C. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as the developing solvent. Thus, a compound 133-1 (13.5 g, 94%) was obtained.

MS (m/z): 347.17

### Preparation of Compound 133-2

The compound 133-1 (13.5 g, 39.1 mmol, 1.0 eq) was dissolved in DMSO to produce a solution, and then, PdCl₂ (0.05 eq) was added thereto, followed by stirring at 140° C. for 12 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 133-2 (6.5 g, 48%) was obtained.

MS (m/z): 345.16

### Preparation of Compound 133-3

The compound 133-2 (6.5 g, 18.7 mmol, 1.0 eq) was dissolved in dichloromethane to produce a solution, and then, m-CPBA was added to the solution which in turn was stirred at room temperature for 24 hours. After completion of a reaction, work-up was performed with distilled water and dichloromethane, and then, an organic layer was concentrated. A concentrated residue was dissolved in POCl₃ (40 ml), followed by stirring at ° C. for 4 hours. After a reaction was completed, POCl₃ was removed therefrom with a rotary evaporator, and then, sat. NaHCO₃ aqueous solution was added thereto for neutralization thereof. Further work-up was performed with distilled water and dichloromethane, the organic layer was dried with anhydrous MgSO₄, and then filtered. The solvent was removed from the filtrate with a rotary evaporator, and then the residue was purified by column chromatography using dichloromethane and hexane as a developing solvent to obtain a compound 133-3 (6.7 g, 90%).

MS (m/z): 379.12

### Preparation of Compound 133-4

The compound 133-3 (6.7 g, 17.8 mmol, 1.0 eq) was dissolved in 1,4-dioxane and distilled water to produce a solution, and then 2-(4-(tert-butyl)naphthalen-2-yl)-4,4,5,5-tetramethyl-1,3,2-dioxaborolane (1.1 eq), Pd(PPh₃)₄ (0.05 eq), and K₂CO₃ (3.0 eq) were added thereto, followed by stirring at 110° C. for 8 hours. After completion of a reaction, the mixed solution was cooled to room temperature and was subjected to extraction using distilled water and dichloromethane. An organic layer was dried with anhydrous MgSO₄, and then filtered. The solvent was removed from the filtrate using a rotary evaporator, and then the residue was purified by column chromatography using dichloromethane and hexane as a developing solvent to obtain a compound 133-4 (8.7 g, 93%).

MS (m/z): 527.26

### Preparation of Compound 133-5

The compound 133-4 (8.7 g, 16.5 mmol, 2.0 eq) and iridium (III) chloride hydrate (1.0 eq) were dissolved in 2-ethoxyethanol and distilled water, followed by stirring at 110° C. for 24 hours under nitrogen reflux. A reaction mixture was cooled to room temperature, and then, a resulting solid was filtered and washed with methanol. The solid was vacuum dried to obtain a compound 133-5 (9.4 g, 91%).

MS (m/z): 2517.84

### Preparation of Compound 133

The compound 133-5 (9.4 g, 15.0 mmol, 1.0 eq) and 3,7-diethylnonane-4,6-dione (2.0 eq) was dissolved in 2-ethoxyethanol, followed by stirring at 110° C. for 24 hours under nitrogen reflux. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 133 (9.6 g, 89%) was obtained.

MS (m/z): 1443.64

### Preparation Example 19: Preparation of Compound 134

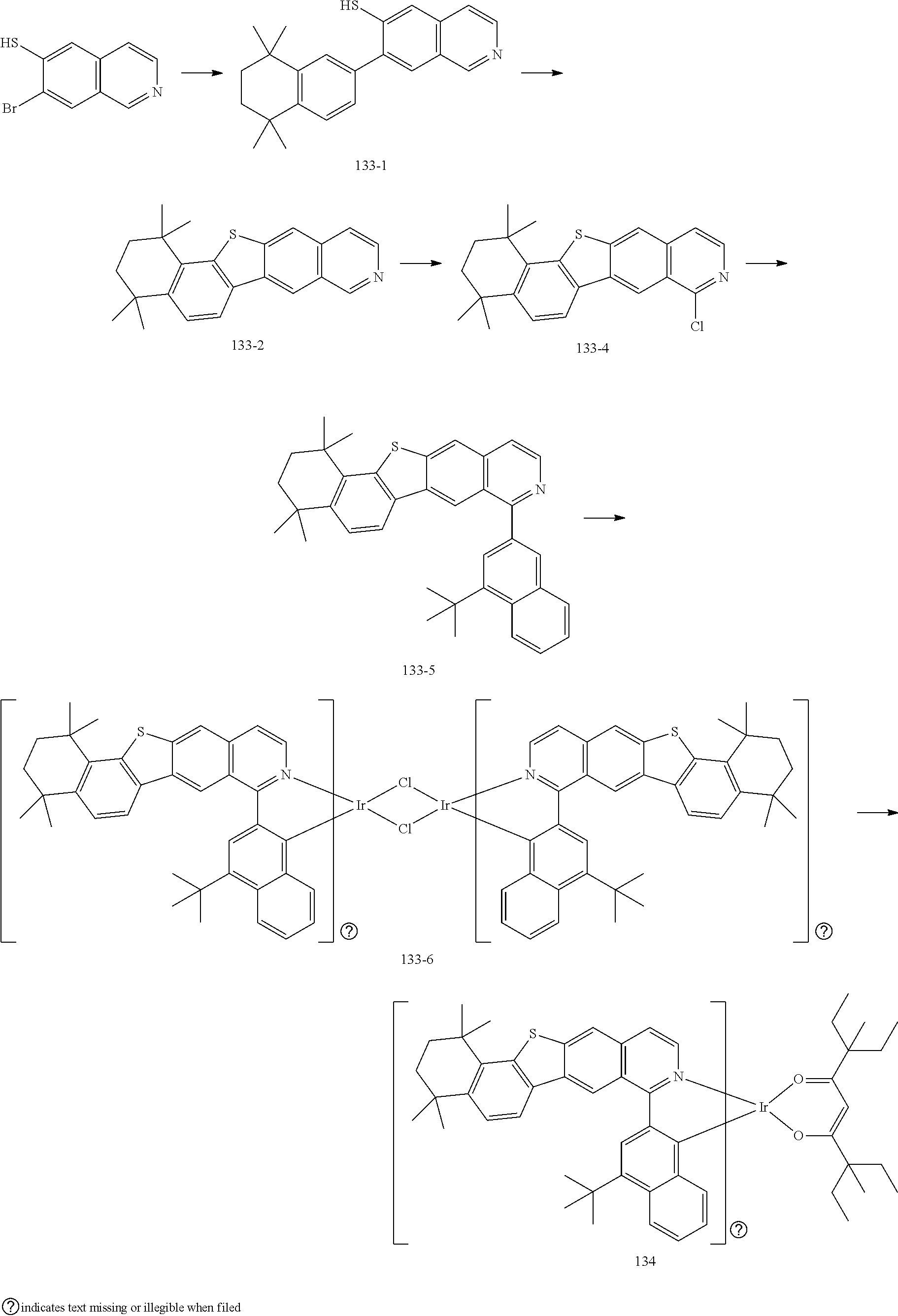

### Preparation of compound 134

A compound 134 was obtained in the same manner as the preparation method of the compound 133 in Preparation Example 18, except for using 3,7-diethyl-3,7-dimethylnonane-4,6-dione instead of 3,7-diethylnonane-4,6-dione as in Preparation Example 18.

MS (m/z): 1471.67

### Preparation Example 20: Preparation of Compound 135

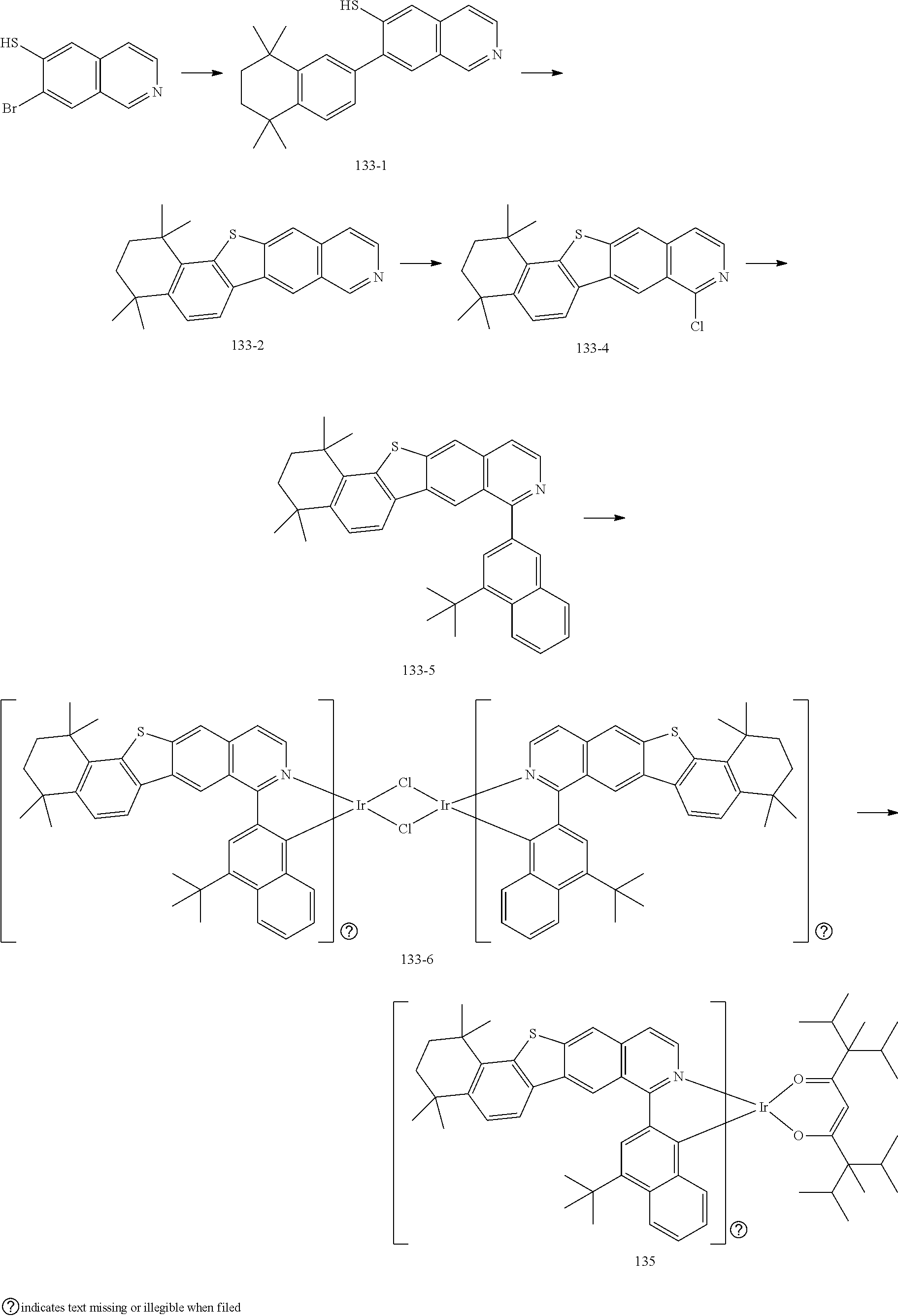

### Preparation of Compound 135

A compound 135 was obtained in the same manner as the preparation method of the compound 133 in Preparation Example 18, except for using 3,7-diisopropyl-2,3,7,8-tetramethylnonane-4,6-dione instead of 3,7-diethylnonane-4,6-dione as in Preparation Example 18.

MS (m/z): 1527.73

### Preparation Example 21: Preparation of Compound 139

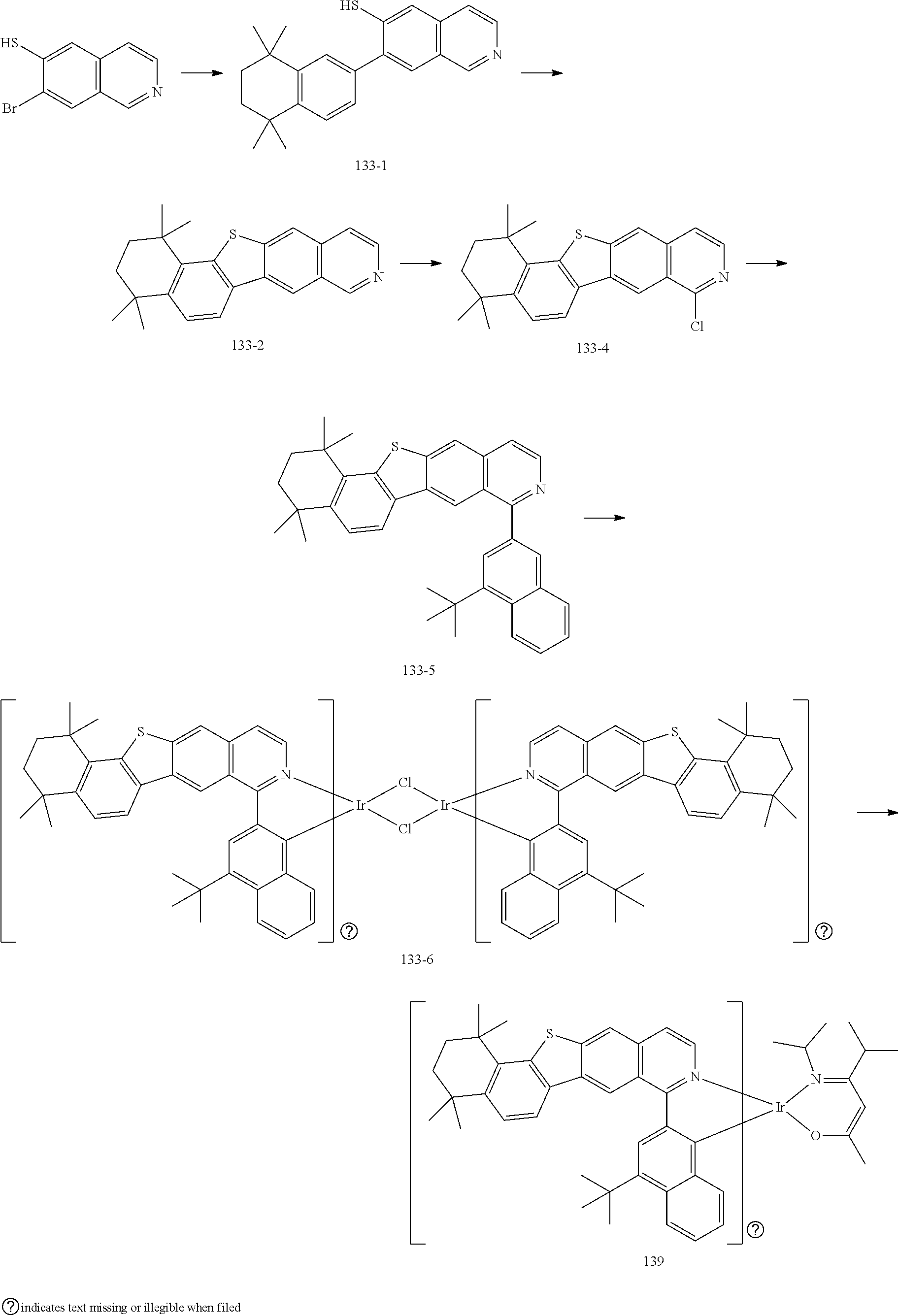

### Preparation of Compound 139

A compound 139 was obtained in the same manner as the preparation method of the compound 133 in Preparation Example 18, except for using (3Z,5E)-5-(isopropylimino)-2,6-dimethylhept-3-en-3-ol instead of 3,7-diethylnonane-4,6-dione as in Preparation Example 18.

MS (m/z): 1428.64

### Preparation Example 22: Preparation of Compound 139

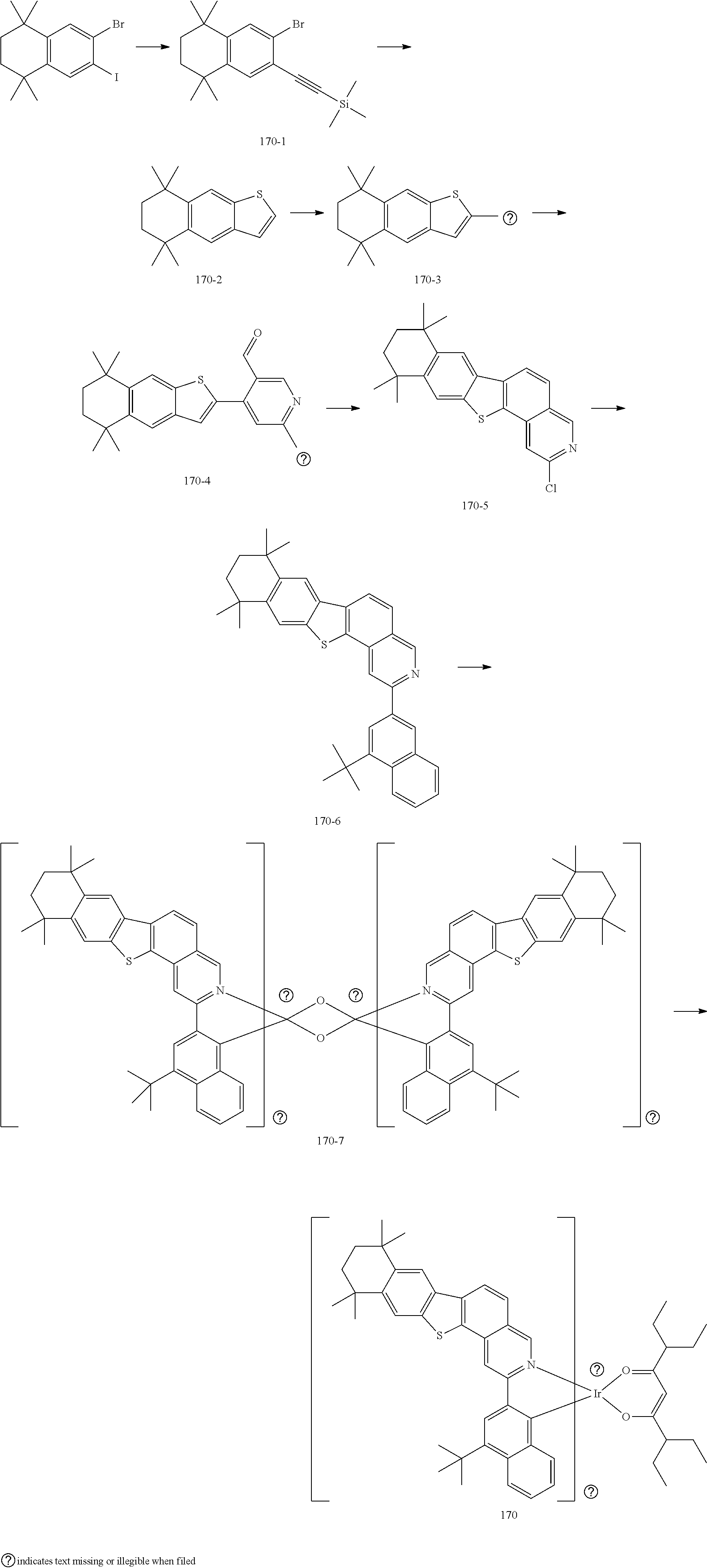

### Preparation of Compound 170-1

6-bromo-7-iodo-1,1,4,4-tetramethyl-1,2,3,4-tetrahydronaphthalene (10 g, mmol, 1.0 eq), Pd(PPh₃)₄ (0.03 eq), and Cut (0.03 eq) were put into a reaction vessel, and Et₃N (300 ml) and trimethylsilylacetylene (1.5 eq) were added thereto under a nitrogen atmosphere. A reaction solution was stirred at 80° C. for 16 hours. After completion of a reaction, the solvent was removed therefrom using a rotary evaporator, and then, the residue was purified by column chromatography using hexane as a developing solvent to obtain a compound 170-1 (8.7 g, 95%).

MS (m/z): 363.41

### Preparation of Compound 170-2

9H₂O (2.4 eq) was dissolved in N-methylpyrrolidone to produce a solution, and then, the compound 170-1 (24.1 mmol) was added to the solution which in turn was stirred at 180° C. for 12 hours. After completion of a reaction, sat. ammonium chloride aqueous solution was added thereto, and a resulting solid was filtered and washed with distilled water and methanol. Then, the washed solid was purified by column chromatography using hexane and dichloromethane as a developing solvent. Thus, a compound 170-2 (4.1 g, 70%) was obtained.

### MS (m/z): 244.40 Preparation of Compound 170-3

The compound 170-2 (16.8 mmol) was dissolved in THF to produce a solution, and then n-BuLi (1.5 eq) was slowly added thereto at −78 degrees C., followed by stirring for 30 minutes. Triisopropyl borate (1.5 eq) was added to the reaction solution, followed by stirring at room temperature for 1 hour, and then HCl was added to the reaction solution which in turn was stirred for 1 hour. After completion of a reaction, extraction was performed with distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as the developing solvent. Thus, a compound 170-3 (4.6 g, 95%) was obtained.

MS (m/z): 288.21

### Preparation of Compound 170-4

The compound 170-3 (4.6 g, 15.9 mmol, 1.0 eq) was dissolved in 1,4-dioxane and distilled water to produce a solution, and then 4-bromo-6-chloronicotinaldehyde (1.1 eq), Pd(PPh₃)₄ (0.05 eq), and K₂CO₃ (3.0 eq) were added to the solution which in turn was stirred at 110° C. for 8 hours. After completion of a reaction, the mixed solution was cooled to room temperature and was subjected to extraction using distilled water and dichloromethane. An organic layer was dried with anhydrous MgSO₄, and then filtered. The solvent was removed from the filtrate using a rotary evaporator. Then, the residue was purified by column chromatography using dichloromethane and hexane as the developing solvent. Thus, a compound 170-4 (5.6 g, 92%) was obtained.

MS (m/z): 383.93

### Preparation of Compound 170-5

Chloro(methoxymethyl)triphenyl-15-phosphane (1.5 eq) was dissolved in THF to produce a solution, and then, potassium tert-butoxide (1.6 eq) was added thereto at room temperature, followed by stirring for 30 minutes. The compound 154-4 (5.6 g, 14.6 mmol, 1 eq) was added to the reaction solution, followed by stirring at room temperature for 4 hours. After completion of a reaction, extraction was performed with distilled water and ethyl acetate. An organic layer was dried with anhydrous MgSO₄, and then filtered. The solvent was removed from the filtrate using a rotary evaporator. A concentrated residue was dissolved in dichloromethane to produce a solution, and then, methanesulfonic acid was added thereto, followed by stirring under reflux for 4 hours. Thus, a compound 170-5 (4.4 g, 80%) was obtained without further purification.

MS (m/z): 379.95

### Preparation of compound 170-6

The compound 170-5 (4.4 g, 11.6 mmol, 1.0 eq) was dissolved in 1,4-dioxane and distilled water to produce a solution, and then 2-(4-(tert-butyl)naphthalen-2-yl)-4,4,5,5-tetramethyl-1,3,2-dioxaborolane (1.1 eq), Pd(PPh₃)₄ (0.05 eq), and K₂CO₃ (3.0 eq) were added thereto, followed by stirring at 110° C. for 8 hours. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 170-6 (5.7 g, 94%) was obtained.

MS (m/z): 527.77

### Preparation of Compound 170-7

The compound 170-6 (5.7 g, 10.9 mmol, 2.0 eq) and iridium (III) chloride hydrate (1.0 eq) were dissolved in 2-ethoxyethanol and distilled water, followed by stirring for 24 hours at 110° C. under nitrogen reflux. A reaction mixture was cooled to room temperature, and then, a resulting solid was filtered and washed with methanol. The solid was vacuum dried to obtain a compound 170-7 (6.2 g, 91%).

MS (m/z): 2523.48

### Preparation of Compound 170

The compound 170-7 (6.2 g, 9.9 mmol, 1.0 eq) and 3,7-diethylnonane-4,6-dione (2.0 eq) were dissolved in 2-ethoxyethanol, followed by stirring at 110° C. for 24 hours under nitrogen reflux. After completion of a reaction, the mixed solution was cooled to room temperature and was subjected to extraction using distilled water and dichloromethane. An organic layer was dried with anhydrous MgSO₄, and then, filtered. The solvent was removed from the filtrate with a rotary evaporator. Then, the residue was purified by column chromatography using dichloromethane and hexane as a developing solvent. Thus, a compound 170 (4.3 g, 61%) was obtained.

MS (m/z): 1457.07

### Preparation Example 23: Preparation of Compound 176

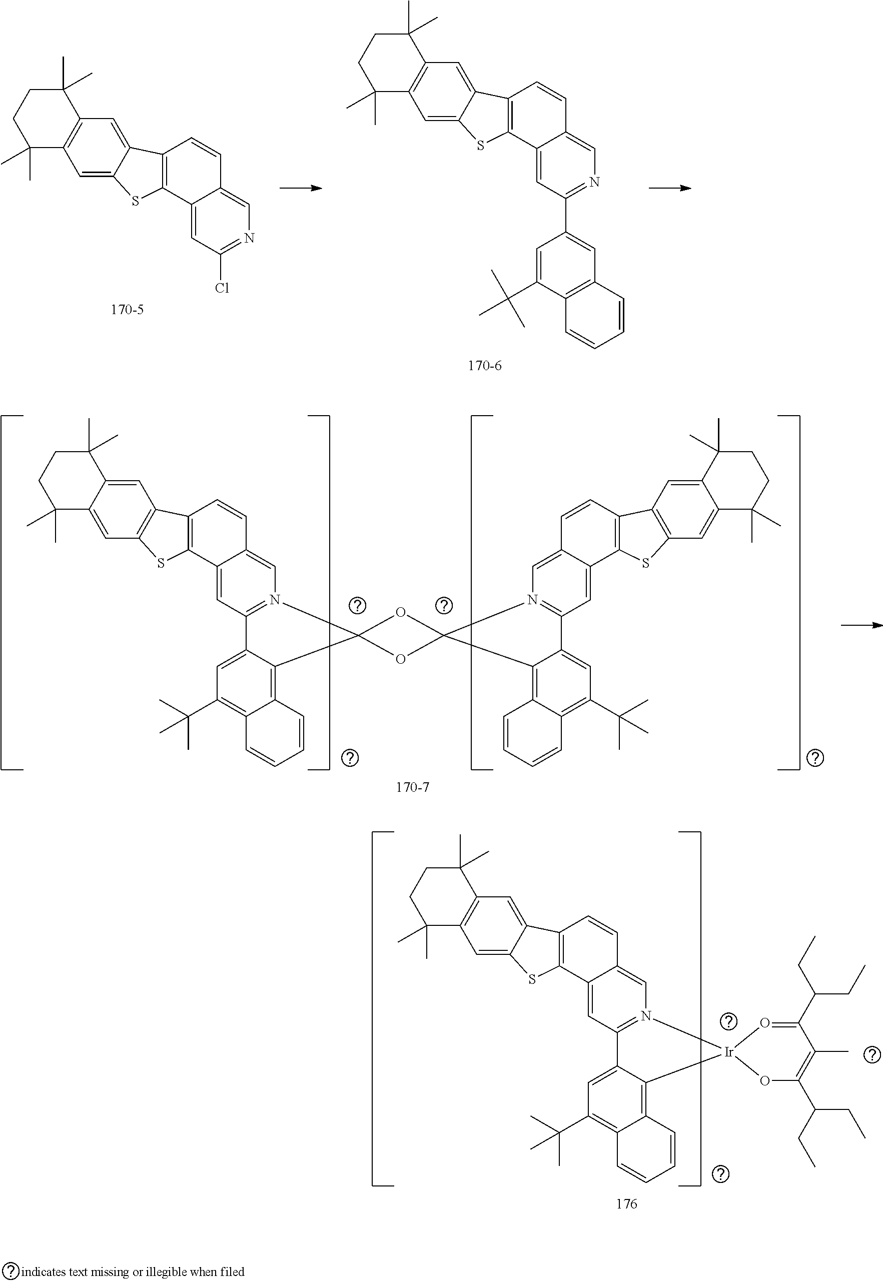

### Preparation of Compound 176

A compound 176 was obtained in the same manner as the preparation method of the compound 170 in Preparation Example 22, except for using (Z)-3,7-diethyl-6-hydroxynon-5-en-4-one-5-d instead of 3,7-diethylnonane-4,6-dione as in Preparation Example 22.

MS (m/z): 1457.65

### Preparation Example 24: Preparation of Compound 177

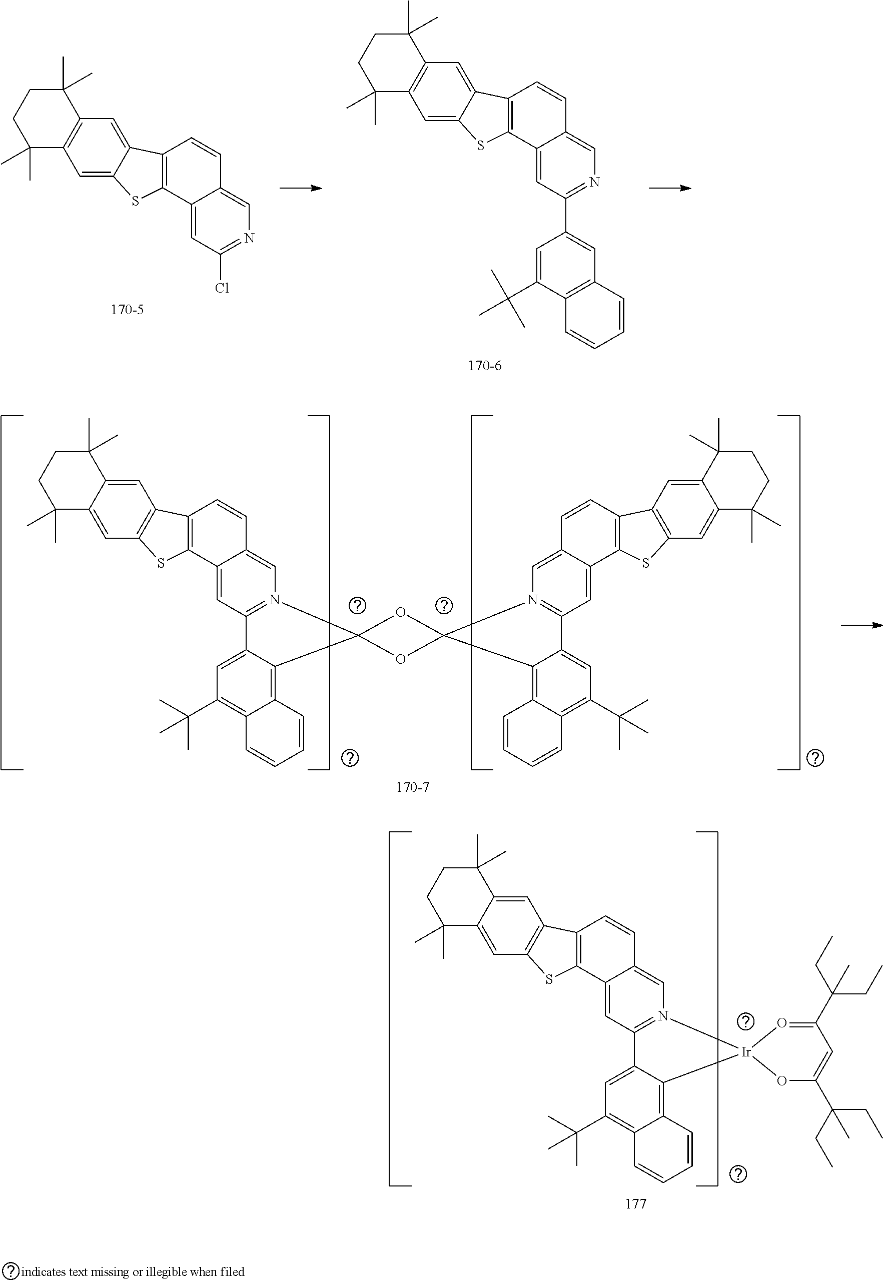

### Preparation of Compound 177

A compound 177 was obtained in the same manner as the preparation method of the compound 170 in Preparation Example 22, except for using 3,7-diethyl-3,7-dimethylnonane-4,6-dione instead of 3,7-diethylnonane-4,6-dione as in Preparation Example 22.

MS (m/z): 1485.12

### Preparation Example 25: Preparation of Compound 179

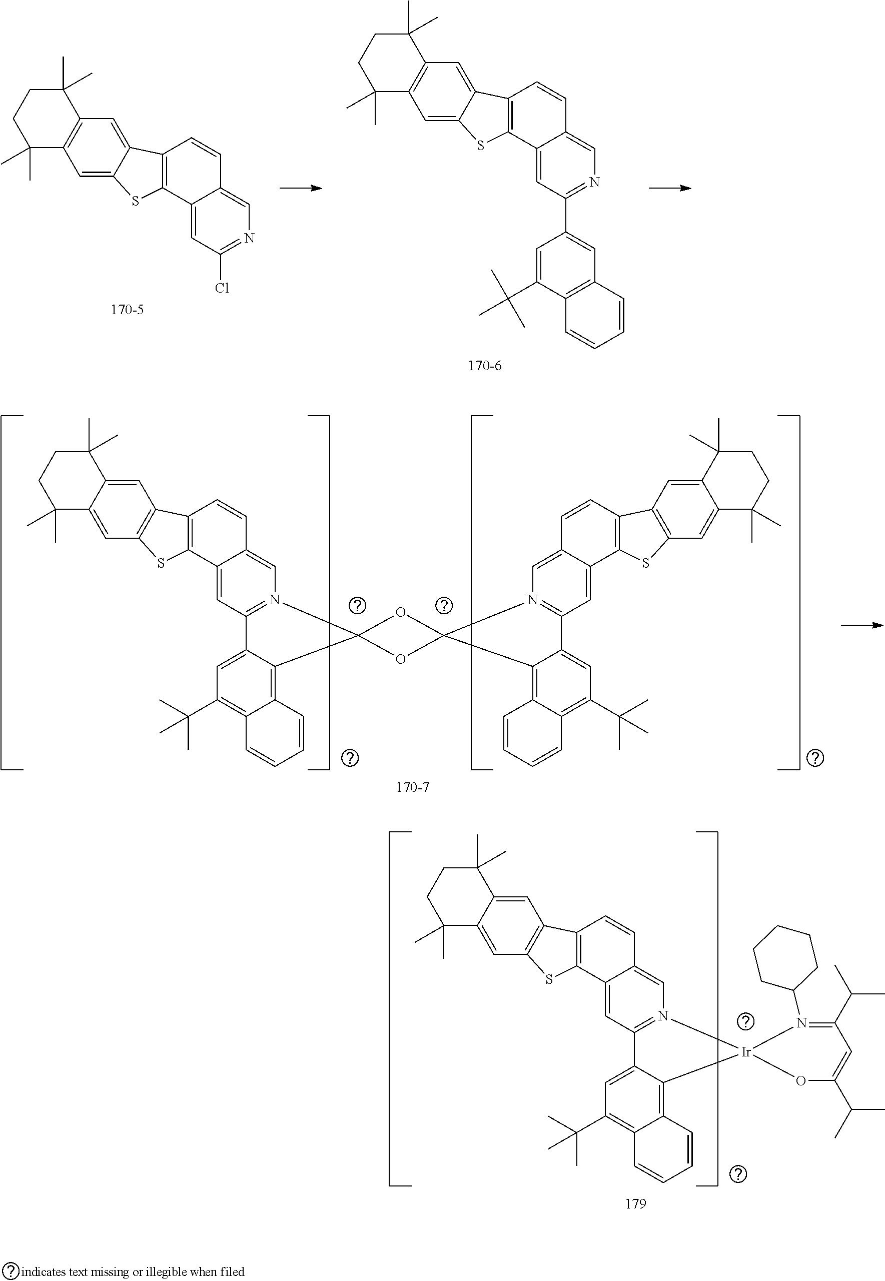

### Preparation of Compound 179

A compound 179 was obtained in the same manner as the preparation method of the compound 170 in Preparation Example 22, except for using (3Z,5E)-5-(cyclohexylimino)-2,6-dimethylhept-3-en-3-ol instead of 3,7-diethylnonane-4,6-dione as in Preparation Example 22.

MS (m/z): 1481.68

### Preparation Example 26: Preparation of Compound 181

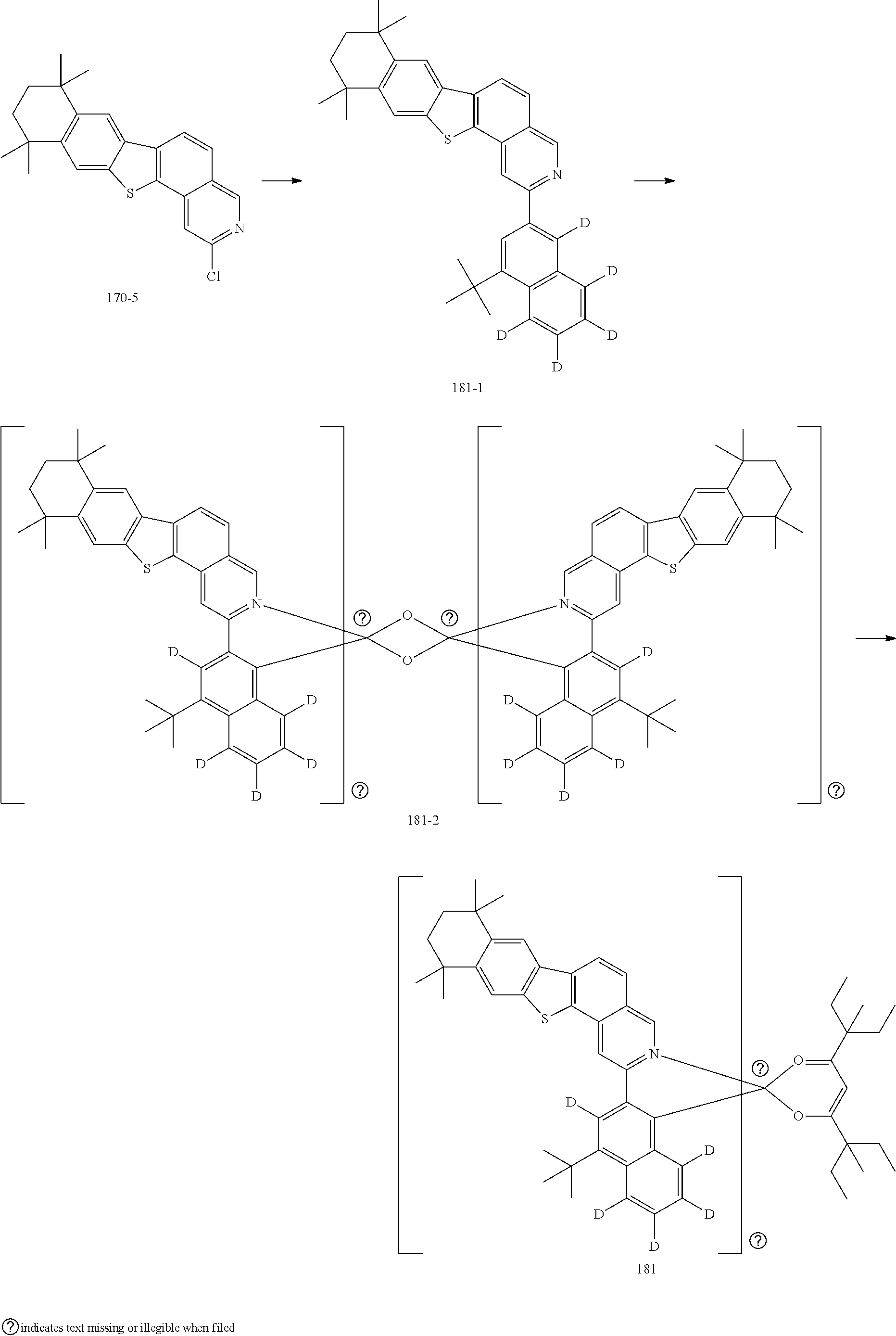

### Preparation of Compound 181

A compound 181 was obtained in the same manner as the preparation method of the compound 170 in Preparation Example 22, except for using 2-(4-(tert-butyl)naphthalen-2-yl-1,3,5,6,7,8-d6)-4,4,5,5-tetramethyl-1,3,2-dioxaborolane instead of 2-(4-(tert-butyl)naphthalen-2-yl)-4,4,5,5-tetramethyl-1,3,2-dioxaborolane as in Preparation Example 22.

MS (m/z): 1493.17

### Preparation Example 27: Preparation of Compound 182

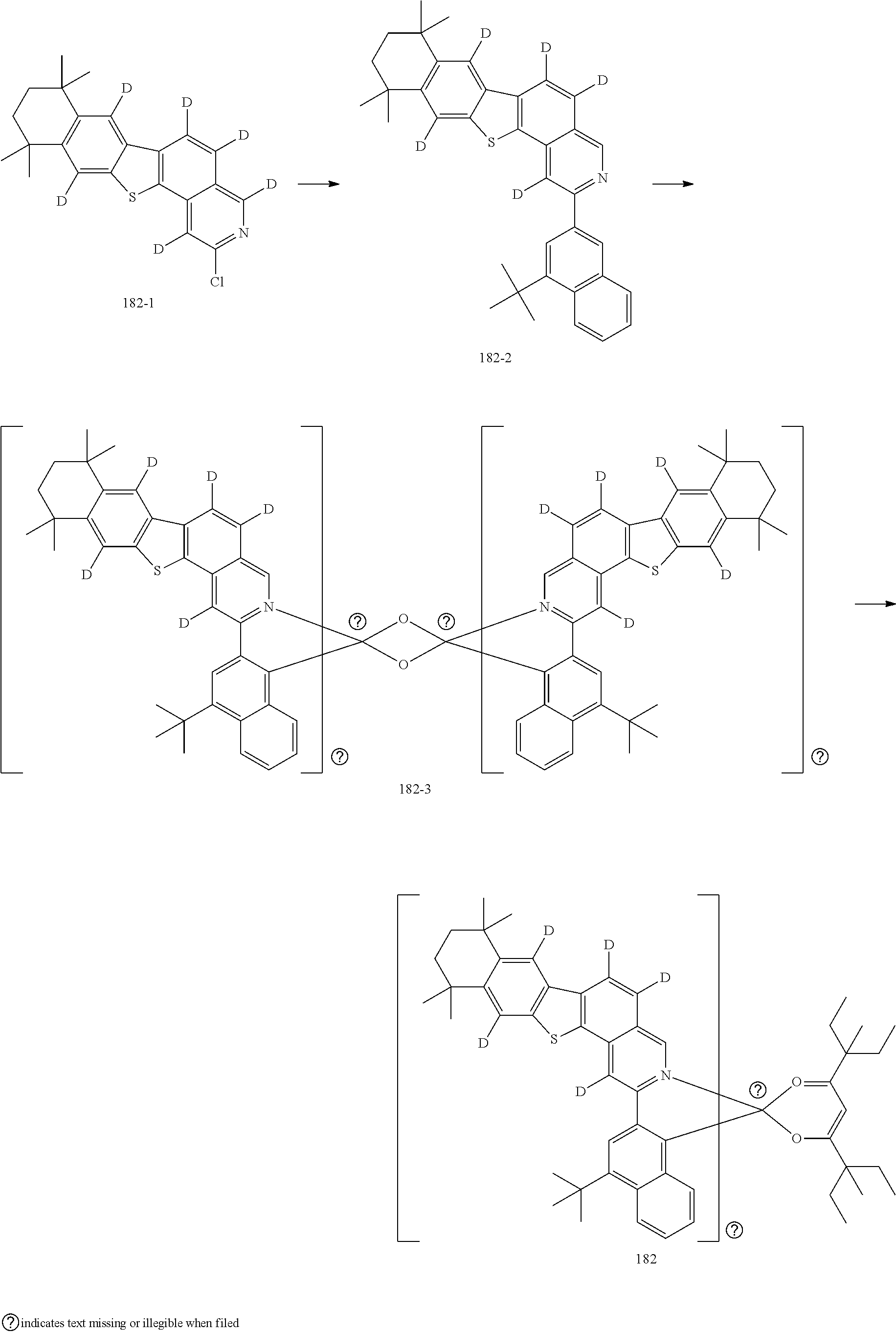

### Preparation of Compound 182

A compound 182 was obtained in the same manner as the preparation method of the compound 170 in Preparation Example 22, except for using 2-chloro-8,8,11,11-tetramethyl-8,9,10,11-tetrahydronaphtho[2′,3′:4,5]thieno[2,3-f]isoquinoline-1,4,5,6,7,12-d6 instead of 2-chloro-8,8,11,11-tetramethyl-8,9,10,11-tetrahydronaphtho[2′,3′:4,5]thieno[2,3-f]isoquinoline.

MS (m/z): 1495.18

### Preparation Example 28: Preparation of Compound 183

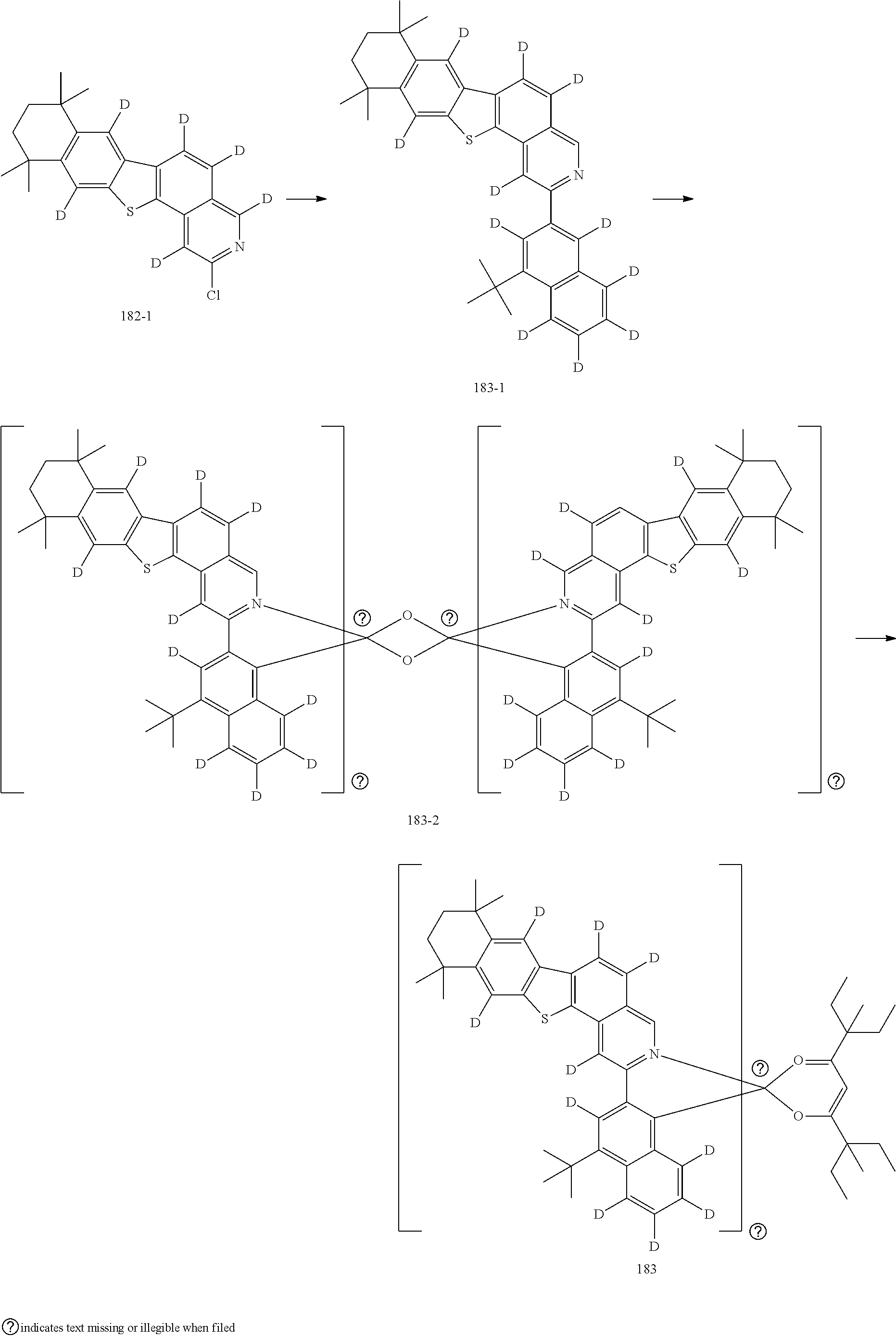

### Preparation of Compound 183

A compound 183 was obtained in the same manner as the preparation method of the compound 182 in Preparation Example 27, except for using 2-(4-(tert-butyl)naphthalen-2-yl-1,3,5,6,7,8-d6)-4,4,5,5-tetramethyl-1,3,2-dioxaborolane instead of 2-(4-(tert-butyl)naphthalen-2-yl)-4,4,5,5-tetramethyl-1,3,2-dioxaborolane.

MS (m/z): 1503.23

### PRESENT EXAMPLES

### Present Example 1

A glass substrate having a thin film of ITO (indium tin oxide) having a thickness of 1,000 Å coated thereon was washed, followed by ultrasonic cleaning with a solvent such as isopropyl alcohol, acetone, or methanol. Then, the glass substrate was dried. Thus, an ITO transparent electrode was formed.

HI-1 as a hole injection material was deposited on the ITO transparent electrode in a thermal vacuum deposition manner. Thus, a hole injection layer having a thickness of 60 nm was formed. Then, NPB as a hole transport material was deposited on the hole injection layer in a thermal vacuum deposition manner. Thus, a hole transport layer having a thickness of 80 nm was formed. Then, CBP as a host material of a light-emitting layer was deposited on the hole transport layer in a thermal vacuum deposition manner. The compound 1 as a dopant was doped into the host material at a doping concentration of 5%. Thus, the light-emitting layer of a thickness of 30 nm was formed. ET-1:Liq (1:1)(30 nm) as a material for an electron transport layer and an electron injection layer was deposited on the light-emitting layer. Then, 100 nm thick aluminum was deposited thereon to form a negative electrode. In this way, an organic light-emitting diode was manufactured. The materials used in Present Example 1 are as follows.

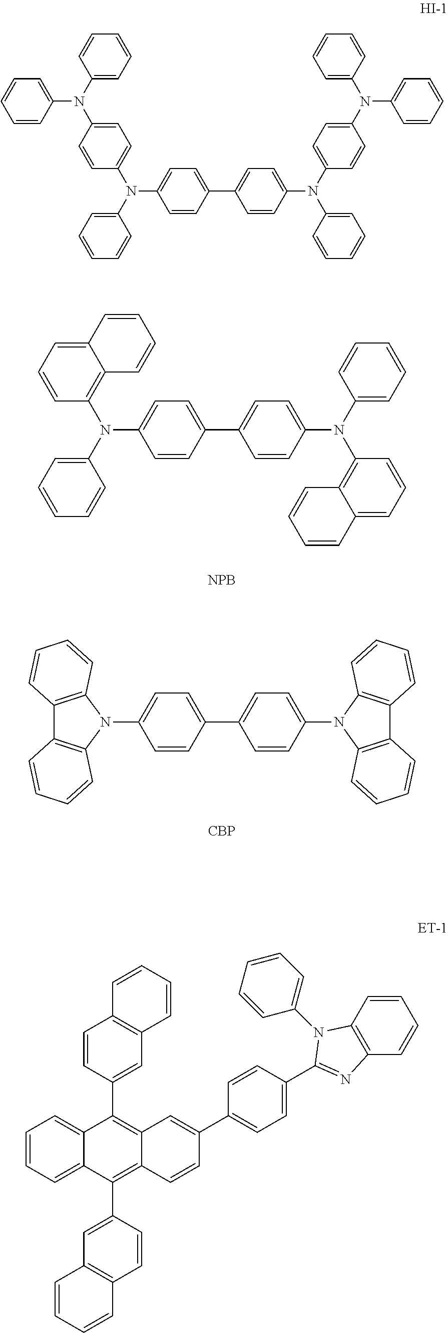 [SMILES: c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1 ; c1ccc(N(c2ccc(-c3ccc(N(c4ccccc4)c4cccc5ccccc45)cc3)cc2)c2cccc3ccccc23)cc1 ; "NPB" ; c1ccc2c(c1)c1ccccc1n2-c1ccc(-c2ccc(-n3c4ccccc4c4ccccc43)cc2)cc1 ; "CBP" ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

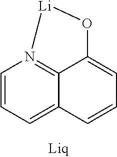

HI-1 is NPNPB, and ET-1 is ZADN.

### Present Example 2

An organic light-emitting diode was manufactured in the same manner as in Present Example 1, except that the compound 7 was used instead of the compound 1 as in Present Example 1.

### Present Example 3

An organic light-emitting diode was manufactured in the same manner as in Present Example 1, except that the compound 18 was used instead of the compound 1 as in Present Example 1.

### Present Example 4

An organic light-emitting diode was manufactured in the same manner as in Present Example 1, except that the compound 22 was used instead of the compound 1 as in Present Example 1.

### Present Example 5

An organic light-emitting diode was manufactured in the same manner as in Present Example 1, except that the compound 40 was used instead of the compound 1 as in Present Example 1.

### Present Example 6

An organic light-emitting diode was manufactured in the same manner as in Present Example 1, except that the compound 41 was used instead of the compound 1 as in Present Example 1.

### Present Example 7

An organic light-emitting diode was manufactured in the same manner as in Present Example 1, except that the compound 44 was used instead of the compound 1 as in Present Example 1.

### Present Example 8

An organic light-emitting diode was manufactured in the same manner as in Present Example 1, except that the compound 45 was used instead of the compound 1 as in Present Example 1.

### Present Example 9

An organic light-emitting diode was manufactured in the same manner as in Present Example 1, except that the compound 46 was used instead of the compound 1 as in Present Example 1.

### Present Example 10

An organic light-emitting diode was manufactured in the same manner as in Present Example 1, except that the compound 47 was used instead of the compound 1 as in Present Example 1.

### Present Example 11

An organic light-emitting diode was manufactured in the same manner as in Present Example 1, except that the compound 54 was used instead of the compound 1 as in Present Example 1.

### Present Example 12

An organic light-emitting diode was manufactured in the same manner as in Present Example 1, except that the compound 77 was used instead of the compound 1 as in Present Example 1.

### Present Example 13

An organic light-emitting diode was manufactured in the same manner as in Present Example 1, except that the compound 85 was used instead of the compound 1 as in Present Example 1.

### Present Example 14

An organic light-emitting diode was manufactured in the same manner as in Present Example 1, except that the compound 86 was used instead of the compound 1 as in Present Example 1.

### Present Example 15

An organic light-emitting diode was manufactured in the same manner as in Present Example 1, except that the compound 106 was used instead of the compound 1 as in Present Example 1.

### Present Example 16

An organic light-emitting diode was manufactured in the same manner as in Present Example 1, except that the compound 120 was used instead of the compound 1 as in Present Example 1.

### Present Example 17

An organic light-emitting diode was manufactured in the same manner as in Present Example 1, except that the compound 121 was used instead of the compound 1 as in Present Example 1.

### Present Example 18

An organic light-emitting diode was manufactured in the same manner as in Present Example 1, except that the compound 133 was used instead of the compound 1 as in Present Example 1.

### Present Example 19

An organic light-emitting diode was manufactured in the same manner as in Present Example 1, except that the compound 134 was used instead of the compound 1 as in Present Example 1.

### Present Example 20

An organic light-emitting diode was manufactured in the same manner as in Present Example 1, except that the compound 135 was used instead of the compound 1 as in Present Example 1.

### Present Example 21

An organic light-emitting diode was manufactured in the same manner as in Present Example 1, except that the compound 139 was used instead of the compound 1 as in Present Example 1.

### Present Example 22

An organic light-emitting diode was manufactured in the same manner as in Present Example 1, except that the compound 170 was used instead of the compound 1 as in Present Example 1.

### Present Example 23

An organic light-emitting diode was manufactured in the same manner as in Present Example 1, except that the compound 176 was used instead of the compound 1 as in Present Example 1.

### Present Example 24

An organic light-emitting diode was manufactured in the same manner as in Present Example 1, except that the compound 177 was used instead of the compound 1 as in Present Example 1.

### Present Example 25

An organic light-emitting diode was manufactured in the same manner as in Present Example 1, except that the compound 179 was used instead of the compound 1 as in Present Example 1.

### Present Example 26

An organic light-emitting diode was manufactured in the same manner as in Present Example 1, except that the compound 181 was used instead of the compound 1 as in Present Example 1.

### Present Example 27

An organic light-emitting diode was manufactured in the same manner as in Present Example 1, except that the compound 182 was used instead of the compound 1 as in Present Example 1.

### Present Example 28

An organic light-emitting diode was manufactured in the same manner as in Present Example 1, except that the compound 183 was used instead of the compound 1 as in Present Example 1.

### Comparative Example 1

An organic light-emitting diode was manufactured in the same manner as in Present Example 1, except that RD having a following structure was used instead of the compound 1 as in Present Example 1.

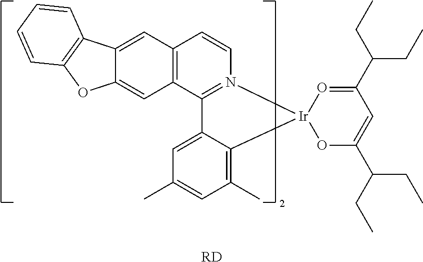

### Experimental Example

The organic light-emitting diode as manufactured in each of Present Examples 1 to 28 and Comparative Example 1 was connected to an external power source, and characteristics of the organic light-emitting diode were evaluated at room temperature using a current source and a photometer.

Operation voltage (%), external quantum efficiency (EQE; %), lifetime characteristics (LT95; %), full width at half maximum (FWHM) (%), and an aspect ratio (%) were measured at a current density of 10 mA/cm², and were calculated as relative values to those of Comparative Example 1, and the results are shown in the following Table 1.

LT95 lifetime refers to a time it takes for the display element to lose 5% of its initial brightness. LT95 is the customer specification that may be the most difficult to meet. Whether or not image burn-in occurs on the display may be determined based on the LT95.

The full width at half maximum (FWHM) means a wavelength width corresponding to ½ of the maximum value of a curve representing a wavelength. A narrow FWHM means that a purity of the color may be high, which means that the light-emitting diode renders a desired color based on a combination of light beams may be implemented at high efficiency and a high color gamut may be obtained. The full width at half maximum was evaluated via photoluminescence (PL) intensity measurement, and a model/maker of the measurement equipment was FS-5/Edinburgh Instruments.

The aspect ratio was calculated based on {(a length at a long axis of a molecule centered on a metal (N-Metal-N direction))/(a length at a short axis perpendicular to the long axis of the molecule centered on the metal)}. The aspect ratio was measured based on a calculating result of a distance between atoms in a molecule using a Gaussian molecular calculation program (Gaussian 16).

TABLE 1

| | | Operation | EQE | LT95 | FWHM | Aspect ratio |
|---|---|---|---|---|---|---|
| | | voltage | (%, | (%, | (%, | (%, |
| | | (%, relative | relative | relative | relative | relative |
| Example | Dopant | value) | value) | value) | value) | value) |
| Comparative | Compound RD | 100 | 100 | 100 | 100 | 100 |
| Example 1 | | | | | | |
| Present | Compound 1 | 94 | 118 | 125 | 55 | 128 |
| Example 1 | | | | | | |
| Present | Compound 7 | 95 | 120 | 128 | 56 | 129 |
| Example 2 | | | | | | |
| Present | Compound 18 | 96 | 119 | 126 | 56 | 130 |
| Example 3 | | | | | | |
| Present | Compound 22 | 94 | 121 | 128 | 55 | 130 |
| Example 4 | | | | | | |
| Present | Compound 40 | 95 | 115 | 120 | 56 | 115 |
| Example 5 | | | | | | |
| Present | Compound 41 | 96 | 118 | 130 | 51 | 123 |
| Example 6 | | | | | | |
| Present | Compound 44 | 96 | 120 | 132 | 51 | 122 |
| Example 7 | | | | | | |
| Present | Compound 45 | 96 | 120 | 135 | 50 | 123 |
| Example 8 | | | | | | |
| Present | Compound 46 | 97 | 122 | 125 | 50 | 125 |
| Example 9 | | | | | | |
| Present | Compound 47 | 97 | 122 | 128 | 50 | 125 |
| Example 10 | | | | | | |
| Present | Compound 54 | 97 | 122 | 130 | 50 | 125 |
| Example 11 | | | | | | |
| Present | Compound 77 | 96 | 124 | 130 | 51 | 125 |
| Example 12 | | | | | | |
| Present | Compound 85 | 95 | 125 | 125 | 50 | 125 |
| Example 13 | | | | | | |
| Present | Compound 86 | 95 | 125 | 125 | 50 | 125 |
| Example 14 | | | | | | |
| Present | Compound 106 | 96 | 130 | 130 | 50 | 125 |
| Example 15 | | | | | | |
| Present | Compound 120 | 96 | 130 | 130 | 50 | 125 |
| Example 16 | | | | | | |
| Present | Compound 121 | 96 | 130 | 130 | 50 | 125 |
| Example 17 | | | | | | |
| Present | Compound 133 | 95 | 128 | 135 | 51 | 123 |
| Example 18 | | | | | | |
| Present | Compound 134 | 95 | 130 | 135 | 52 | 124 |
| Example 19 | | | | | | |
| Present | Compound 135 | 97 | 135 | 128 | 55 | 122 |
| Example 20 | | | | | | |
| Present | Compound 139 | 96 | 133 | 130 | 56 | 120 |
| Example 21 | | | | | | |
| Present | Compound 170 | 96 | 128 | 140 | 50 | 125 |
| Example 22 | | | | | | |
| Present | Compound 176 | 95 | 130 | 145 | 50 | 125 |
| Example 23 | | | | | | |
| Present | Compound 177 | 95 | 130 | 135 | 50 | 125 |
| Example 24 | | | | | | |
| Present | Compound 179 | 96 | 131 | 130 | 55 | 122 |
| Example 25 | | | | | | |
| Present | Compound 181 | 95 | 130 | 155 | 50 | 125 |
| Example 26 | | | | | | |
| Present | Compound 182 | 95 | 129 | 160 | 50 | 125 |
| Example 27 | | | | | | |
| Present | Compound 183 | 95 | 129 | 165 | 50 | 125 |
| Example 28 | | | | | | |

As may be identified from the results of Table 1, the organometallic compound used in each of Present Examples 1 to 28 satisfies the structure represented by the Chemical Formula I of the present disclosure. The organic light-emitting diode in each of Present Examples 1 to 28 had a lower operation voltage and a higher aspect ratio, and improved external quantum efficiency (EQE) and lifetime (LT95) compared to those in Comparative Example 1, which used a dopant that does not satisfy the structure represent by the Chemical Formula I of the present disclosure. Further, the organic light-emitting diode in each of Present Examples 1 to 28 had a narrow full width at half maximum, resulting in improved color purity.

Example embodiments of the present disclosure can also be described as follows:

An organometallic compound according to an example embodiment of the present disclosure may represented by Chemical Formula I:

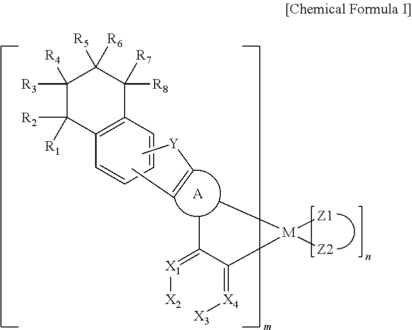

wherein in the Chemical Formula I,
M may represent a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au);
each of R₁ to R₈ may independently represent one selected from the group consisting of hydrogen, deuterium, a substituted or unsubstituted C1 to C20 alkyl group, and a substituted or unsubstituted C3 to C20 bicycloalkyl group;
Y may represent one selected from the group consisting of BR₉, CR₉R₁₀, C═O, CNR₉, SiR₉R₁₀, NR₉, PR₉, AsR₉, SbR₉, P(O)R₉, P(S)R₉, P(Se)R₉, As(O)R₉, As(S)R₉, As(Se)R₉, Sb(O)R₉, Sb(S)R₉, Sb(Se)R₉, O, S, Se, Te, SO, SO₂, SeO, SeO₂, TeO, and TeO₂;
each of R₉ and R₁₀ may independently represent one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
A may represent a ring structure of isoquinoline;
each of X₁ to X₄ may independently represent one selected from CR₁₁ and nitrogen (N);
each R₁₁ may independently represent one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group and a phosphino group;
when at least two of X₁ to X₄ are each independently represented by CR₁₁, two adjacent R₁₁ may be optionally fused with each other to form one ring structure selected from a 5-membered carbon ring, a 5-membered hetero ring, a 6-membered carbon ring, and a 6-membered hetero ring;

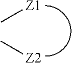

may represent a bidentate ligand;
m may be an integer of 1, 2 or 3, n may be an integer of 0, 1 or 2, and m+n may be an oxidation number of the metal M.

In some embodiments of the present disclosure, the organometallic compound represented by the Chemical Formula I may be represented by one selected from the group consisting of Chemical Formula II-1 and Chemical Formula II-2:

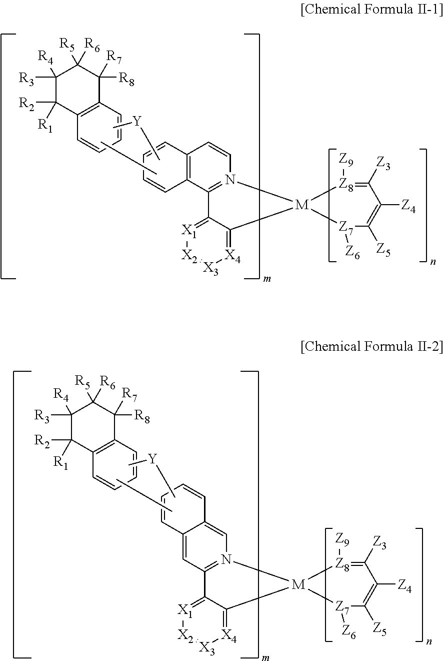

wherein in the Chemical Formula II-1 and the Chemical Formula II-2,
each of Z₃ to Z₆ and Z₉ may independently represent one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
two adjacent substituents among Z₃ to Z₆ and Z₉ optionally form a C3-C20 carbon ring or a C3-C20 hetero ring;
each of Z₇ and Z₈ may independently represent one selected from oxygen (O) and nitrogen (N).

In some embodiments of the present disclosure, M may be iridium (Ir).

In some embodiments of the present disclosure, the compound represented by the Chemical Formula I may be at least one selected from the group consisting of compounds 1 to 183.

In some embodiments of the present disclosure, the compound represented by the Chemical Formula I may be a red phosphorescent material.

An organic light-emitting device according to an example embodiment of the present disclosure may include a first electrode; a second electrode facing the first electrode; and an organic layer disposed between the first electrode and the second electrode, the organic layer may include a light-emitting layer that includes a dopant material that includes the organometallic compound according to example embodiments of the present disclosure.

In some embodiments of the present disclosure, the light-emitting layer is a red phosphorescent light-emitting layer.

In some embodiments of the present disclosure, the organic layer further includes at least one selected from the group consisting of a hole injection layer, a hole transport layer, an electron transport layer, and an electron injection layer.

An organic light-emitting device according to an example embodiment of the present disclosure may include a first electrode; a second electrode facing the first electrode; a first light-emitting stack; and a second light-emitting stack, wherein both the first and second light-emitting stacks may be between the first electrode and the second electrode, and wherein each of the first light-emitting stack and the second light-emitting stack may include at least one light-emitting layer including a red phosphorescent light-emitting layer that includes a dopant material that includes the organometallic compound according to example embodiments of the present disclosure.

An organic light-emitting device according to an example embodiment of the present disclosure may include a first electrode; a second electrode facing the first electrode; a first light-emitting stack; a second light-emitting stack; and a third light-emitting stack, wherein the first, second, and third light-emitting stacks may be between the first electrode and the second electrode, and wherein each of the first light-emitting stack, the second light-emitting stack, and the third light-emitting stack may include at least one light-emitting layer including a red phosphorescent light-emitting layer that includes a dopant material that includes the organometallic compound according to example embodiments of the present disclosure.

An organic light-emitting display device according to an example embodiment of the present disclosure may include a substrate; a driving element on the substrate; and the organic light-emitting device according to example embodiments of the present disclosure, the organic light-emitting device may be disposed on the substrate and connected to the driving element.

Although example embodiments of the present disclosure have been described in detail with reference to the accompanying drawings, the present disclosure is not limited thereto and may be embodied in many different forms without departing from the technical concept of the present disclosure. Therefore, example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

It will be apparent to those skilled in the art that various modifications and variations can be made in the present disclosure without departing from the technical idea or scope of the disclosure. Thus, it is intended that embodiments of the present disclosure cover the modifications and variations of the disclosure provided they come within the scope of the appended claims and their equivalents.

1. An organometallic compound represented by Chemical Formula I: 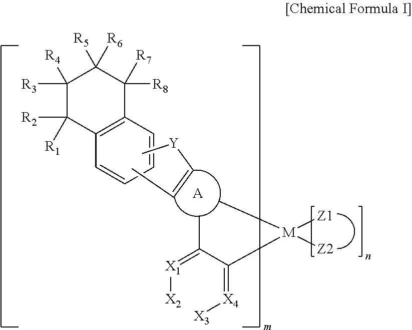
wherein in the Chemical Formula I,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au);
each of R₁ to R₈ independently represents one selected from the group consisting of hydrogen, deuterium, a substituted or unsubstituted C1 to C20 alkyl group, and a substituted or unsubstituted C3 to C20 bicycloalkyl group;
Y represents one selected from the group consisting of BR₉, CR₉R₁₀, C═O, CNR₉, SiR₉R₁₀, NR₉, PR₉, AsR₉, SbR₉, P(O)R₉, P(S)R₉, P(Se)R₉, As(O)R₉, As(S)R₉, As(Se)R₉, Sb(O)R₉, Sb(S)R₉, Sb(Se)R₉, O, S, Se, Te, SO, SO₂, SeO, SeO₂, TeO, and TeO₂;
each of R₉ and R₁₀ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
A represents a ring structure of isoquinoline;
each of X₁ to X₄ independently represents one selected from CR₁₁ and nitrogen (N);
each R₁₁ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
when at least two of X₁ to X₄ are each independently represented by CR₁₁, two adjacent R₁₁ are optionally fused with each other to form one ring structure selected from a 5-membered carbon ring, a 5-membered hetero ring, a 6-membered carbon ring, and a 6-membered hetero ring; 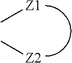
represents a bidentate ligand;
m is an integer of 1, 2 or 3, n is an integer of 0, 1 or 2, and m+n is an oxidation number of the metal (M).

2. The organometallic compound of claim 1, wherein the organometallic compound represented by the Chemical Formula I is represented by one selected from the group consisting of Chemical Formula II-1 and Chemical Formula II-2: 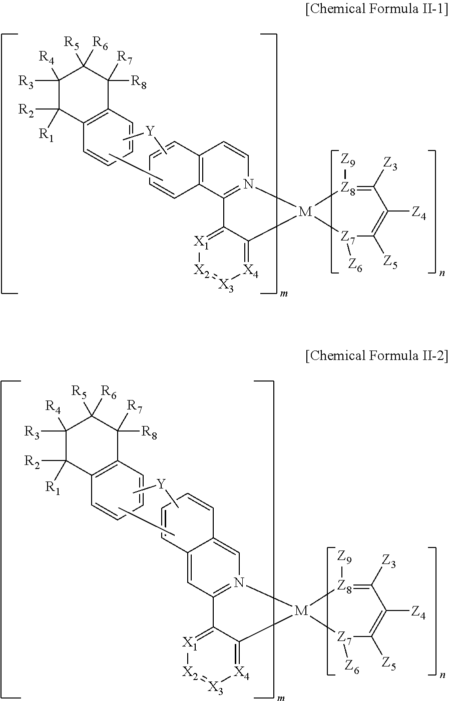
wherein in the Chemical Formula II-1 and the Chemical Formula II-2,
each of Z₃ to Z₆ and Z₉ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
two adjacent substituents among Z₃ to Z₆ and Z₉ optionally form a C3-C20 carbon ring or a C3-C20 hetero ring;
each of Z₇ and Z₈ independently represents one selected from oxygen (O) and nitrogen (N).

3. The organometallic compound of claim 1, wherein M is iridium (Ir).

4. The organometallic compound of claim 1, wherein the organometallic compound represented by the Chemical Formula I includes at least one selected from the group consisting of compounds 1 to 183:

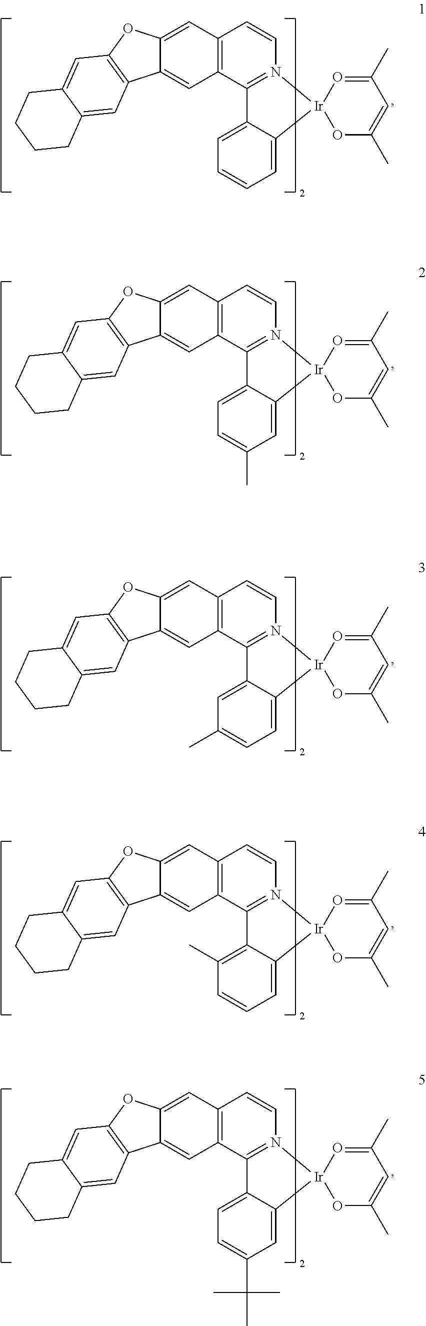

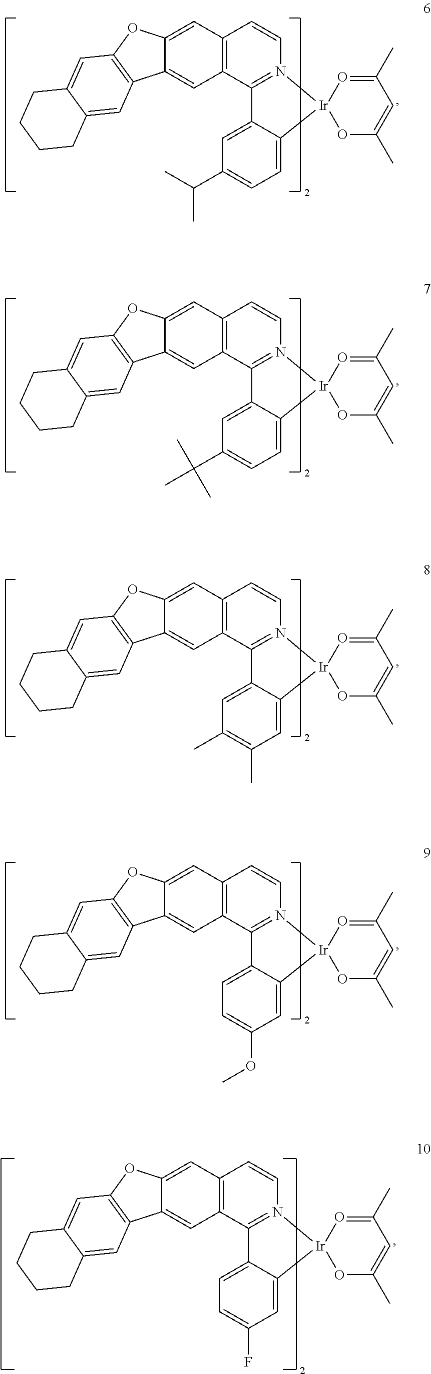

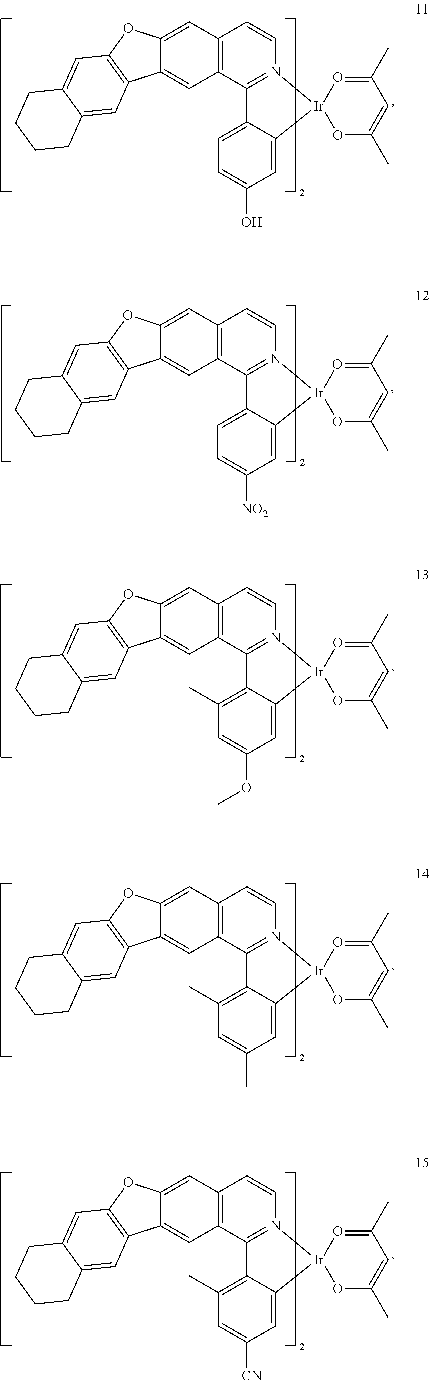

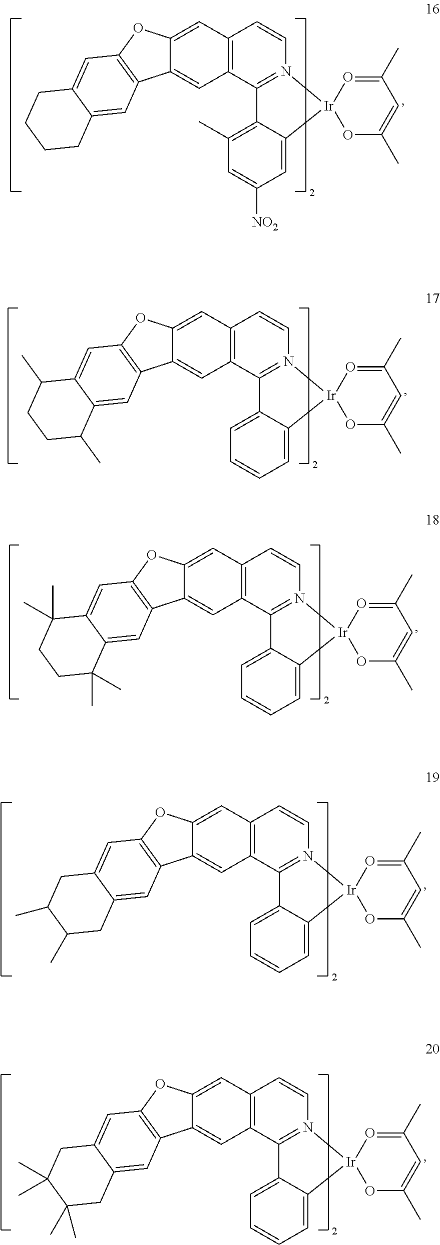

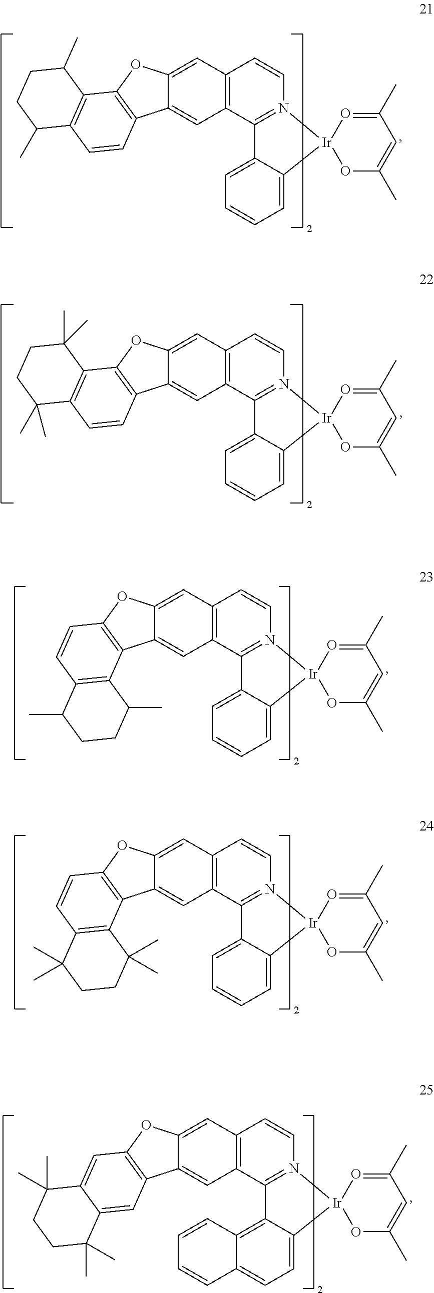

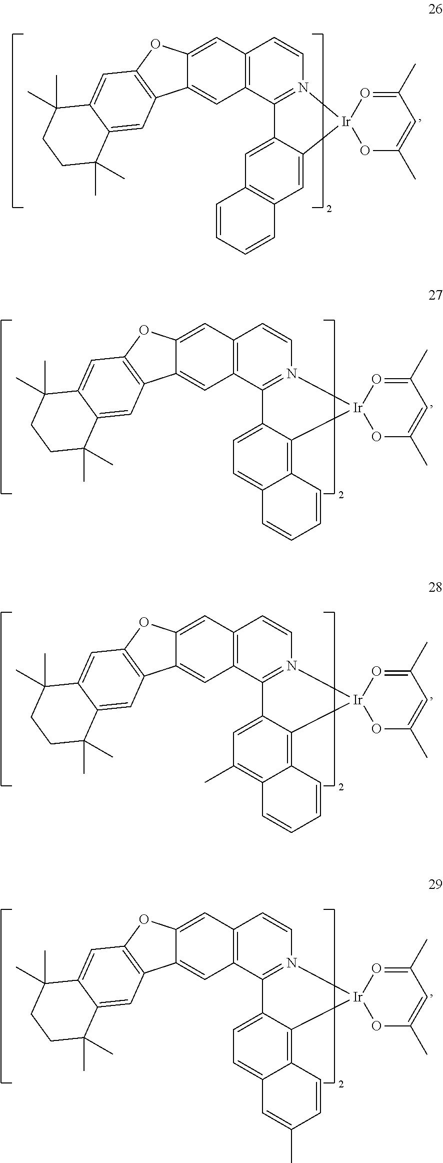

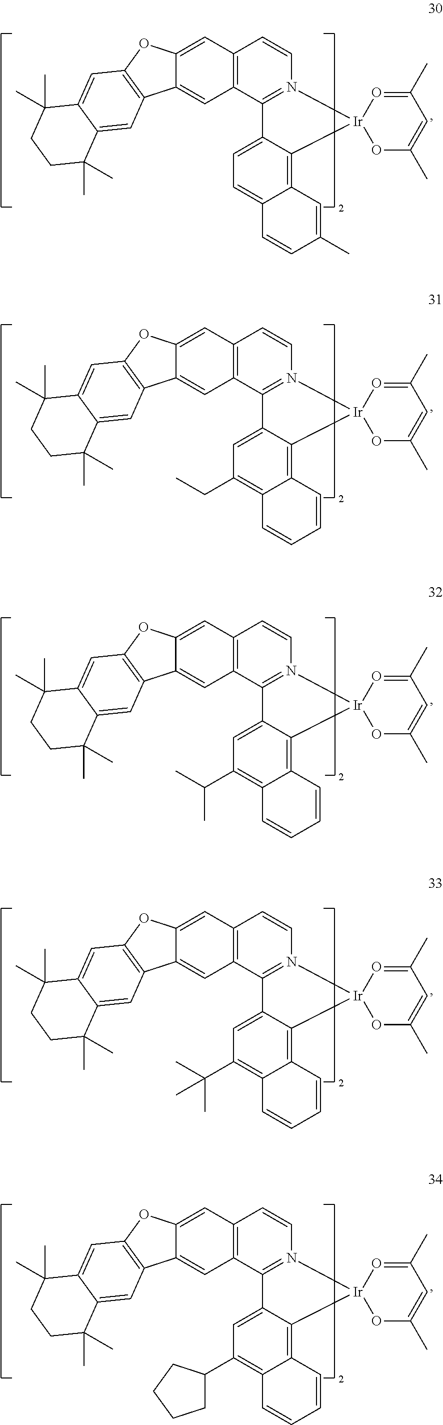

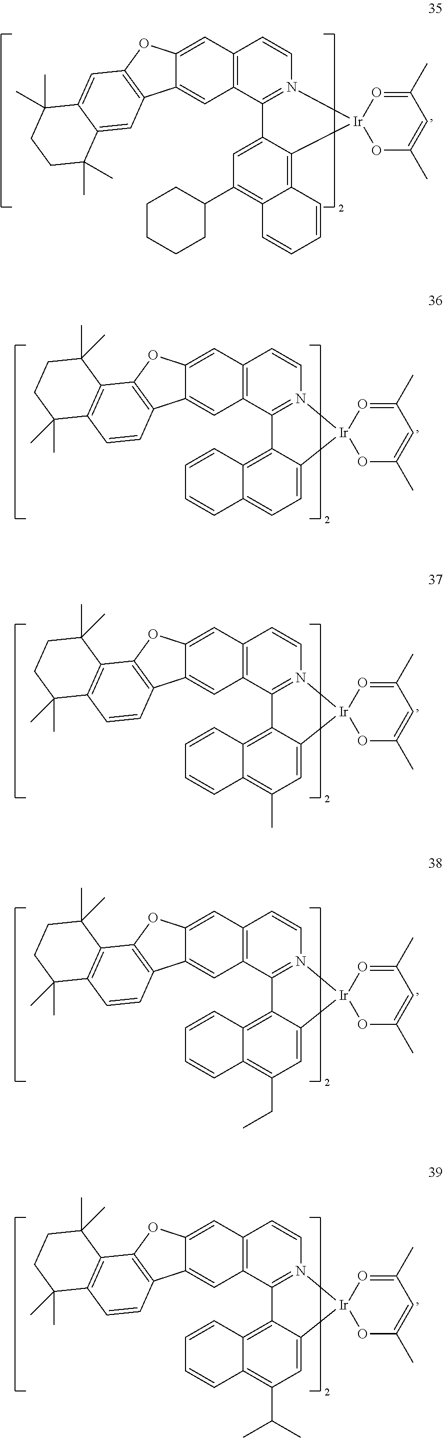

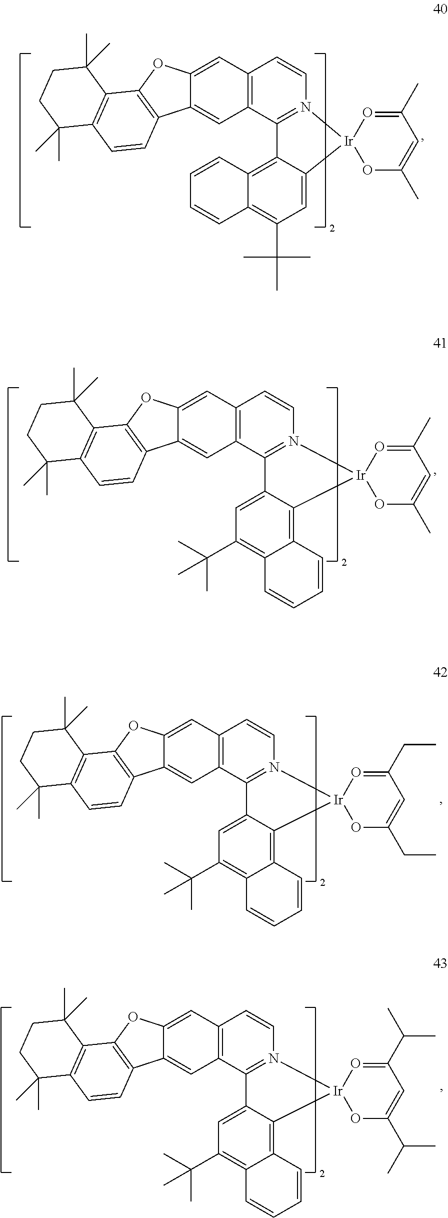

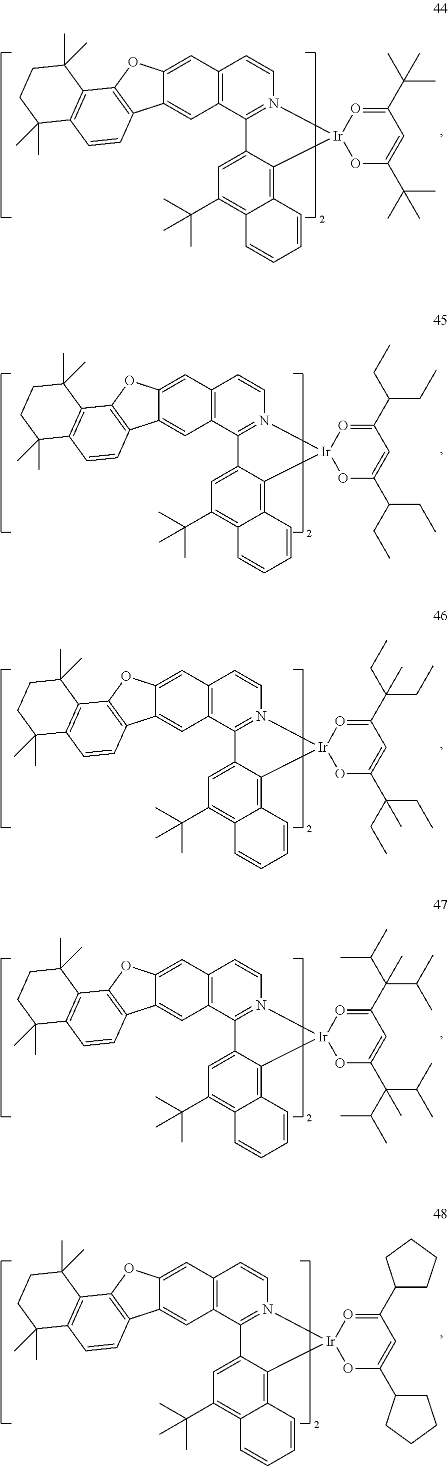

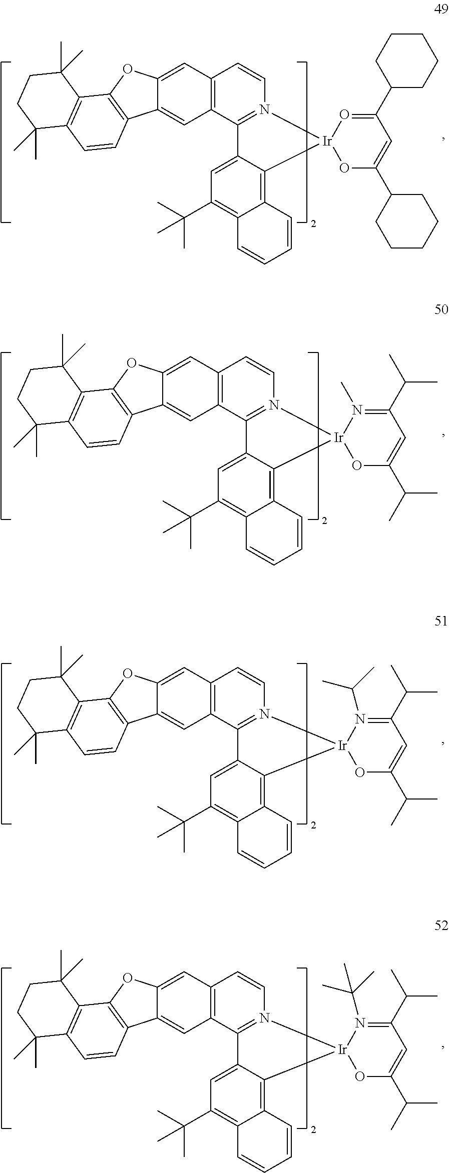

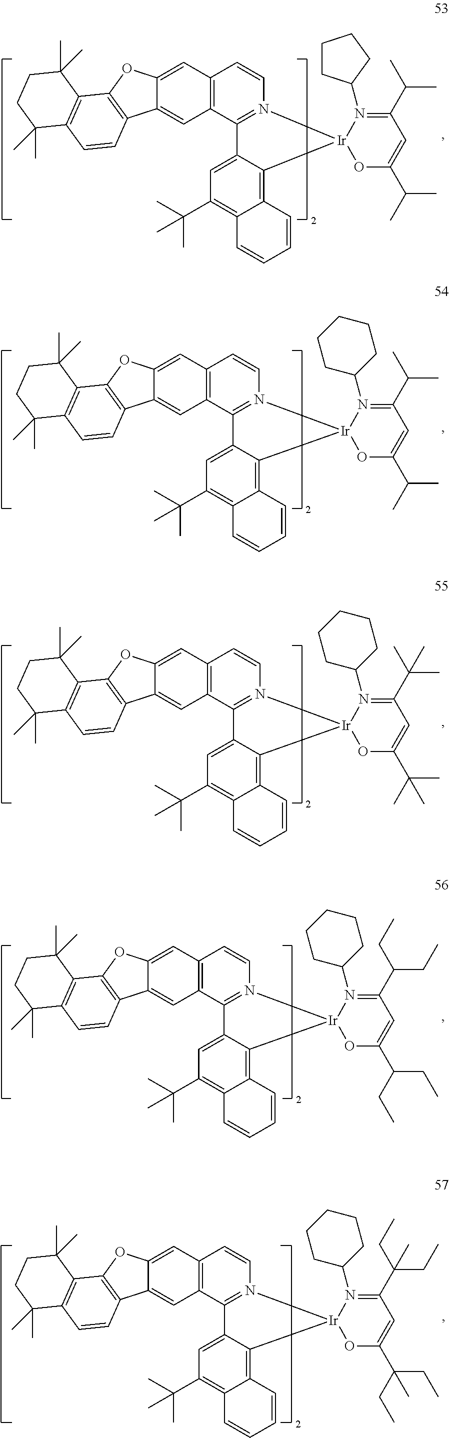

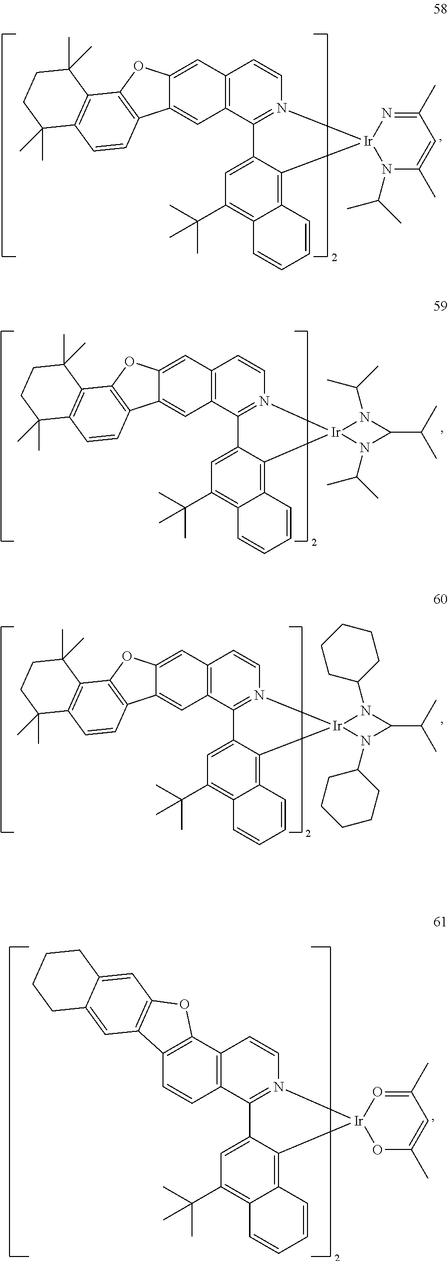

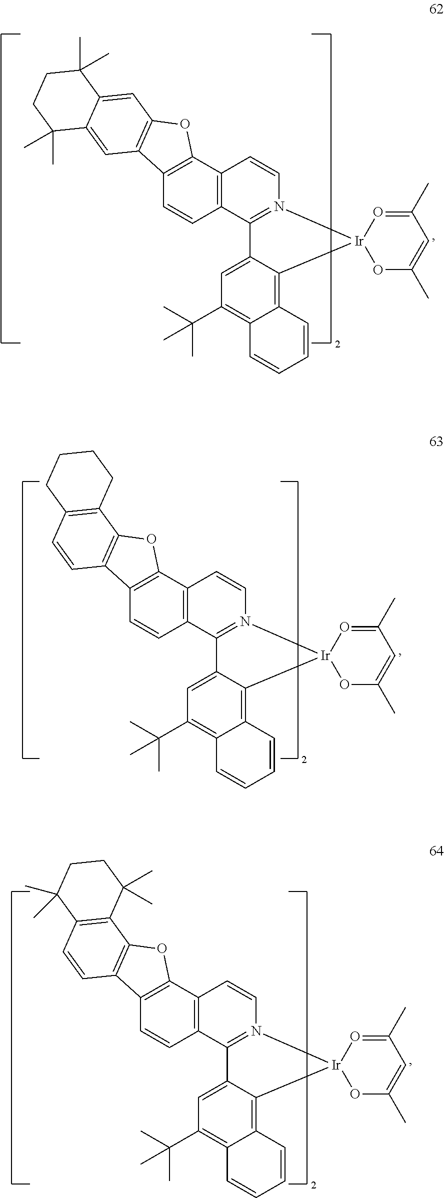

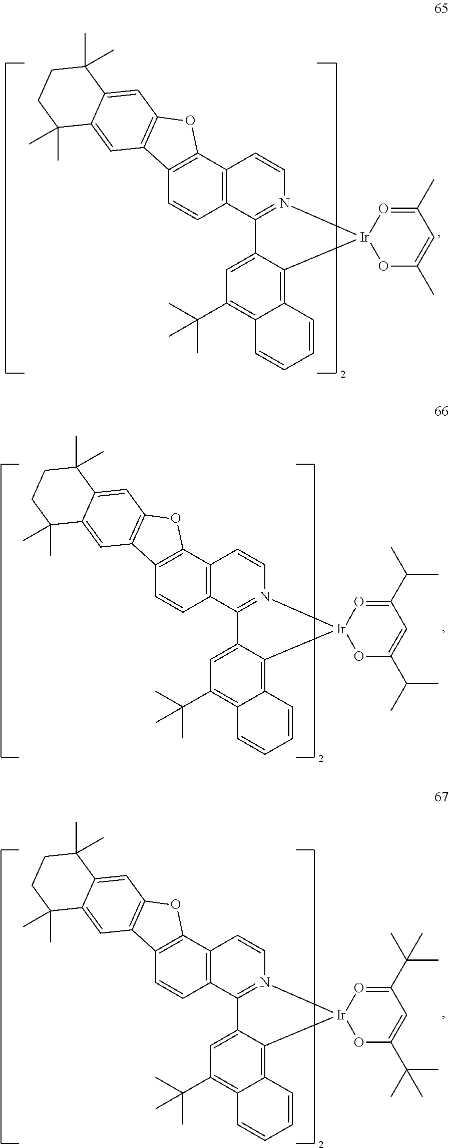

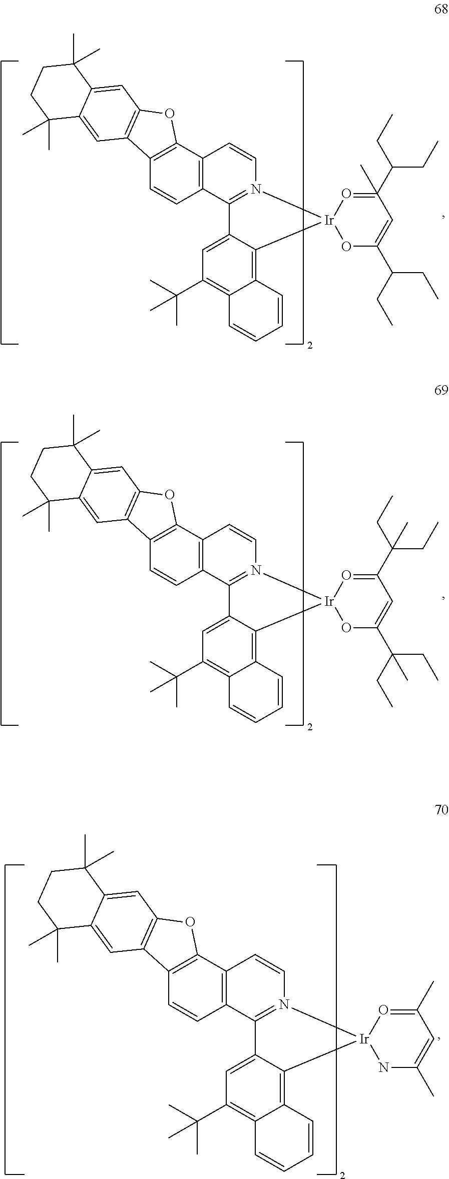

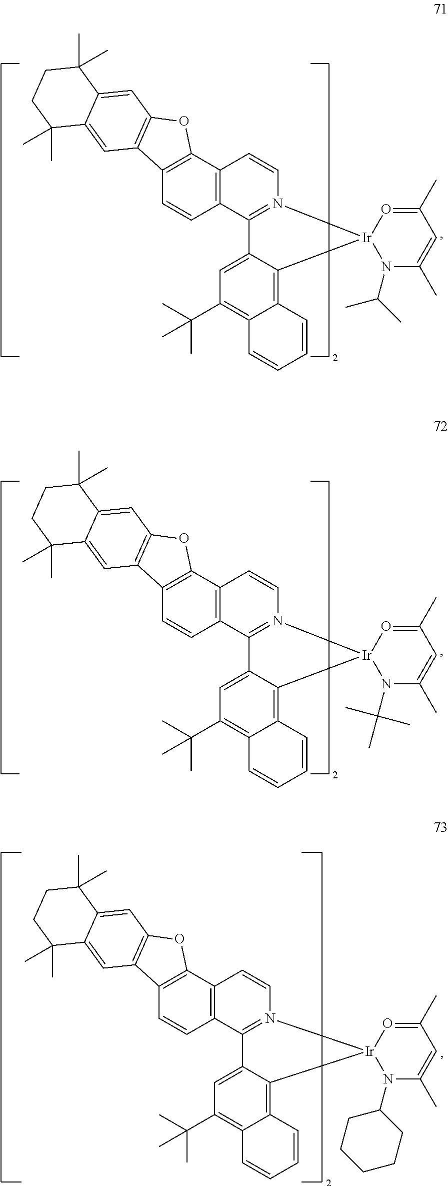

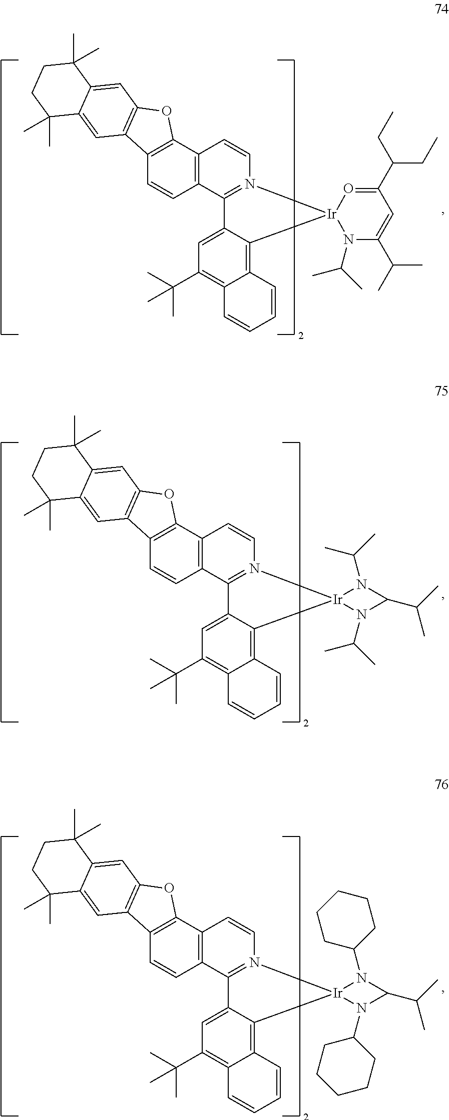

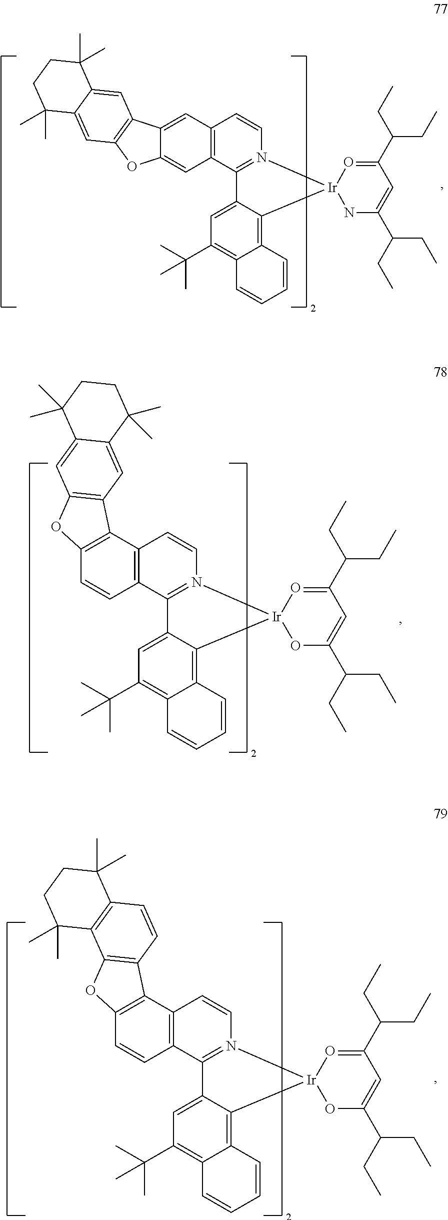

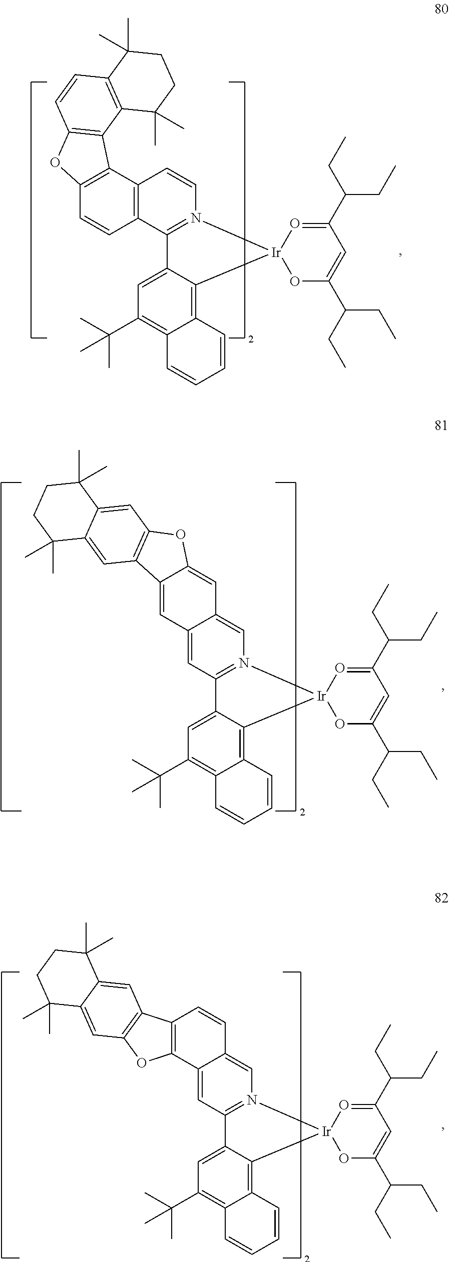

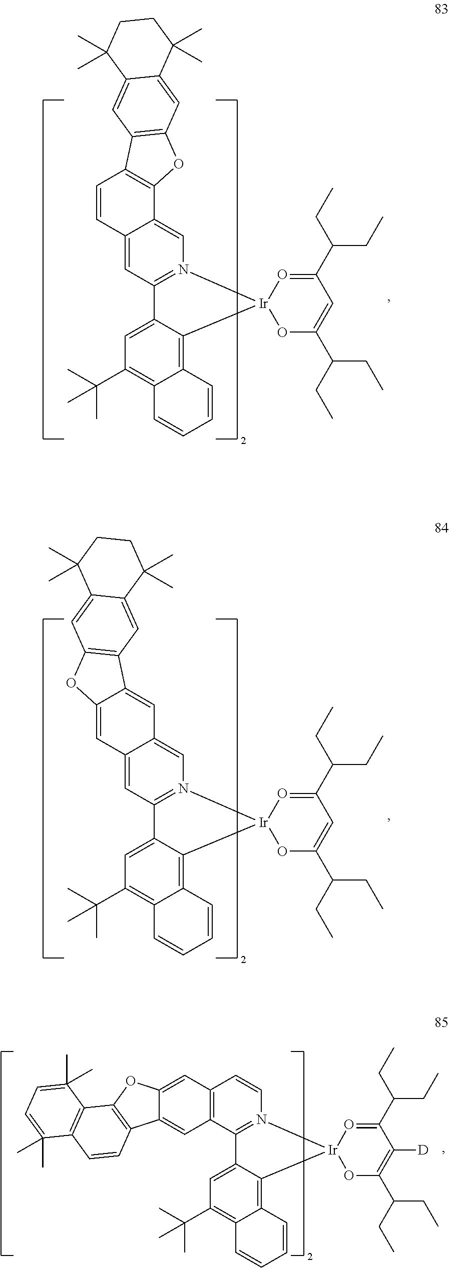

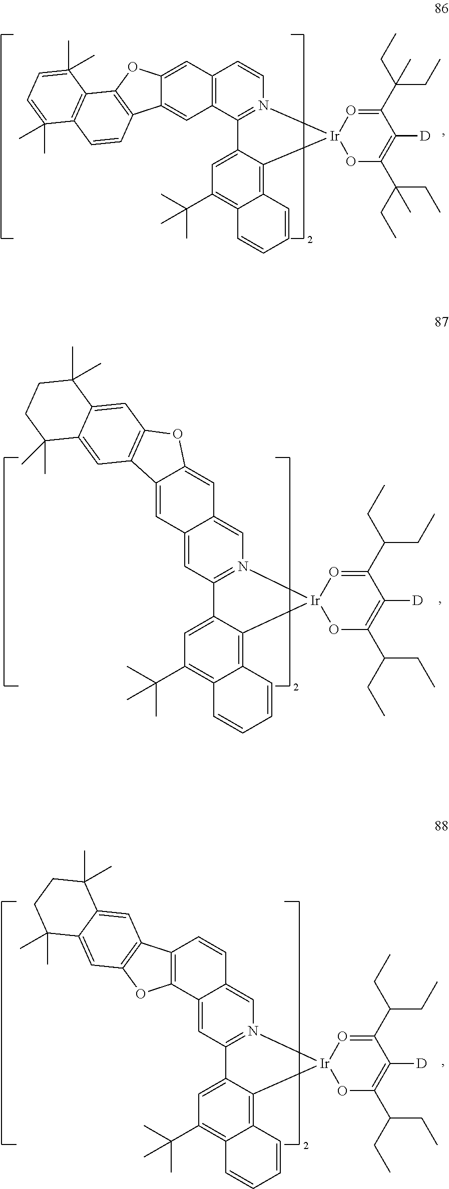

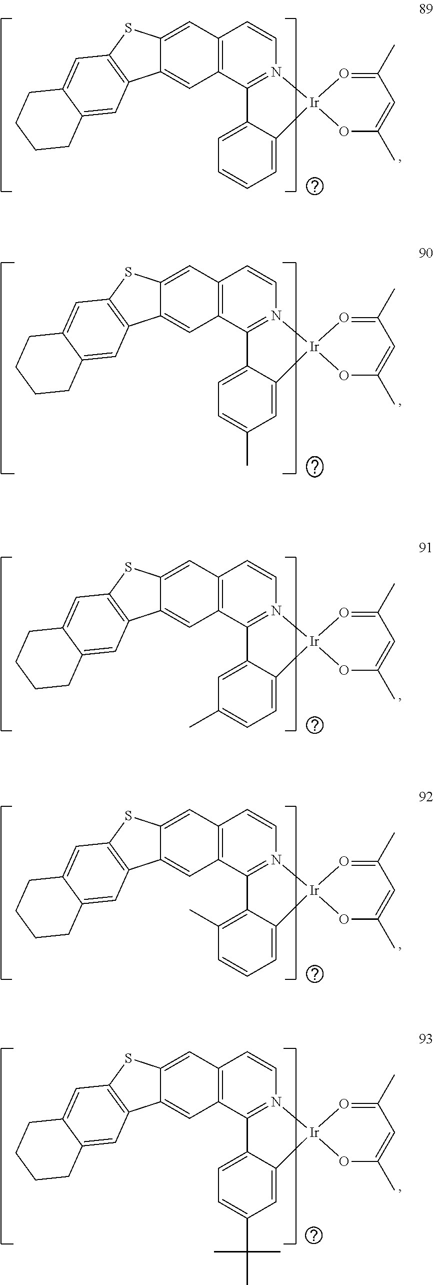

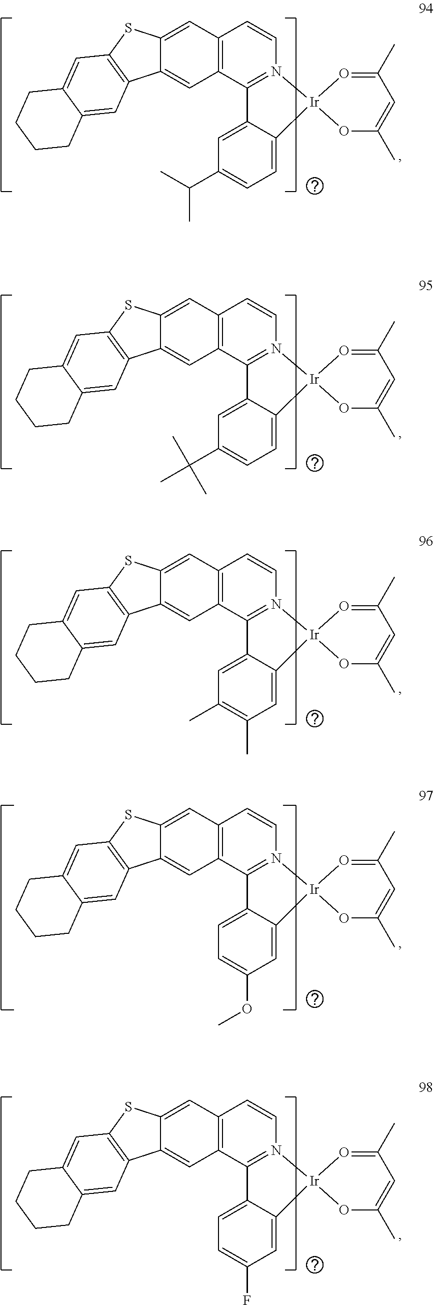

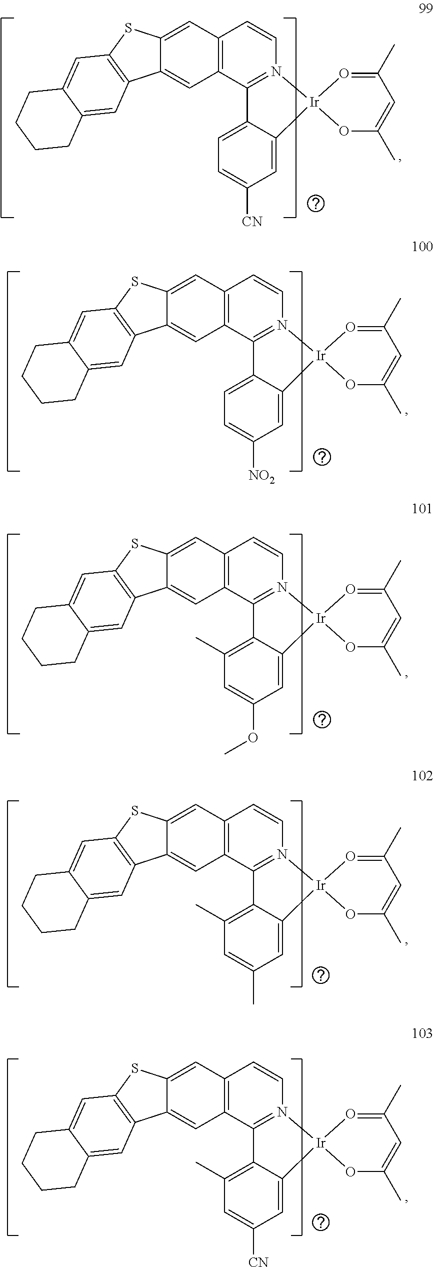

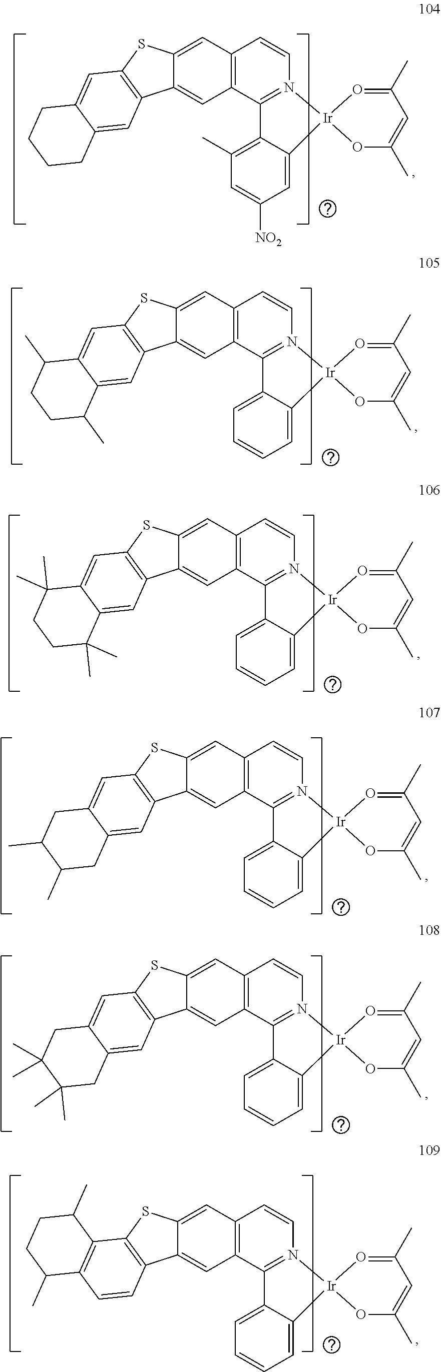

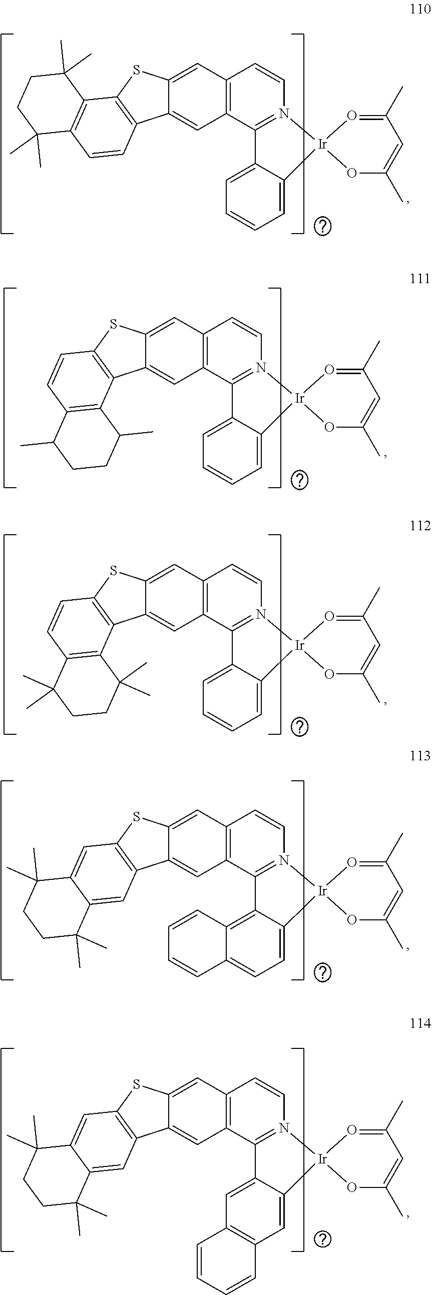

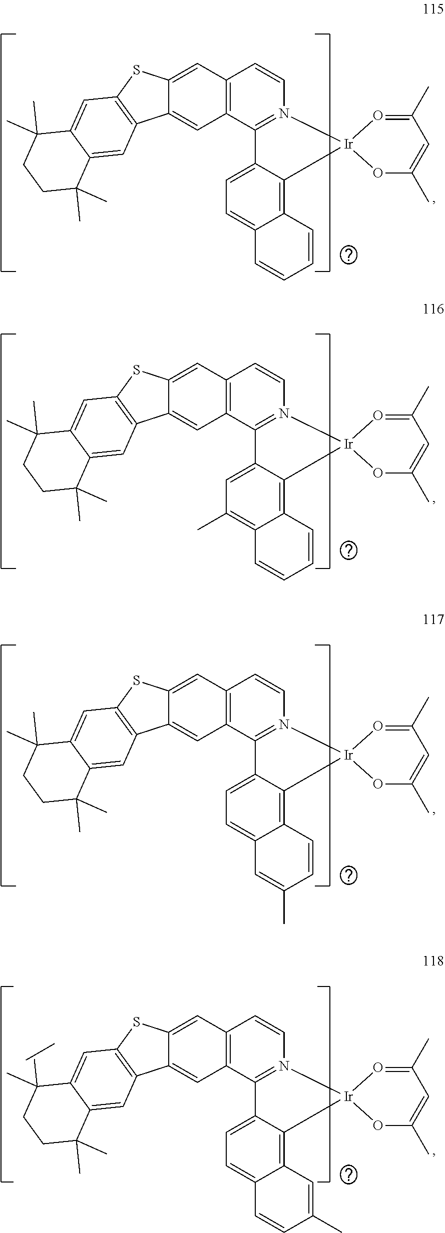

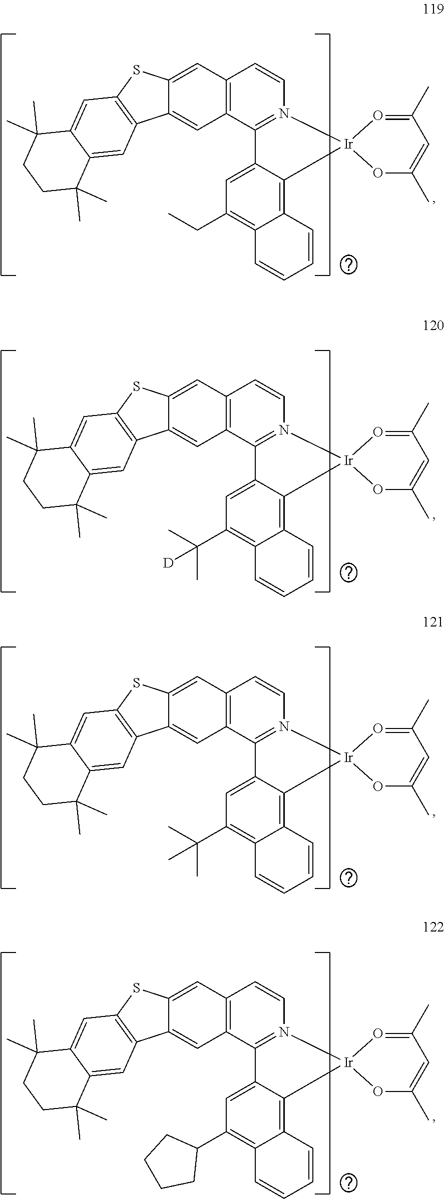

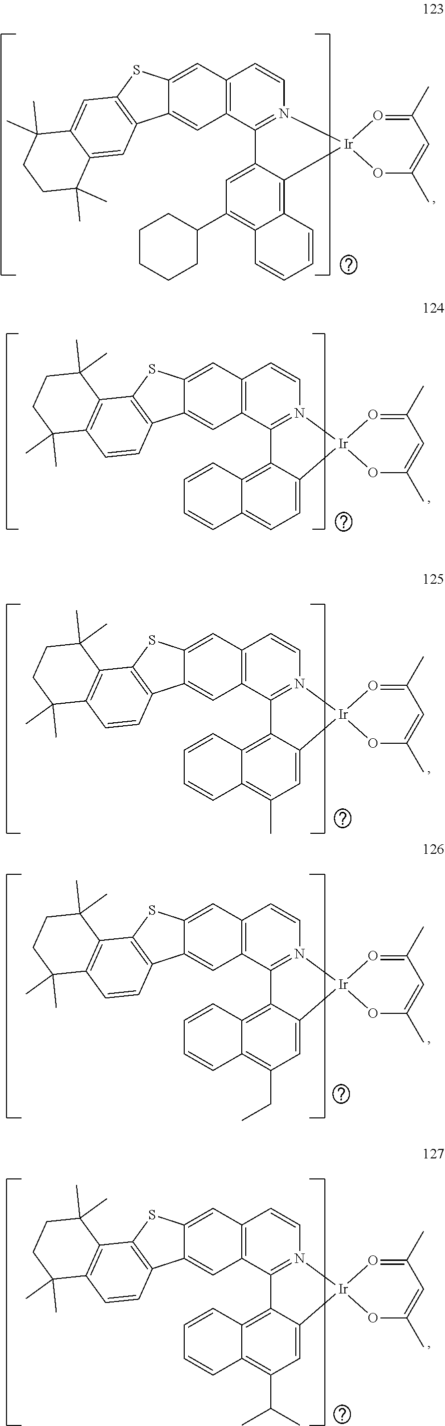

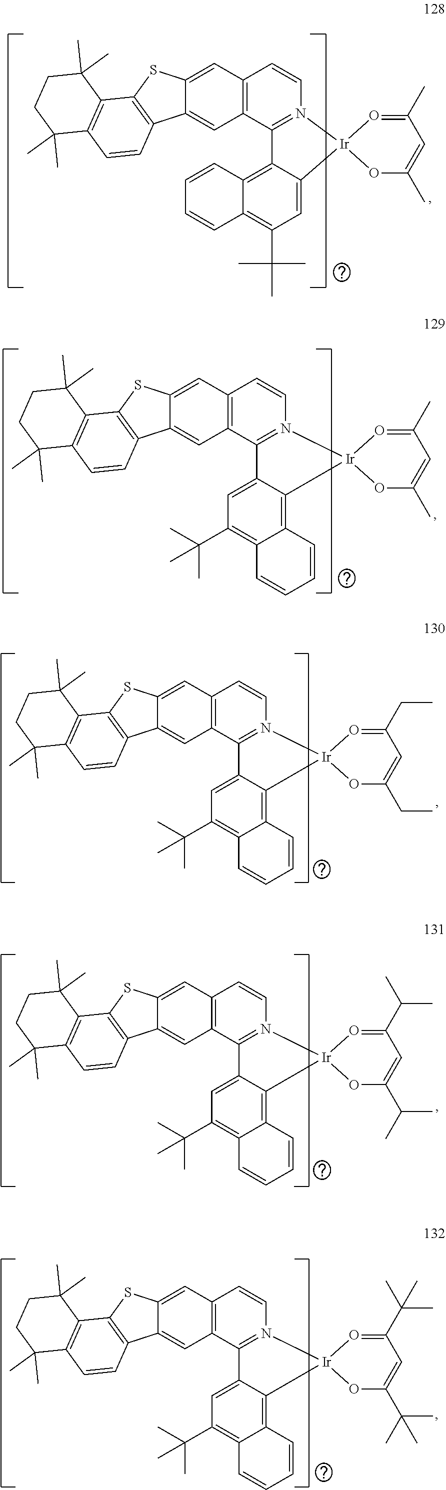

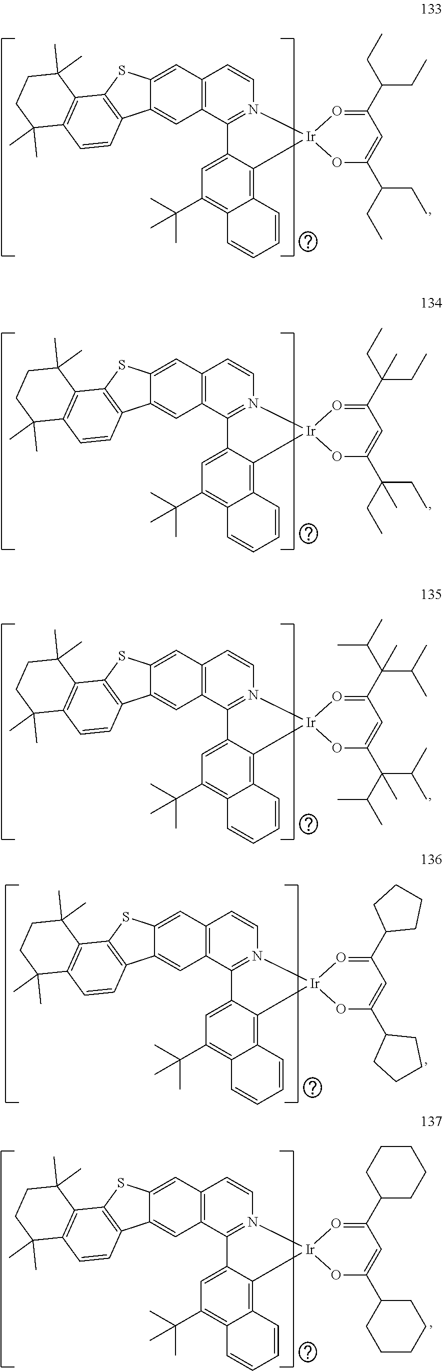

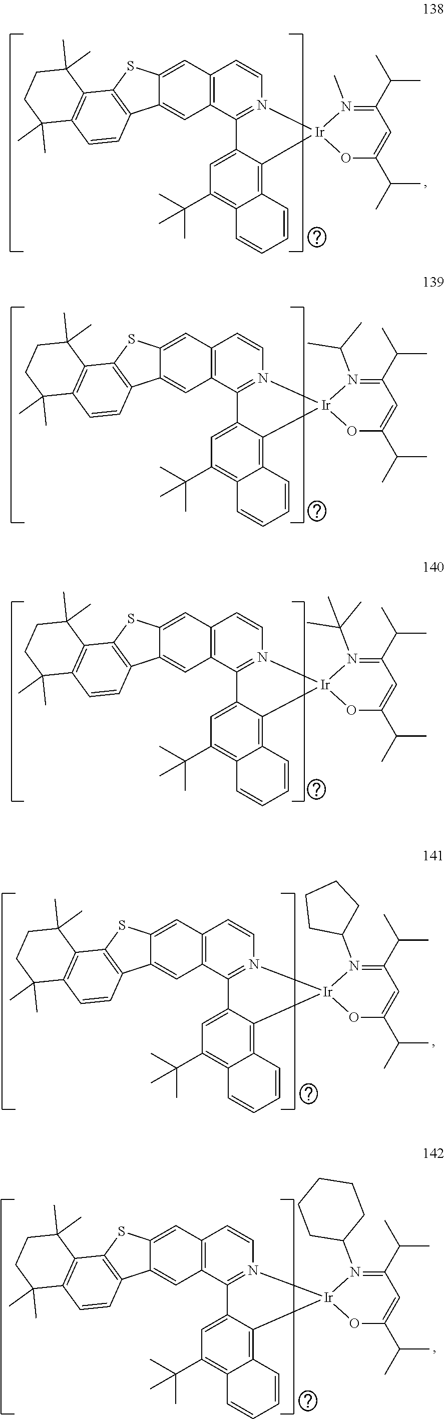

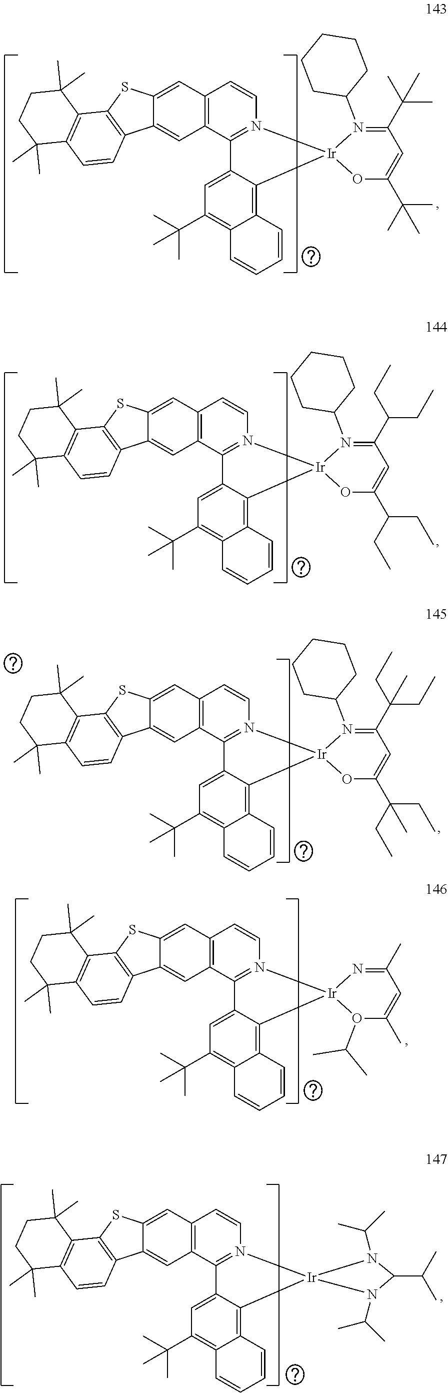

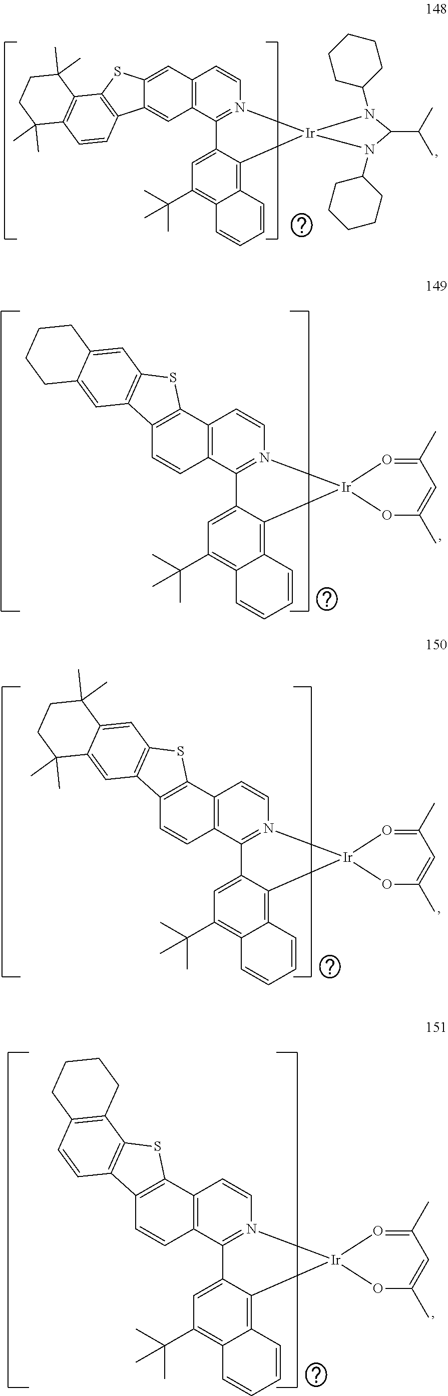

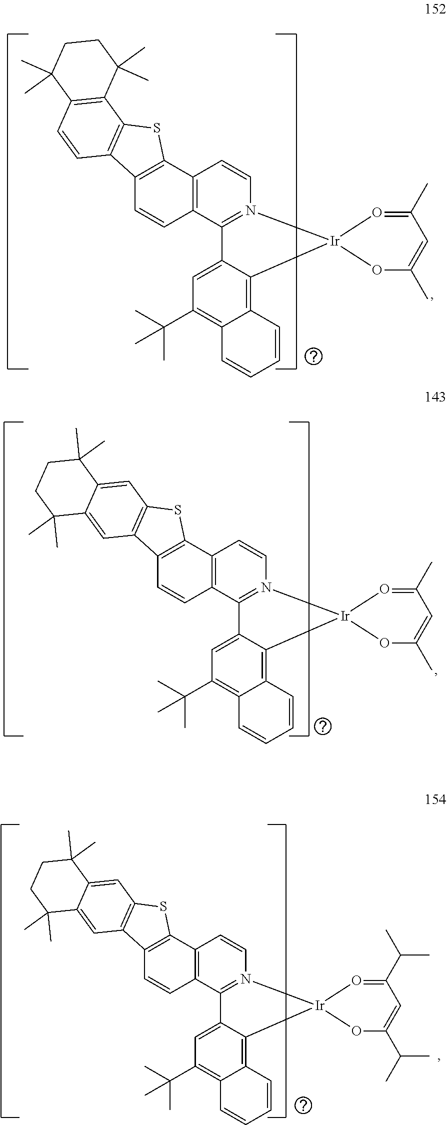

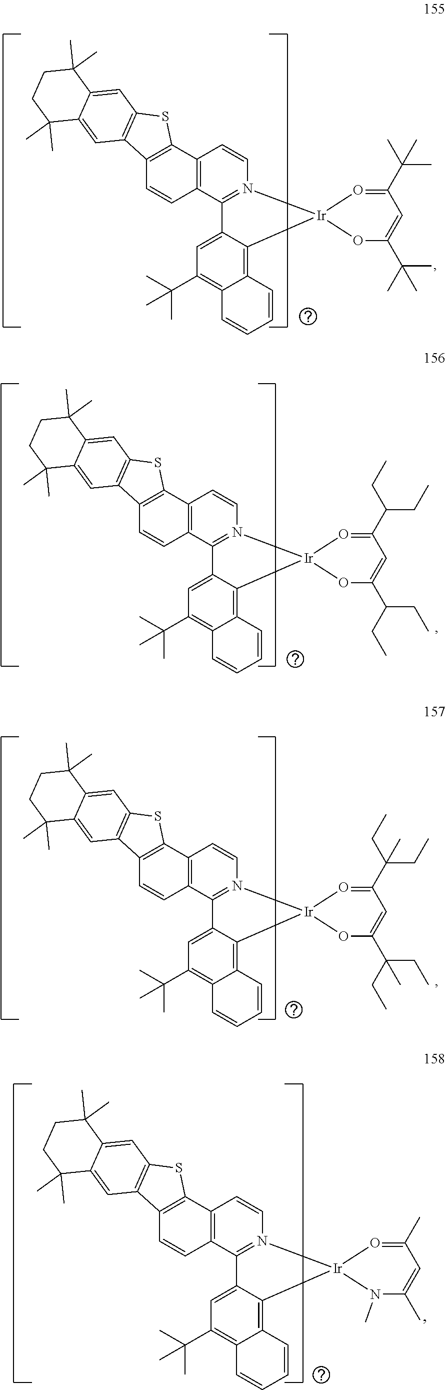

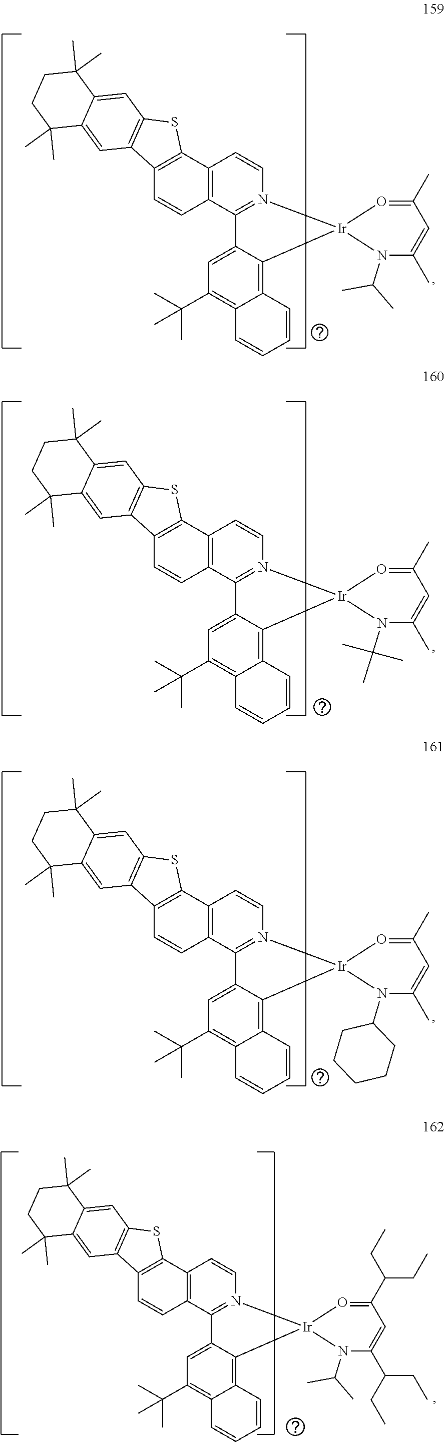

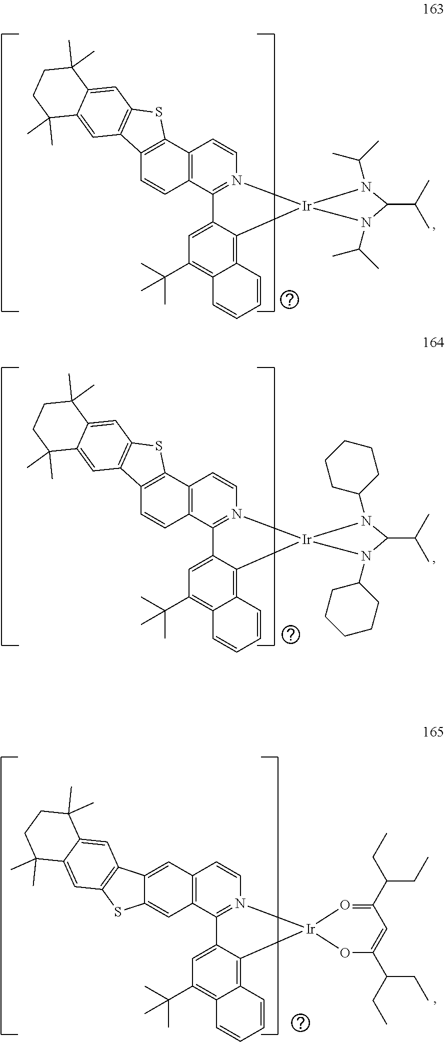

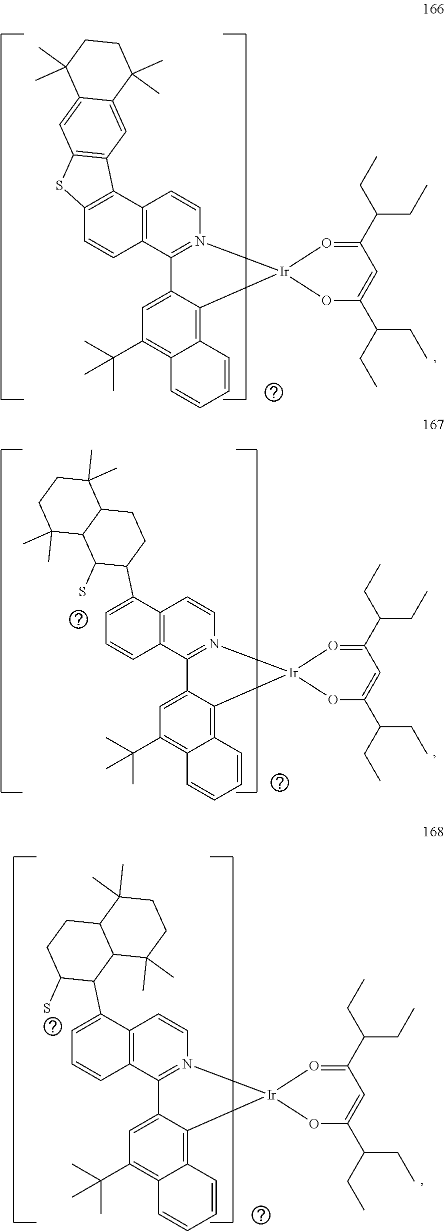

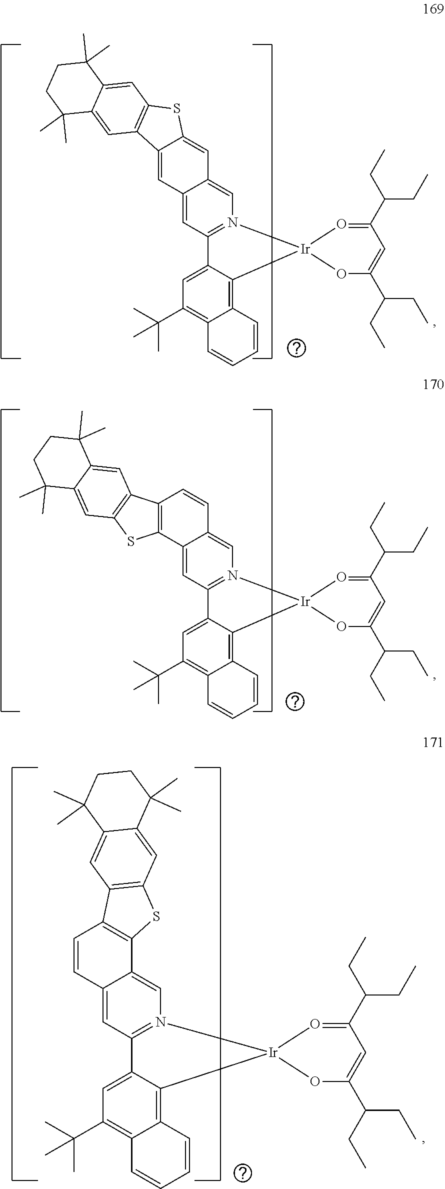

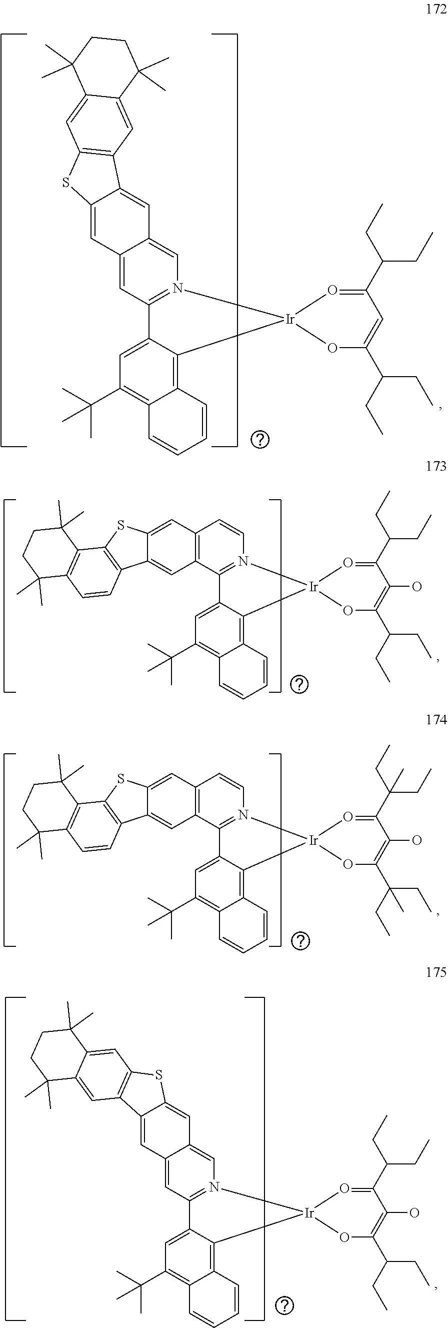

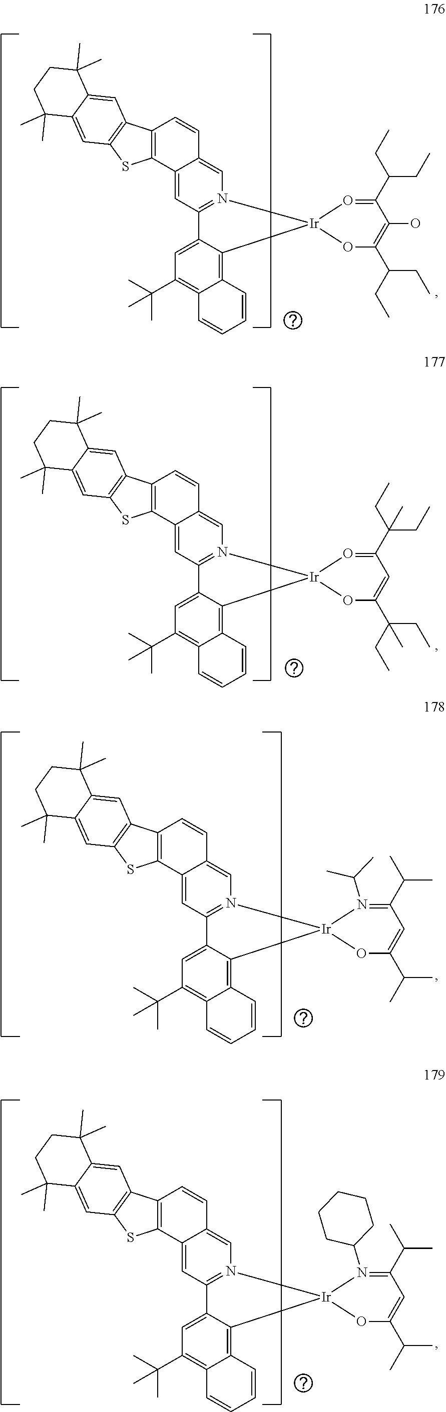

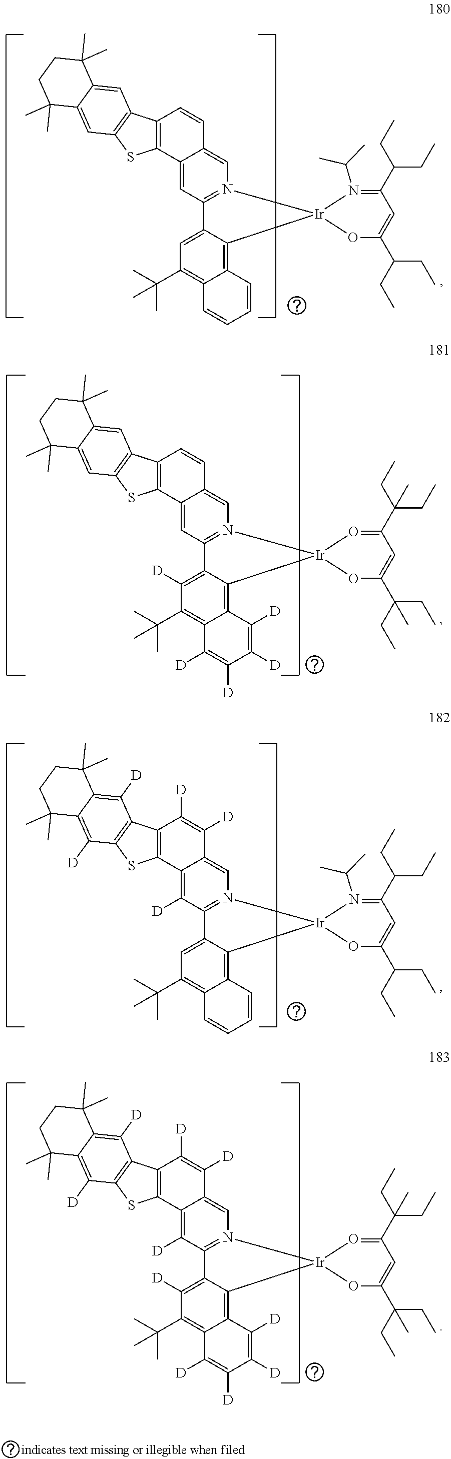

5. The organometallic compound of claim 1, wherein the organometallic compound represented by the Chemical Formula I is a red phosphorescent material.

6. An organic light-emitting device comprising:
a first electrode;
a second electrode facing the first electrode; and
an organic layer disposed between the first electrode and the second electrode, the organic layer including a light-emitting layer that includes a dopant material that includes the organometallic compound of claim 1.

7. The organic light-emitting device of claim 6, wherein the light-emitting layer is a red phosphorescent light-emitting layer.

8. The organic light-emitting device of claim 6, wherein the organic layer further includes at least one selected from the group consisting of a hole injection layer, a hole transport layer, an electron transport layer, and an electron injection layer.

9. An organic light-emitting device comprising:
a first electrode;
a second electrode facing the first electrode;
a first light-emitting stack; and
a second light-emitting stack,
wherein both the first and second light-emitting stacks are between the first electrode and the second electrode, and
wherein each of the first light-emitting stack and the second light-emitting stack includes at least one light-emitting layer including a red phosphorescent light-emitting layer that includes a dopant material that includes the organometallic compound of claim 1.

10. An organic light-emitting device comprising:
a first electrode;
a second electrode facing the first electrode;
a first light-emitting stack;
a second light-emitting stack; and
a third light-emitting stack,
wherein the first, second, and third light-emitting stacks are between the first electrode and the second electrode, and
wherein each of the first light-emitting stack, the second light-emitting stack, and the third light-emitting stack includes at least one light-emitting layer that includes a red phosphorescent light-emitting layer that includes a dopant material that includes the organometallic compound of claim 1.

11. An organic light-emitting display device comprising:
a substrate;
a driving element on the substrate; and
the organic light-emitting device of claim 6, the organic light-emitting device is disposed on the substrate and connected to the driving element.
